(19) United States
(12) Patent Application Publication
(10) Pub. No.: US 2016/0172037 A1
(43) Pub. Date: Jun. 16, 2016

(54) NOVEL LV NAND-CAM SEARCH SCHEME USING EXISTING CIRCUITS WITH LEAST OVERHEAD

(71) Applicant: Peter Wung Lee, Saratoga, CA (US)

(72) Inventor: Peter Wung Lee, Saratoga, CA (US)

(21) Appl. No.: 14/970,525

(22) Filed: Dec. 15, 2015

Related U.S. Application Data
(60) Provisional application No. 62/092,150, filed on Dec. 15, 2014.

(51) Int. Cl. G11C 15/04; G11C 16/04; G11C 16/26; G11C 16/08; G11C 16/24

(52) U.S. Cl. CPC G11C 15/046; G11C 16/08; G11C 16/24; G11C 16/26; G11C 16/0483

(57) ABSTRACT

Y-word Search schemes under preferred hierarchical broken-GBL and broken-LBL NAND-CAM arrays with 1) one CSL line shared by two NAND blocks as a match line or 2) one LBLps line shared in each LG of H Blocks as a match line. The NAND-CAM includes three types of sense-amplifiers for Y-word search operations, including 1) an Analog SA with 3-Bias cascade circuit for LG-based LBLps match line, 2) a Digital-like SA circuit for Block-based CSL match line, and 3) an existing DR-SA along with decoders for Y-direction-CSL match line. One or more embodiments of the Y-word search operations are provided for finding one matched paired-block, then one matched block, and one matched Y-word string associated with a LBL using sequential On/Off technique without extra overhead.

### 1. CROSS-REFERENCES TO RELATED APPLICATIONS

This application claims priority to U.S. Provisional Application No. 62/092,150, filed Dec. 15, 2014, commonly assigned and incorporated by reference herein for all purposes.

Additionally, this application is related to U.S. Pat. Nos. 8,169,808, 8,837,189, 8,169,808, 8,458,537, 8,730,740, 8,908,408, and 8,78,634, which are incorporated by reference herein for all purposes.

### 2. BACKGROUND OF THE INVENTION

The embodiments of the present invention relate generally to Non-Volatile Memory (NVM) architecture. More particularly, the invention provides improved 2D and 3D NAND flash devices being configured with a NAND-based content-addressable memory (CAM) functions to achieve fast search speed and low power-consumption substantially free of extra silicon circuit overheads of match-line sense-amplifier (ML-SA) and match-line Read-only memory (ML-ROM) Encoder while using as much as possible of most existing peripheral circuits of NAND.

CAM is also well known as the associative memory or associative storage. As contrast to the conventional approach of utilizing a known address-input to access the data stored in a memory, data-input of CAM in effect is used to perform a search of matching data contents. Regarding CAM bit-matching functions, there are two kinds of CAM memories such as BCAM (Binary CAM) and TCAM (Ternary CAM). The BCAM searches for memory array contents to match the 1's and 0's of each bit position in the input data stream, while TCAM searches for memory array contents to match 1's, 0's and X's of each bit position in the input data stream, where “X” stands for “don't care.” Once a match is met, CAM memory returns the address(es) of the match(es). If no match is met, then the CAM will return a signal indicating no match data is found. Typically, the extra function of ‘X’ is utilized for the maskable bits randomly distributed in the desired matching data stream.

Regarding CAM memory types, there are two kinds of CAM memories such as VM-CAM (Volatile CAM) and NVM-CAM (Non-volatile CAM). The VM-CAM includes SRAM-CAM and DRAM-CAM, while NVM-CAM includes parallel-type NOR-CAM and the serial-type NAND-CAM either in 2D or 3D technology.

Regarding CAM matching approach, there are X-match approach and Y-match approach respectively referring to matching word stored in X-direction and Y-direction. The X-match approach loads the matching word with complimentary bits (referred as X-word) into a designated X-PB (X Page-Buffer) with comparing word bits connecting all or partial BLs broadcasting in X-direction of whole CAM memory array. Conversely, the Y-match approach loads the matching word input bits (referred as Y-word) into a designated Y-PB (Y Page-Buffer) with comparing word with complimentary bits connecting all WLs in Y-direction of whole CAM memory array. Furthermore, the 2D XY-matching approach loads the matching data bits into both designated X-PB and Y-PB with comparing bits connecting with all BLs and WLs extending respectively in both X-direction and Y-direction of entire CAM memory array. As one option of state-of-art NVM CAM design, each bit of Y-word may include one paired of complementary bits formed in two NVM cells connected in series in two adjacent WLs along with one BL. Another option of NVM CAM design is that each bit of Y-word may include one paired of complementary bits formed in two NVM cells connected in parallel in same single WLs but along with two parallel BLs. The formal option has 2-fold Y-word physical length of the latter one.

Practically, each NAND-CAM's 1D search step may be divided into a plurality of 1D sub-steps. For the number of sub-steps of 1D X-word search may be different from 1D Y-word search subs-step in 2D NAND-CAM. The physical length of each vertical (parallel to BL direction) NAND string limits the length of Y-word search. The length or the bit number of Y-word is defined by ½ of total available NAND cell number physically connected in series between one top and one bottom string select transistors because each matching bit of Y-word is comprised of one pair of regular bit and its complementary bit.

Similarly, the X-word search is also limited by the number of BLs or cell formed in each horizontal word line (WL) in each NAND block. There are pros and cons for either X-word search or Y-word Search. Typically, the Y-word search is much faster than X-word search due to the specific NAND string structure favoring the Y-word current-sensing over X-word in NAND-CAM array. But X-word program scheme is compatible with conventional NAND page program in WL direction, while the Y-word program scheme is in BL direction, which is incompatible with conventional NAND page program along the WL direction.

There are many applications and demands for a faster, lower-power, higher-density, and flexible number of matching bits of NVM-CAM memory with lower cost. An extremely high-density NAND-CAM is particularly desired, which is a NAND flash memory being configured with an aforementioned on-chip CAM search and matching functions.

The NAND-CAM includes SLC-NAND-CAM, MLC-NAND-CAM, TLC-NAND-CAM, XLC-NAND-CAM, nLC-NAND-CAM or even Hybrid-NAND-CAM, depending on the storage types of NAND cells. In the specification of the present invention for nLC-NAND-CAM, n=1 is referred as the SLC-NAND-CAM, n=2 the MLC-NAND-CAM, n=3 the TLC-NAND-CAM, while n=4, XLC-NAND-CAM. The Hybrid-NAND-CAM means that each NAND-CAM includes a plurality of mixed NAND storages of SLC, MLC, TLC, and XLC with on-chip CAM functions. In certain embodiments of the present invention, the SLC NAND-CAM is used as an example to describe the operation but techniques should be extended to MLC NAND-CAM. For those CAM search applications requiring the high-speed performance, then TLC-NAND-CAM and XLC-NAND-CAM are not practical.

Conventional NAND-CAM scheme uses various extra circuits of ROMs and SAs for the preferred ML-schemes with large silicon overhead, where ML stands for Match-Line. Today, CAM chip has pluralities of search and matching applications such as image, biometrics, voice recognition, maps, dictionaries and text files in gigantic database such as all-NAND data centers. Although many fast SRAM-CAM and DRAM-CAM related patents and applications have been broadly disclosed and adopted in past 30 years, the publications, applications, and utilizations of the NAND-CAM are still very limited.

For the reasons stated above and for other good reasons stated below, it is desired for a superior and flexible NAND-CAM with improved concurrent search performances in terms of faster speed, less power consumption, and lower die cost and more flexible number of matching bits. It is also desired to use the existing SAs and PRBs in DRs and SCRs associated with the NAND-CAM with Y-pass gate circuits and all decoders of Y-decoders, block-decoders, and LG, MG, and HG decoders to decode the matched LBL and Block to save silicon area.

### 3. BRIEF SUMMARY OF THE INVENTION

The embodiments of the present invention relate generally to NVM array architecture. More particularly, the invention provides improved NAND-based content-addressable memory (CAM) to achieve fast search speed and low power-consumption substantially with less extra silicon circuit overheads of match-line sense-amplifier (ML-SA) and match-line Read-only memory (ML-ROM) Encoder while using most of the existing peripheral circuits of NAND that are originally reserved for performing other functions. Embodiments of the preferred NAND-CAM with the mixed pipeline and concurrent operations can be carried out in both 2D and 3D NAND manufacturing technologies.

In the following summarized embodiments of the present invention, the reference is made to the accompanying drawings that forms a part hereof, and in which is shown, by way of illustration, specific embodiments in which the disclosure may be practiced. In the drawings, like numerals describe substantially similar components throughout the several views. Other embodiments may be utilized and structural, logical, and electrical changes may be made without departing from the scope of the present disclosure.

In an embodiment, the present invention provides a preferred hierarchical N₁-level broken-GBL (global bit line) and broken-LBL (local bit line) nLC NAND-CAM array structure associated with N₂-bit dynamic CACHE registers (DCRs) each with expandable parasitic capacitance C_{LBL}, where n is an integer varied from 1 to 4 for SLC, MLC, TLC, and XLC and N₁ is an integer no smaller than 2. This preferred NAND-CAM cell array is divided, along Y-direction (bit line direction) of the array, into J HG groups per plane, L MG groups per HG, J′ LG groups per MG, H blocks per LG and N₂ NAND strings per block without including the additional spare LBL lines for storing ECC syndrome bits. Each string includes N₃ cells connecting in series with a plurality of LG-based search lines laid out in parallel to the string common source line (CSL) along X-direction (word line direction) of the array and N₃ WLs acting as Match lines (MLs) for Y-word search scheme with Y-direction Page Buffer (Y-PB). These MLs also work as the power lines of N₂ C_{LBL}S of the N₂-bit DCRs to supply Vinh with a value of LV Vdd or a HV up to 7V and Vss during concurrent and pipeline precharge, discharge, CAM search sensing, nLC program, nLC read, nLC program-verify, and nLC erase-verify operations, etc. The total number of blocks in one plane of the NAND-CAM is N₄. The NAND-CAM array includes a flexible Y-word length of N₅ which can be one or less than one fixed physical length of N₃/2 bits of one block, where N₅ is only limited by the whole total bits of N₅ (N3/2)×N₄ within one long physical GBL across all N₄ blocks.

In an example, each string comprises N₃ cells connecting in series with one top string select transistor connecting to one Y-direction LBL line and one bottom select transistor connecting to one X-direction CSL line, where N₃=8, 16, 32, 64, 128 or any other integer number. The number of strings per block is N₂, where N₂=16 KB in this example. The total number of blocks in one plane of the NAND-CAM is N₄ and the density of one SLC NAND-CAM plane is defined as N₂×N₃×N₄/2 due to one paired cells for each matching complimentary bits without including the parity bits of a plurality of spare LBL lines for ECC purpose.

In an embodiment, the present invention provides a preferred hierarchical N₁-level broken-GBL and broken-LBL nLC NAND-CAM array structure and N₂-bit DCRs each having expandable C_{LBL} capacitance for the similar LG-based but 1D X-word search function with a flexible word length of N₅ defined as N₅≦N₃ and an X-direction Page-Buffer (X-PB). The disclosed X-word NAND-CAM uses 1WL-1BL search scheme for 100% of the NAND array without being reduced by half as conventional X-word search approach but with search speed being at least 30-fold faster by using a batched-based concurrent page-read scheme. Alternatively, the NAND-CAM array includes a flexible X-word length of N₆ which can be only limited by the whole N₂NAND cells of one physical WL or whole number of LBL strings per one physical block.

In another embodiment, the present invention discloses a method of full utilization of the NAND-CAM array by storing those “don't-care” matching bits in all physical pages or WLs with dual functions. A first function of each “don't-care” WL is for Y-word search operation with stored bits being used as the maskable bits (as “don't care”) by applying a V_{READ} voltage that is defined with a value higher than maximum threshold values Vtn of all nLC cells. In other words, V_{READ}>Vtnmax. A second function of each “don't-care” WL is used to store X-direction nLC page data during non-Y-search operation by biasing the “don't-care” WL to a voltage of a predetermined VRN and V_{READ} for the rest of WLs in each selected block as defined in the regular nLC read operation.

In another embodiment, the present invention discloses a method of full utilization of NAND-CAM array by storing those “don't-care” matching bits in each physical WL with dual functions. A first function is for X-word search operation with stored bits to be used as the maskable bits (as “don't care”) by storing Vt with a value higher than Vtmax. A second function of each don't-care X-word bits is to store the nLC partial-page data or others such as ECC parity data during X-search operation by biasing the selected WL's voltage with a predetermined VRN and V_{READ} for the rest of WLs in each selected block as defined in the regular nLC read operation.

In an alternative embodiment, the present invention provides circuits of XT-decoder and Block-decoder designed with a latch function and an operating scheme to allow different desired voltages on all WLs, SSLs, and GSLs of all blocks of the NAND-CAM to be flexibly set and locked into their respective parasitic poly lines or capacitors in a mixed pipeline and concurrent fashion so that a Y-word search with flexible length can be quickly performed on whole NAND-CAM array without adding any silicon area overhead of a physical Y-direction Page-Buffer (Y-PB). This is referred as a pseudo Y-PB preferably using existing long X-direction poly line parasitic capacitances as temporary voltage storage buffers for all WLs, SSLs, and GSLs of strings in accordance with each Y-word input data. The whole operation can be implemented and controlled by an on-chip State-machine of the preferred NAND-CAM.

In another alternative embodiment, the present invention provides a method for the voltages of all above Y-word search data with the flexible bit length to be locked into a preferred pseudo Y-PB by performing accurate timing operations over Block decoders and XT-decoders controlled by the on-chip state-machine including 1) loading an XT bus with voltages in accordance with Y-word of N₆ bits of complimentary search data from an on-chip Y-word register; 2) passing and locking the above N₆ Y-word voltages at XT bus in 1-cycle to all corresponding sets of WLs, SSLs, and GSLs of every block via a Block decoder and enabling a HV pump circuit if the Y-word length is less than or equal to one Block, or passing and locking the above N₆ Y-word voltages at XT bus in more-than-one cycles to all corresponding sets of WLs, SSLs, and GSLs of every Block via the Block decoder and enabling the HV pump circuit if the Y-word length is N₇>1 Blocks (where the Y-word data has to be sequentially loaded into every N₇ Blocks in whole array in a pipeline manner); 3) starting a whole chip searching for matching Y-word.

In yet another embodiment, the present invention discloses a circuit of LG-based Y-word ML cascaded Sense-Amplifier that uses three Bias voltages to do precharge first on all N₂ LBL capacitors, then search which LG block contains a conducting NAND string to pull-down the ML voltage that indicates a matching of Y-word, and automatically return the matched LG-address via an on-chip compact ROM. The returning of LG-address is very fast and can be done within 25 μs due to total capacitances to be precharged and discharged during the searching operation are one small C_{LBL} in a LG block and one ML line only. Additionally, the present invention discloses a circuit of a LG-based compact ROM that reports the matched LG-address automatically without using a complicate ML-encoder circuit.

In still another embodiment, the present invention discloses a method for sequentially turning off NOR-wired H NAND blocks within one LG to each ML one by one in H−1 cycles by discharging off H−1 SSL, GSL, and WLs lines to prevent leakage of each NAND string so that each ML can be recharged back to identify a matched block which address can be found out from one matched LG within (H−1) cycles. As a result, total Y-word search time with returning the matching LG and matching Block addresses for whole 2WL-1BL based NAND-CAM can be approximately less than 50 μs.

In yet still another embodiment, the present invention discloses a method for using existing Y-pass array, Y-decoder, SA, and Static Cache Register (SCR) in Static Page Buffer (SPB) with additions of PMOS pull-up devices to allow a divided, NOR-wired ML line in PB area to sequentially turn off YC-dec, YB-dec, and YA-dec and finally to allow fast search of the matching LBL within a huge PB of 8 KB size. Since LBL number of 8 KB is much larger than 2K block number in a NAND-CAM of the present invention, more cycles to identify the matched LBL are required than identification of the matched block. Before searching the matched LBL is performed, a DRAM-like charge sharing read operation is performed to pass the 8 KB LBL sensed voltages to 8 KB SAs. As a result, the total time to find the matched LG, then the matched block, and the matched LBL line can be less than 100 In a specific embodiment, the ordering of Y-word search flow has to be strictly followed as explained above with LG-search first, Block-search second, and LBL-search lastly.

In another alternative embodiment, the present invention discloses an X-word search circuit with nLC Bit-matching and Bit-maskable Search functions configured for a matching nLC Word with a flexible length of bits per n MLs of a preferred nLC NAND-CAM array. For a SLC NAND-CAM array, n=1, thus single ML for 1-page comparison is required. For a MLC NAND-CAM, n=2, then 2 MLs for 2-page comparison are required. For a TLC NAND-CAM, n=3, 3 MLs are required. An XLC NAND-CAM requires 4 MLs. In a specific embodiment, the matching-word length extends in X-direction and all nLC storage forms are compatible with those NAND nLC array without using one paired BLs for storing two complementary nLC bit data.

In yet another alternative embodiment, the present invention provides a method for forming a plurality of capacitor-based DCRs in a NAND-CAM array. Fundamentally, each bit of DCR, C_{LG}, is a capacitor made of one broken LBL m0 or m1 metal line with a smaller parasitic capacitance over TPW in the NAND-CAM array. Furthermore, several C_{LG}s within each MG can be combined or connected to form one C_{MG} capacitor with a larger capacitance for a larger DCR in the NAND-CAM array. Each parasitic metal capacitor of each C_{LG} or C_{HG} is used as one-bit of a Dynamic CACHE Register (DCR). The shorter 8 KB C_{LG}-DCR is used for storing 8 KB page data for All-BL nLC program operation, while the longer 8 KB C_{MG}-DCR is preferably used for those Search, Read and Verify related operations required to perform the CS operation between one C_{MG} (C_{LBL}) and multiple C_{HG}s (C_{GBL}).

In still another alternative embodiment, the present invention discloses a method for forming a 2-level hierarchical BL structure of a NAND array with J m2 broken-GBL (Global-BL) lines and two interleaving broken m1 and m0 LBL (Local-BL) lines per each long column for performing many preferred batch-based low-power and fast operations. Each piecewise m2 GBL line represents one m2 C_{HG} capacitor being divided into J broken shorter m2 GBL lines, C_{HG}, by using J−1 Broken-GBL devices MGBL. Similarly, each broken HG with a C_{HG}, is further divided into shortest L MGs, C_{MG}, and each C_{MG} is further more divided by J′ broken LGs, C_{LG}, and each LG comprises H blocks and each block comprises of a plurality of strings including at least one with common SLs or at least one using adjacent BL as the SL. This preferred 2-level hierarchical broken LBL and GBL structure of a NAND-CAM array is optimized for performing a self-timed lengthy search operation that also flexibly allows the repeated interruptions by the regular nLC program and read operations simultaneously but with a higher priority.

In yet still another alternative embodiment, the present invention provides a method for forming a 2-level hierarchical broken BL-structure in which each C_{Column} parasitic BL line capacitance is preferably divided into J broken m2 GBL lines with equal or unequal size connected in series for J divided HG groups with J broken C_{HG}s. Each broken C_{HG} is further divided into J′ C_{MG}s connected in parallel to each GBL m2 layer. Furthermore, each m0 or m1 C_{MG} is even further divided into L broken m0 or m1 C_{LG}s connected in series. Therefore, a preferred concurrent and pipeline search operation of the present invention includes totally J′×J pages or WLs of J′×J C_{MG}s being performed simultaneously and collectively with a (J′×J)-fold speed improvement over prior art NAND-CAM.

In a specific embodiment, the present invention provides a method for dividing a HG1 group (a first HG nearest to the PB) into J′×J broken but even-length C_{MG}s in parallel to allow up to J′×J pages in HG1 to perform a faster search simultaneously with other C_{MG}s in the remaining J−1 C_{HG}s. The HG1 group is the nearest C_{HG} to the PB, having the least charge-sharing effect so that more WLs can be read concurrently with the C_{MG}s in the remaining J−1 HGs but be performed with charge-sharing in pipeline manner for a search and matching operation of this NAND-CAM. The latency of each charge-sharing operation is negligible relative to the latency of Read that involves the long RC of each C_{LG} and resistance R-string (about 1 Meg-ohm) of each NAND string during verify or read operations. For this preferred search operation, the search of each page is like to read one nLC WL from one selected block. Thus, the discharge of each C_{LG} with one preferred Vinh through each R-string is a bottleneck of read operation. This preferred hierarchical NAND-CAM array is compatible with the way of nLC storage but allows multiple WLs to be sensed or read on the same time. Thus, the Search function can be carried out on multiple selected WLs (e.g., M WLs) concurrently to cut the discharge time in M-fold.

In another specific embodiment, the present invention provides a method of maximizing page number of concurrent and pipeline search, read and verify operations by progressively reducing number of HGs from the highest one of HG1 with J×J′ MGs to the lowest one of HGJ with J′ MGs only. In an example, HG1 is the nearest HG to PB, while the HGJ is the farthest HG to PB as defined in this preferred hierarchical broken GBL and LBL NAND-CAM array. The C_{LG} precharged voltages can be progressively increased from Vdd in all C_{MG}s in HG1 to Vinh (≧7V) in all C_{MG}s in HGJ due to CS effect is progressively increased from HG1 to HGJ with the BVDS of all devices formed along Vinh signal path being made to sustain Vinh or Vinh(Vdd) with. Although the numbers of MGs in each HG are different, the length of J C_{HG} is kept the same. A maximum number of J×J′ XL C_{LG}s can be selected for a self-timed simultaneous or pipeline ABL 8 KB nLC page program for this NAND-CAM in principle of this preferred hierarchical broken GBL and LBL NAND-CAM array to achieve a big saving in nLC program latency.

In yet another specific embodiment, the present invention provides a method for using the CSL line as Matching line for Y-word search application. All CSLs are precharged with a Vinh, a value defined as Vdd≦Vinh≦5V, and all C_{MG} capacitors are floating at Vss voltage with the BVDS of all devices formed along Vinh signal path being made to sustain Vinh. When the whole NAND-CAM array is under Y-word search operation, one LBL will be matched to Y-word line, thus connecting one ML to one LBL line. Thus one ML of Vinh will be leaked to one LBL matched line with a voltage drop to be detected by a ML sense amplifier (ML-SA). Conversely, one matched line LBL voltage would be increased from floating Vss to about Vgs-Vte, where Vgs=0V and Vte=−1V of one paired complementary WLs' gate voltages. As a result, about 1V increment in one LBL line would be detected by each corresponding SA in each PB. Both LBL and ML detections can be done simultaneously but LBL voltage increase detecting will go through at least 2-cycle to identify the matched LBL. The final address of the matched BL and Block will be returned automatically with a very fast speed.

In still another specific embodiment, the present invention discloses another NAND-CAM that uses substantially zero silicon area overheads in search circuit because the conventional each ML-SA is replaced by each existing DCR, and each ML-ROM Encoder is replaced by the existing several-level Y-pass, Y-decoders, and the all WL direction CSL-ML lines are routed along BL direction to the predetermined DCR bits out of all bits of DCR.

### 4. BRIEF DESCRIPTION OF THE DRAWINGS

FIG. 1A is a simplified diagram of a conventional NAND block circuit of 2-dimensional mainstream NAND array architecture.

FIG. 1B is a simplified diagram of first two Vt distribution states of one SLC-based NAND-CAM cell according to an embodiment the present invention.

FIG. 1C is a simplified diagram of second four Vt distribution states of one MLC-based NAND-CAM cell according to an embodiment the present invention.

FIG. 1D is a simplified diagram of one conventional NAND-CAM block that stores N+1 Y-words extending in X-direction or WL-direction across the whole block.

FIG. 1E is a simplified diagram detailing a NAND-based CAM architecture according to a prior art.

FIG. 1F is a diagram showing conventional keys being written along bit lines of NAND array and searched.

FIG. 1G is a diagram of first two preferred Vt distribution states assigned for a NAND-CAM cell according to an embodiment of the present invention.

FIG. 1H is a diagram of first two preferred Vt distribution states assigned for a ROM CAM cell according to an embodiment of the present invention.

FIG. 1I is a diagram depicting a 1-cycle concurrent Y-word search through all blocks of a NAND-CAM array according to an embodiment of the present invention.

FIG. 2A is a block diagram of a hierarchical LG-based NAND-CAM array according to an embodiment of the present invention.

FIG. 2B is a block diagram of a hierarchical Block-based NAND-CAM array according to an embodiment of the present invention.

FIG. 2C is a block diagram of a hierarchical non-Block-based and non-LG-based NAND-CAM array according to an embodiment of the present invention.

FIG. 2D is a diagram of one LG group circuit of the hierarchical LG-based NAND-CAM array according to an embodiment of the present invention.

FIG. 2E is a diagram of one LG group circuit of the hierarchical Block-based NAND-CAM array according to an embodiment of the present invention.

FIG. 2F is a diagram of one block circuit of the hierarchical non-Block-based and non-LG-based NAND-CAM array according to an embodiment of the present invention.

FIG. 2G is a block diagram of a hierarchical LG-based ROM CAM array according to an embodiment of the present invention.

FIG. 2H is a block diagram of a hierarchical LG-based ROM CAM array according to another embodiment of the present invention.

FIG. 2I is a cross-sectional view of two preferred interleaving LBL metal lines used in each string and block as depicted in FIG. 1A within each LG of three NAND-CAMs shown in FIG. 2A, FIG. 2B and FIG. 2C of the present invention.

FIG. 3A is a simplified diagram of preferred memory divisions of this NAND-CAM array divided into 3 hierarchical broken GBL and LBL groups according to an embodiment of the present invention.

FIG. 3B is a simplified diagram of a detailed MG Multiplexer circuit as seen in FIG. 3A.

FIG. 3C is a simplified diagram of a detailed LG group circuit as seen in FIG. 3A.

FIG. 3D is a simplified diagram of a detailed ISO circuit as seen in FIG. 3A.

FIG. 4A is a diagram of a sense amplifier of Y-word searching circuit for LG-based searching operation according to an embodiment of the present invention.

FIG. 4B is a diagram of a sense amplifier of Y-word searching circuit for Block-based searching operation according to an embodiment of the present invention.

FIG. 4C is a diagram of a sense amplifier of Y-word searching circuit for Block-based searching operation according to another embodiment of the present invention.

FIG. 5A is a diagram of detailed circuits of a LG-ROM and LG-SAs for operating the preferred NAND-CAM of FIG. 2A under Y-word search in worst-case scenario.

FIG. 5B is a diagram of several key timing waveforms of Y-word search operation of the NAND-CAM of FIG. 2A in worst-case scenario.

FIG. 5C is a diagram of detailed circuits of a LG-ROM and LG-SAs for operating the preferred NAND-CAM of FIG. 2A under Y-word search in best-case scenario.

FIG. 5D is a diagram of several key timing waveforms of Y-word search operation of the NAND-CAM of FIG. 2A in best-case scenario.

FIG. 5E shows the timing simulation results associated with the current sensing scheme of LG-SA 138a as shown in FIG. 4A under adjusted voltage conditions for BIAS1, BIAS2, and BIAS3.

FIG. 5F is a diagram of detailed circuits of a BLK-ROM and BLK-SAs using each CSL as one ML for operating the preferred NAND CAM of FIG. 2B under Y-word search in worst-case scenario.

FIG. 5G is a diagram of several timing waveforms during Y-word search operation in the NAND-CAM of FIG. 2B for identifying matched block out of a matched paired-block according to an embodiment of the present invention.

FIG. 6 is a diagram of detailed circuits of Data Registers, SCRs, and Y-pass/ML Encoder, I/O Controller, and ISO circuit associated with NAND array block according to an embodiment of the present invention.

FIG. 7A is a diagram of a LBL search circuit with decoding output of BLSCH1 for identifying address of a single matched LBL of a NAND-CAM array according to an embodiment of the present invention.

FIG. 7B is a diagram of timing waveforms of several key control signals for performing the preferred LBL-Search operation in worst-case scenario according to an embodiment of the present invention.

FIG. 7C is a diagram of a LBL search circuit with decoding output of BLSCH8 for identifying address of a single matched LBL of a NAND-CAM array according to another embodiment of the present invention.

FIG. 7D is a diagram of timing waveforms of several key control signals for performing the preferred LBL-Search operation in best-case scenario according to an embodiment of the present invention.

FIG. 7E is a diagram of a 3-bit LBL-ROM encoder circuit for further narrowing down single matched LBL address after a matched byte is found by a Y-pass circuit according to an embodiment of the present invention.

FIG. 7F is a diagram of worst-case scenario timing waveforms for searching one matched LBL line according to an embodiment of the present invention.

FIG. 7G is a diagram of best-case scenario timing waveforms for searching one matched LBL line according to an embodiment of the present invention.

FIG. 8 is a diagram of a circuit of Block decoder associated with NAND-CAM array according to an embodiment of the present invention.

FIG. 9 is a diagram of eight Block decoders for a LG group of NAND-CAM and one shared self-timed delay control circuit according to an embodiment of the present invention.

FIG. 10 is a diagram of the self-time delay control circuit of FIG. 9 according to an embodiment of the present invention.

FIG. 11A is a flow chart illustrating a method for performing an operation of Y-word search with variable length according to an embodiment of the present invention.

FIG. 11B is a flow chart illustrating a method for performing an operation of Y-word search with flexible length according to another embodiment of the present invention.

FIG. 11C is a flow chart illustrating a method for performing an operation of Y-word search with flexible length according to certain embodiments of the present invention.

FIG. 11D is a flow chart illustrating a method of Y-word search with flexible length for searching matched LBL according to some embodiments of the present invention.

FIG. 11E is a flow chart illustrating a method of Y-word search with flexible length for searching matched block according to an embodiment of the present invention.

FIG. 11F is a flow chart illustrating a method for performing an operation of Y-word search with flexible length according to still another embodiment of the present invention.

FIG. 11G is a flow chart illustrating a method of Y-word search with flexible length for searching matched block according to another embodiment of the present invention.

### 5. DETAILED DESCRIPTION OF THE INVENTION

In the following detailed description of the present embodiments, reference is made to the previous pending utilities or provisional ones filed the same inventor and the following accompanying drawings that forms a part hereof, and in which is shown, by way of illustration, specific embodiments in which the disclosure may be practiced. In the drawings, like numerals describe substantially similar components throughout the several views. These embodiments are described in sufficient detail to enable those skilled in the ordinary art to practice the embodiments. Other embodiments may be utilized and any structural, logical, and electrical changes may be made without departing from the scope of the present disclosure. The following detailed description, therefore, not to be taken in a limitation sense.

As will be known in the subsequent detailed explanation, the goal of the present invention aims to dramatically improve all areas of mainstream NVM CAM, particularly nLC NAND-CAM in terms of search speed, search power consumption, flexible search word length, silicon area overhead and concurrent and pipelined nLC program and program-verify speed for NAND design node below 20 nm, regardless of 2D or 3D NAND manufacturing technologies.

Although many novel inventive techniques will be disclosed herein, the main theme of the present invention is to use a novel Hierarchical broken LBL and broken GBL nLC NAND array being divided into a plurality of LGs, MGs and HGs partial arrays along with a plurality of Block-based or LG-based MLs made by either conventional NAND-strings' CSL lines or the newly added LG-based LBLps lines to become a NAND-based CAM with a fast Y-word or X-word search function.

For a preferred Y-word search NAND-CAM of the present invention, the Y-word length is preferably made of a flexible number of paired complementary cells or bits formed in one paired WLs in series in one single BL. Practically, the length each NAND string is preferably formed by N paired complementary NAND cells in series with one top and one bottom select transistors. The nLC cells in each NAND-CAM string can store the SLC data when n=1 or store MLC data if n=2 to further increase the NAND-CAM density by 2-fold.

Since NAND density has been increased to near 1 Tb per die with a Read speed much faster than the traditional mechanical disk drive at lower power consumption, all NAND storage solution has gained more acceptances and footprints in data center, server and network applications. As a result, a NAND-based CAM to provide a faster, cheaper cost, lower-power Search function becomes extremely important to replace the traditional costly DRAM-based or SRAM-based CAM with a density limitation. As will be known subsequently, the disclosed NAND-based CAM of the present invention can even achieve the less latency in search speed than the counterparts of SRAM CAM or DRAM CAM with the dramatic die cost reduction.

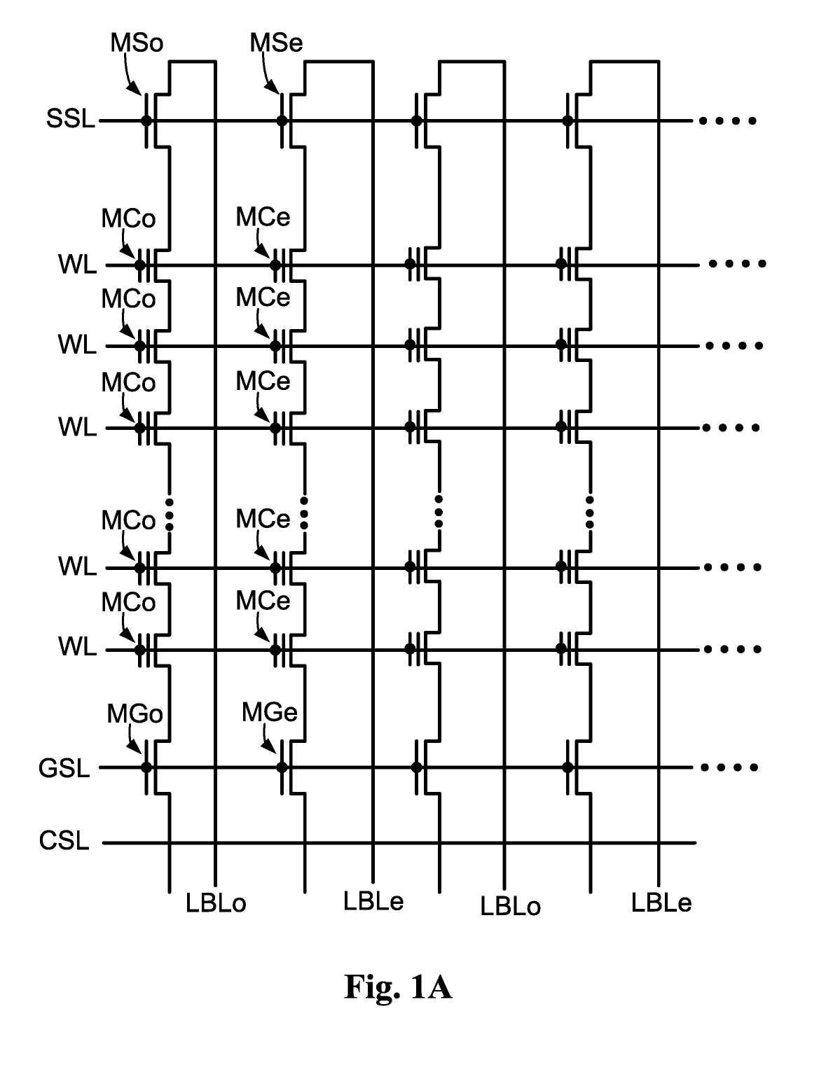

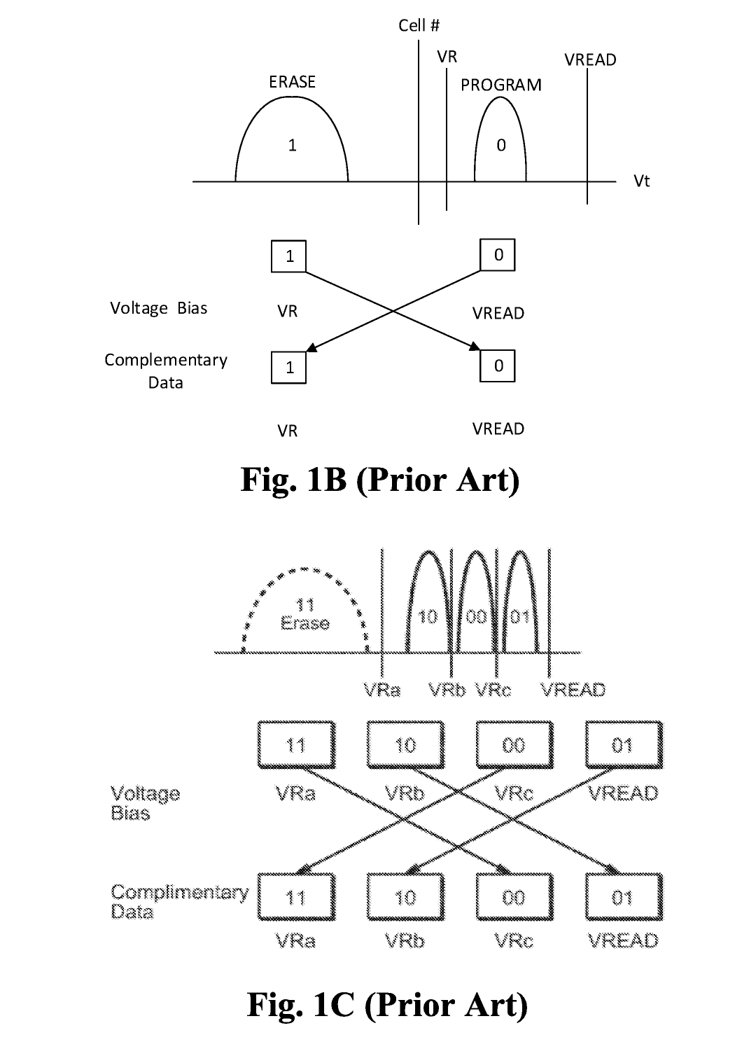

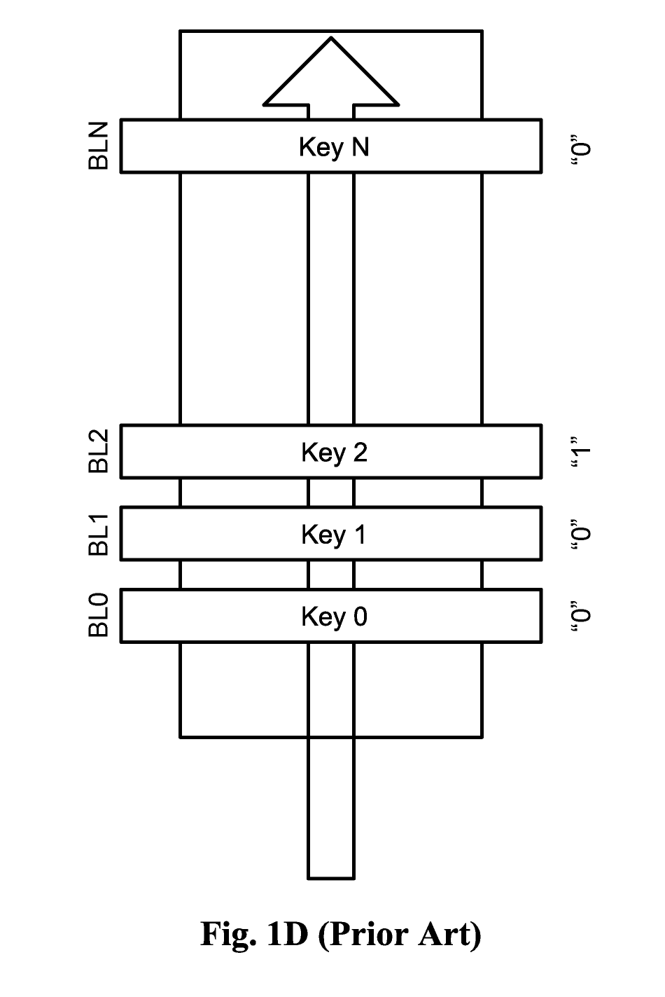

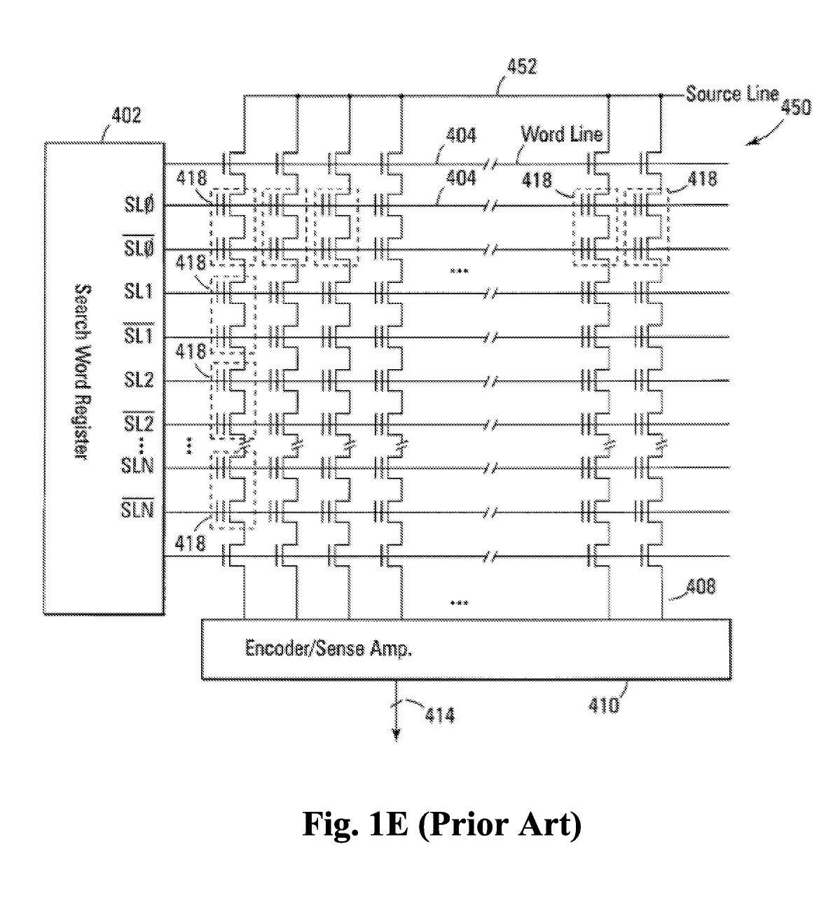

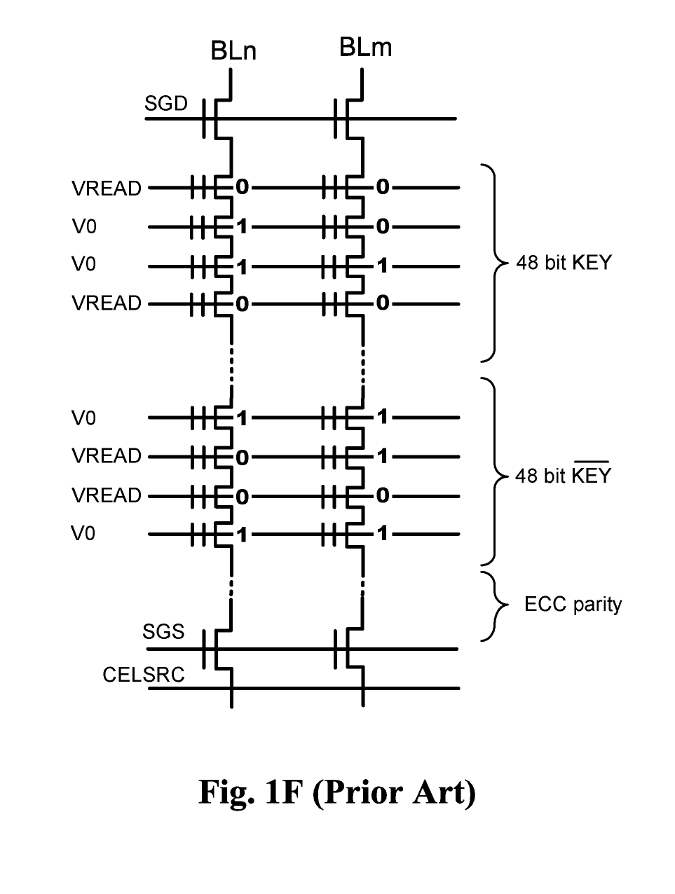

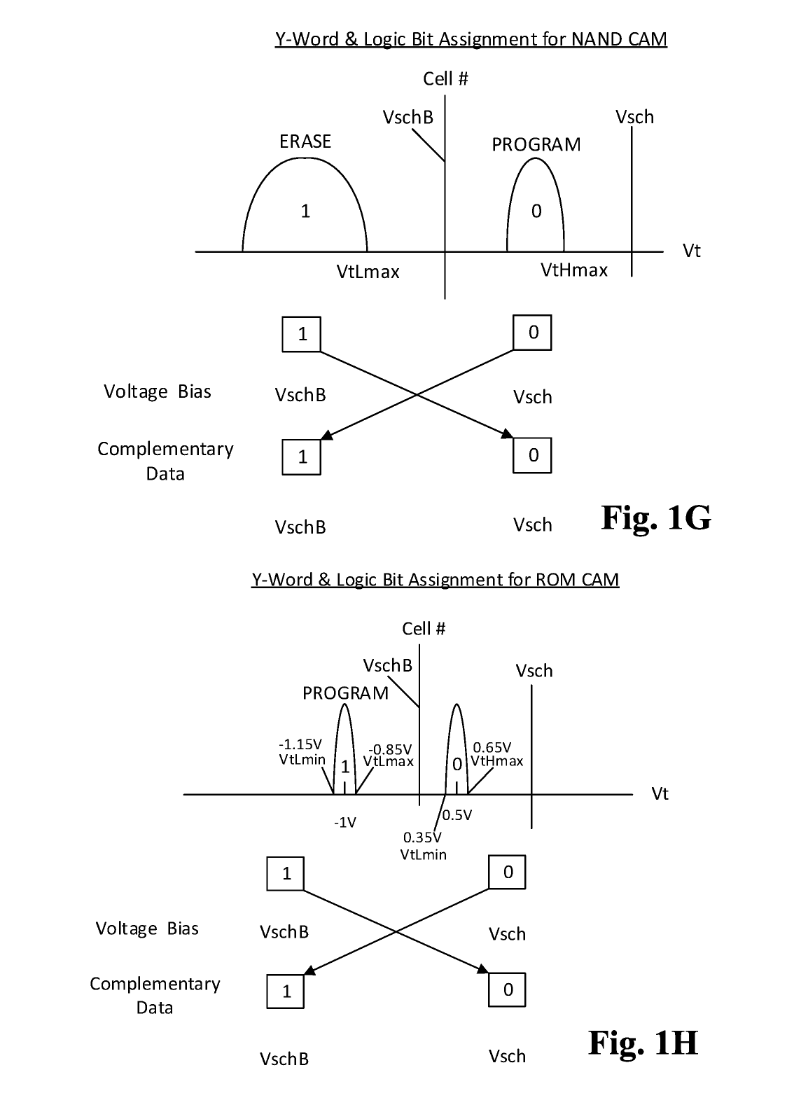

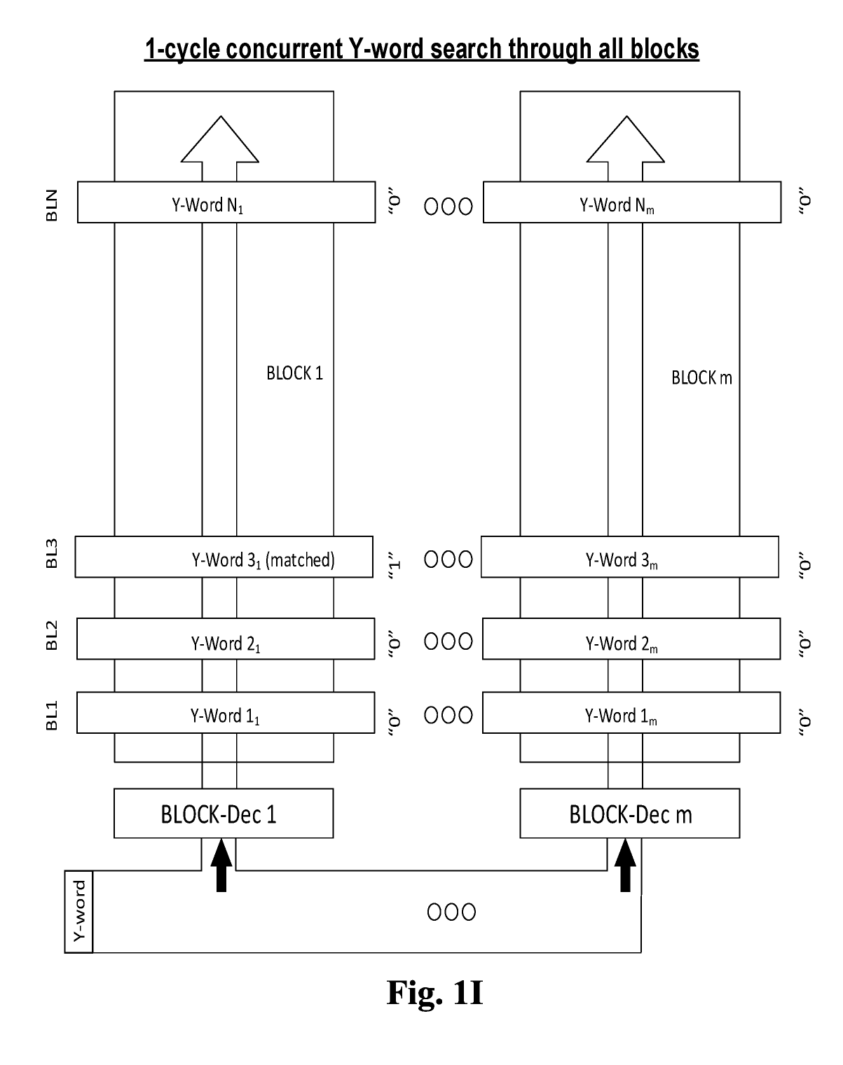

Although the description of the following disclosed examples are based SLC NAND-CAM, which stores one digital bit per one NAND cell, multiple embodiments on NAND-CAM array architecture and operation techniques used by the SLC NAND-CAM can be extendedly used as well by the MLC NAND-CAM of the present invention as long as the values of cell's Vt assignments of complementary SLC and MLC codes following the guidelines defined in FIGS. 1B and 1C.

Besides the disclosed search circuits, search schemes and operation flows for this NAND-CAM, the nLC program and program-verify operations of NAND-CAM also are dramatically improved in operation speed by using the batched-based multiple-WL, ABL-program and ABL-program-verify scheme of the present invention. A virtual Y-PB is also disclosed using the parasitic poly line capacitors of SSLs, GSLs, and WLs in each NAND block to temporarily store the flexible-length of Y-word search without taking any extra physical silicon area overhead.

Furthermore, the examples below are 2D NAND-CAM. But the same techniques can also be used in 3D NAND-CAM when 3D NAND array are also being configured similarly into the hierarchical broken LBL and broken GBL NAND array with a plurality of LGs, MGs, and HGs and MLs made of CSL and LBLps lines.

The description of the preferred batch-based SLC NAND pipeline and concurrent operations of whole patent is being organized starting from random page and partial or full block SLC Erase, SLC Erase-Verify, SLC ABL pipeline Program, and SLC ABL-like Read optimized with V_{LBL} voltages of Vinh and Vss.

FIG. 1A is a simplified diagram of a conventional NAND block circuit of 2-dimensional mainstream NAND array architecture. As shown, one typical portion of a mainstream NAND memory block circuit is provided with a scheme of 1-level bit line (BL) and one common source line (CSL) per block under a conventional 2D NAND array architecture. A comparable 3D NAND block comprising of similar NAND strings with identical 1-level BL and CSL scheme is also applicable.

Both 2D and 3D nLC NAND strings in prior art have a plurality of CSL lines and each of it is shared by two adjacent blocks typically for read and program operation. This basic NAND string structure has n NAND cells connected in series with one select transistor with its gate connected to a GSL signal and another select transistor with another gate connected to a SSL signal.

Each block comprises a plurality of NAND strings with their individual drains nodes connected to a plurality of BLs. The plurality of BLs are divided into interleaving Even BL group of BLe and Odd BL group of BLo to respectively connect to Even string of NAND cells MCe and Odd string of NAND cells MCo. Additionally, the source nodes of the plurality of NAND strings are connected to one CSL. The gates of two select transistors and n2 NAND cells in all strings are respectively connected to n2 different WLs, a GSL, and a SSL lines. Each NAND string, in certain embodiments, also includes several dummy NAND cells sandwiched by top and bottom select transistors, where n2 can be 8, 16, 32, 64, 128 or any other integer numbers. The dummy NAND cells are formed in series with the regular NAND cells near two select transistors at two ends of the NAND string to avoid GIDL effect that results in higher Vt of NAND cells of top and bottom WLs.

In the conventional NAND block, the tight 1λ-width and 1λ-spacing of all BLe and BLo metal lines (at m1 layer) are laid out in parallel in Y-direction and are perpendicular to all CSLs (laid in lower m0 layer) in X-direction. The BLs and CSLs are laid out to use two different metal layers. A very long BL laid at one level, either BLe or BLo line, connects all NAND blocks without being divided. This conventional NAND-CAM array with 1-level BL structure has a long and heavy BLe and BLo m1 capacitance suffering a highly interleaving BL coupling effect below 20 nm node.

A method for programming and reading nLC cells in the NAND array is referred as All BL (ABL) program and read. In this method, all nLC 16 KB NAND cells in all strings along each selected physical WLn are programmed and read at same time at expense of using large size Page Buffer (PB) of 16 KB and Static CACHE Register (SCR) of 16 KB. The number of the PB bits is same as the number of cells formed in each physical WL for ABL program and ABL read operation, making the operation a costly solution. Another method is called as Odd/Even-BL or shielded BL (SBL) read and program. In this method, only SLC cells associated with half of all BLs in each physical word line (WLn), belonging to either Odd-BL group or Even-BL group, are selectively programmed and read at same time with a benefit of using a smaller 8 KB PB, of which is only ½ of the PB bit size in ABL counterpart. Each bit of PB is connected to one GBL line, but the GBL line is split to two LBL lines respectively connected to two bits of SLC cells through one Odd/Even column decoder.

However, there are some penalties of the second method as summarized below: 1) 2-fold latency of read and program operations slows down the performance of NAND and NAND-CAM; 2) 2-fold high voltage gate disturbance degrades P/E endurance cycle and data reliability of NAND and NAND-CAM products; 3) 2-fold power consumption of read, program and verify is caused due to 2 times of half-page access operations. In other words, the ABL method has superior SLC and MLC performance and reliability over Odd/Even-BL method but with a penalty of 2× area size in PB and SCR.

Furthermore, each of all lines of GSL, WLs, and SSL is made of a long poly or metal lines in one layer which has a high parasitic capacitance. All these lines in one block are correspondingly connected to one set of common supply lines of SSLP, GWLs, and GSLP during whole period of program, read and verify operations without disconnection, regardless of 2D or 3D NAND flash or NAND-CAMs.

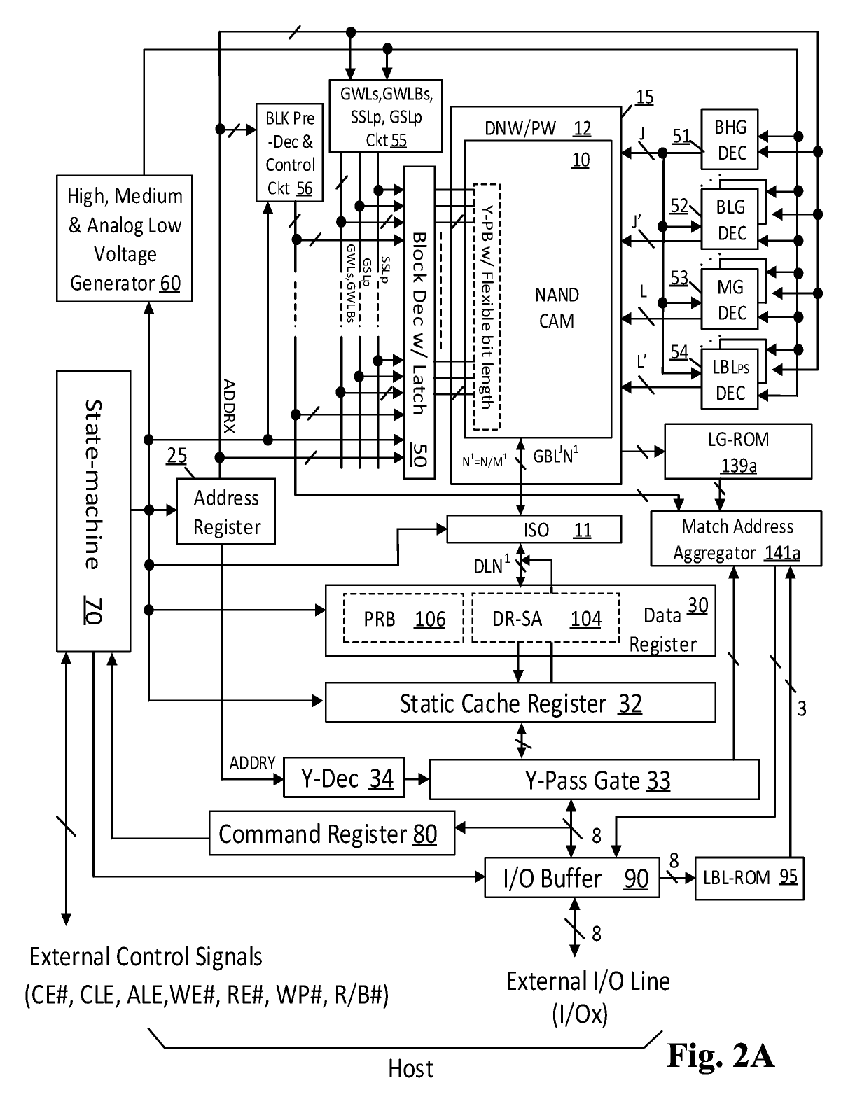

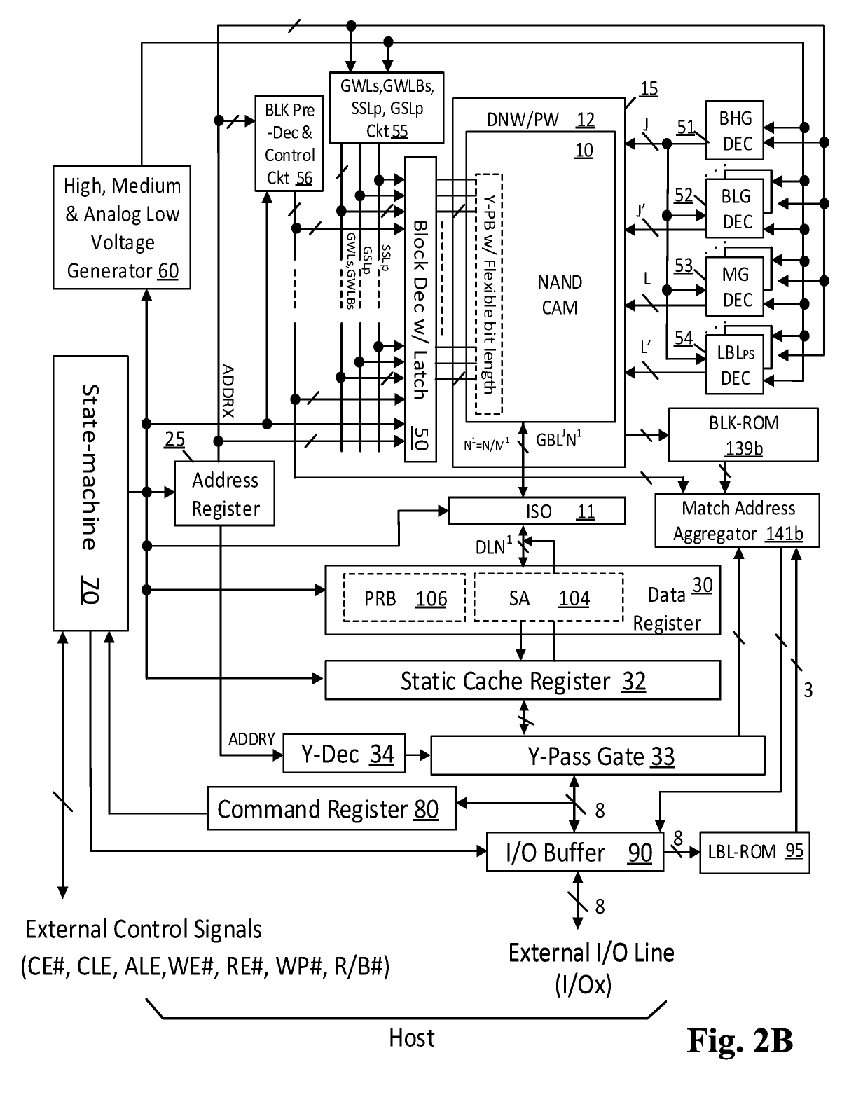

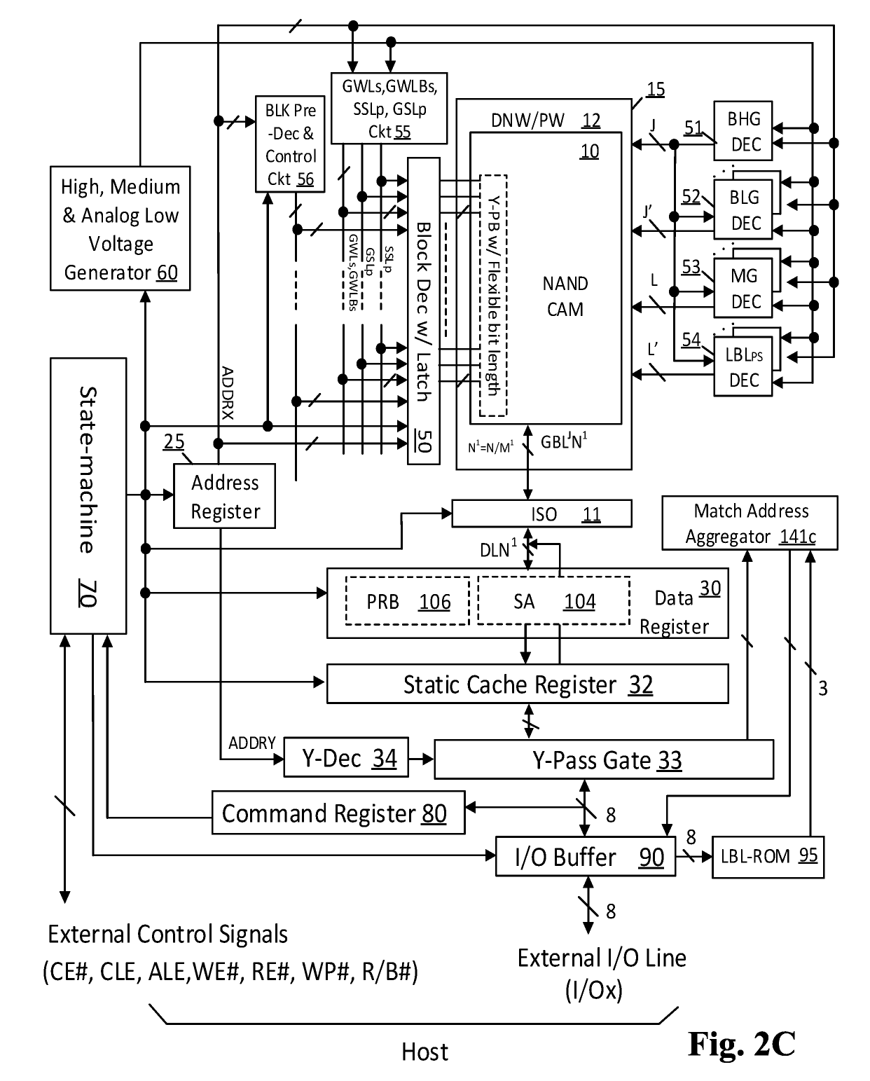

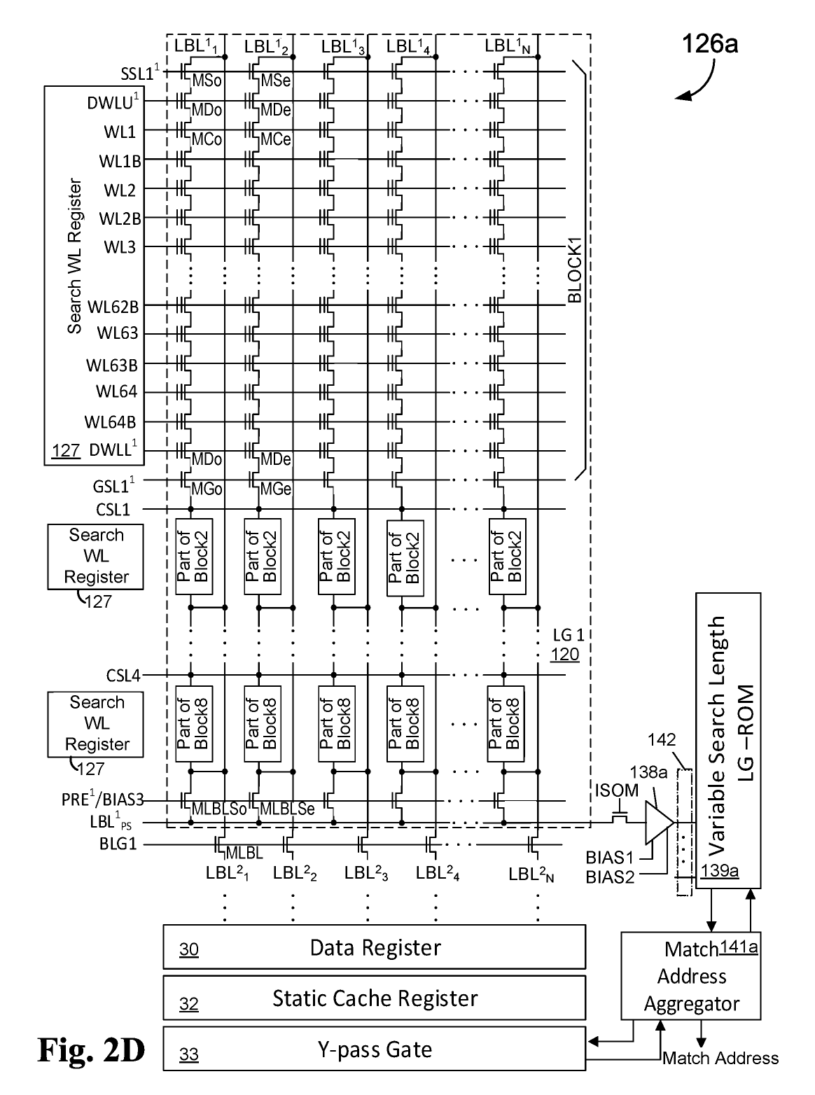

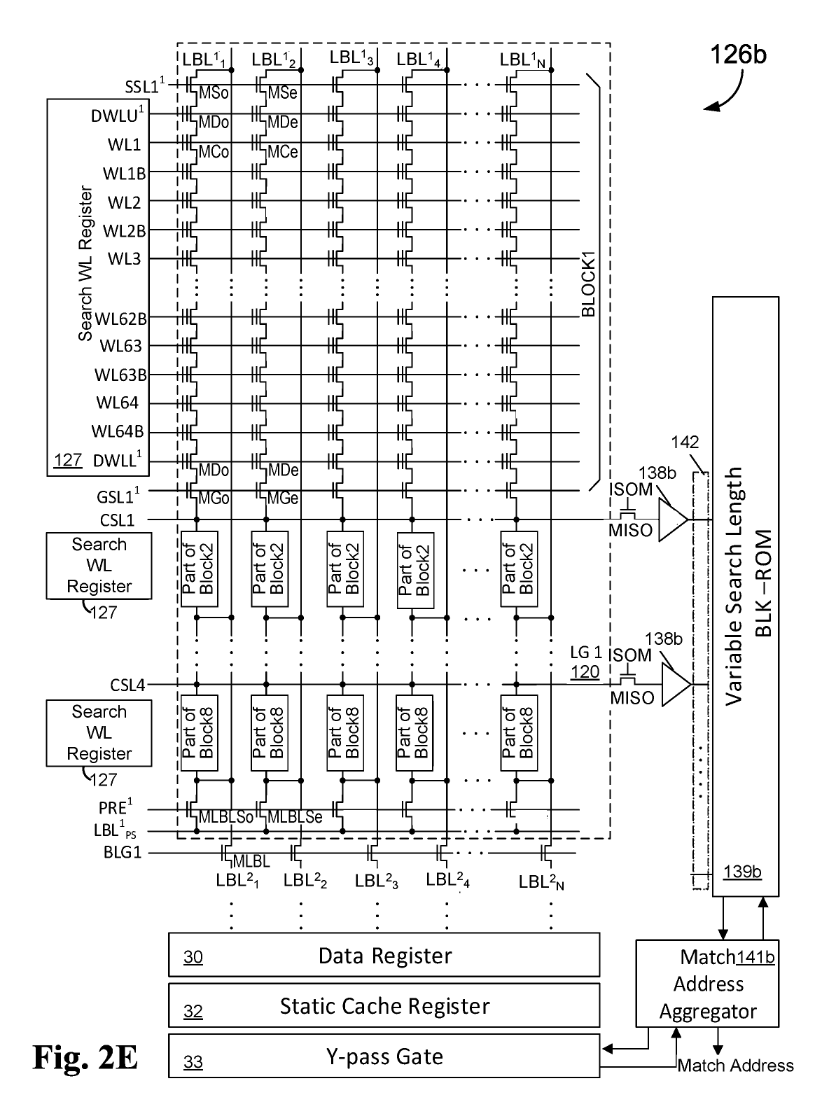

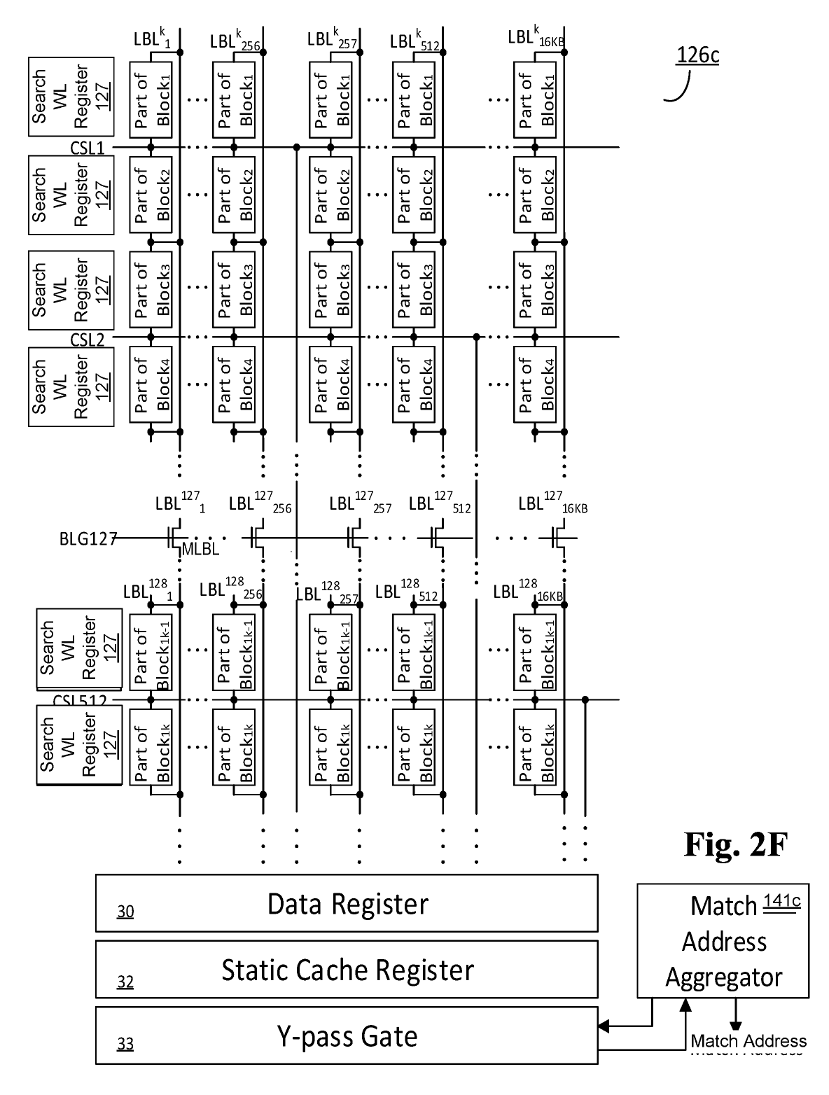

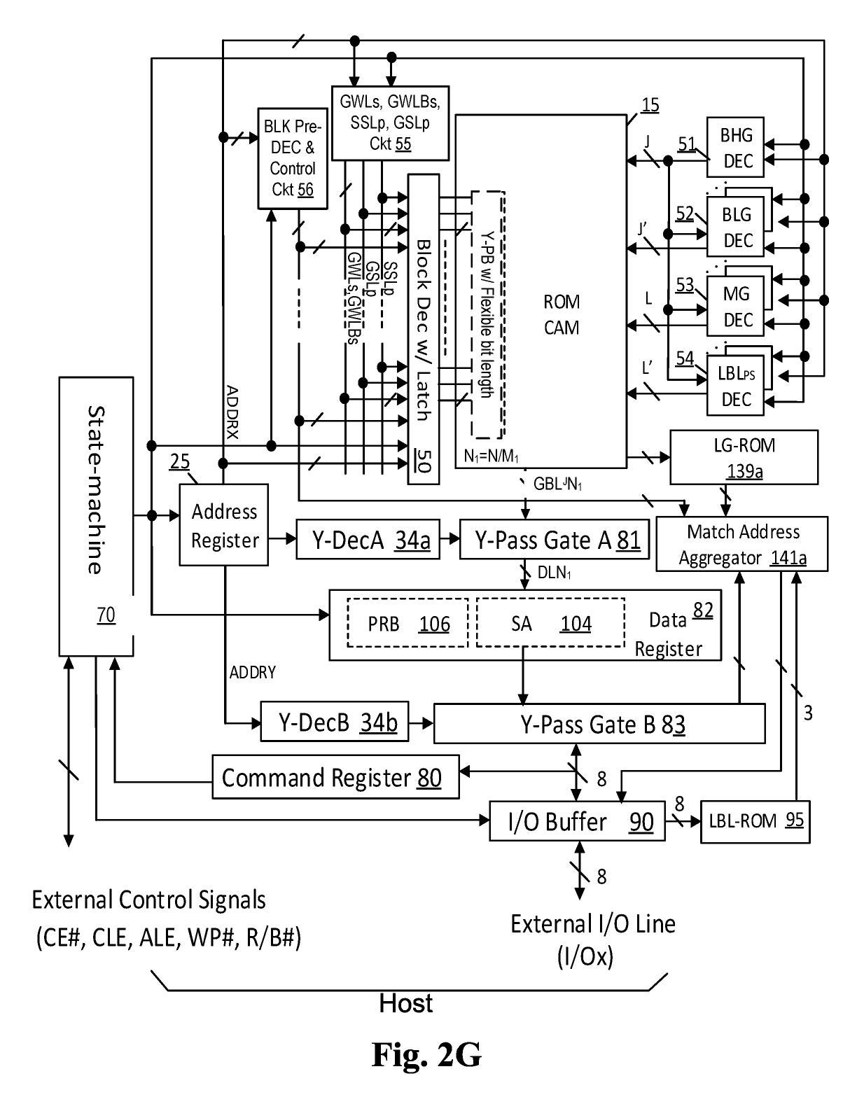

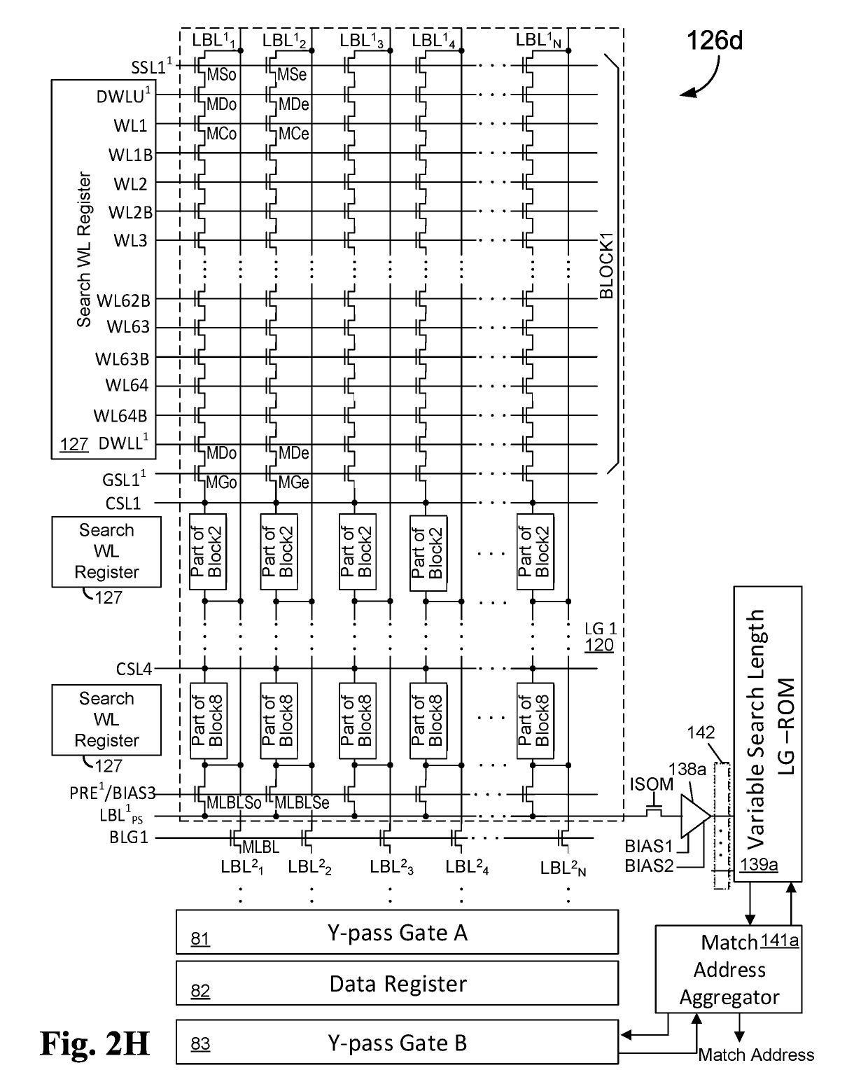

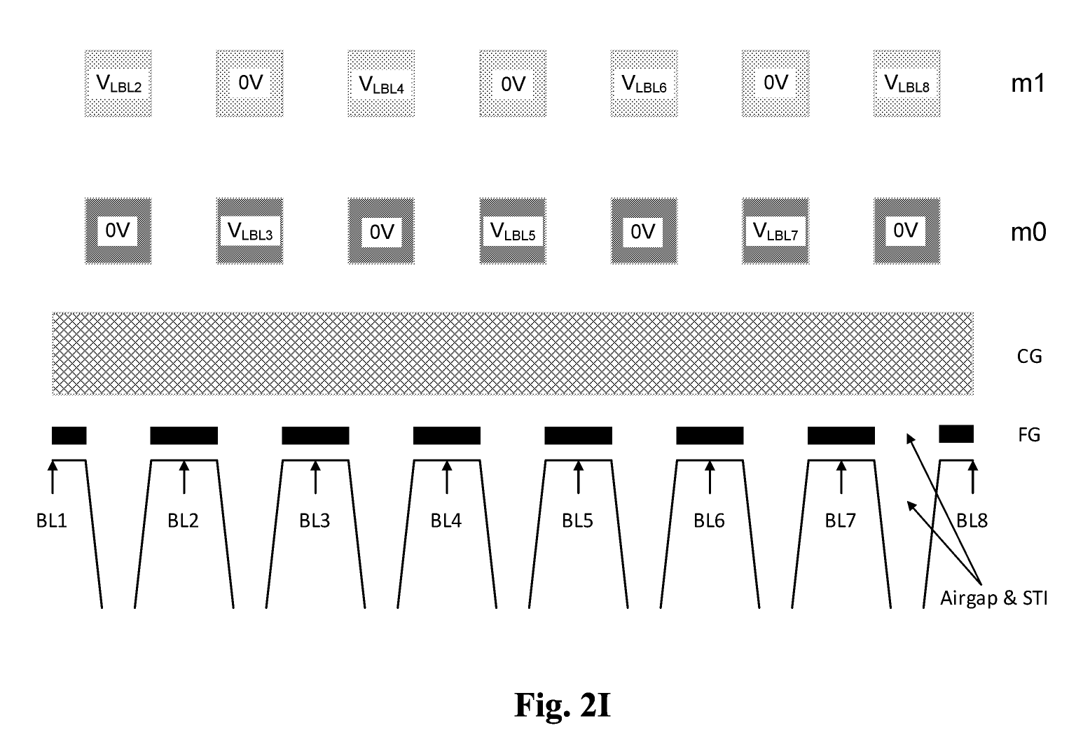

Throughout the specification of the present invention, in certain embodiments, a truly BL-shielding technique is proposed to use two interleaving m0 and m1 broken metal lines as two LBL lines (see below in FIG. 2G) for operating an improved 2D or 3D nLC NAND-CAM array architecture a PB size of only ½″ of original size, where n is an integer ≧1. In addition, the large parasitic capacitances of DSL, SSL, and WLs are used as on-chip capacitors of a preferred Y-PB to temporarily store Y-word data with Vread or 0V during search operation, or Vpgm, Vpass, Vdd, Vss during nLC ABL program operation, or Vread, Vdd, and Vss during nLC concurrent and pipeline program-verify operations in batched-based concurrent and pipeline manner to reduce the latency by M-fold, where M is determined by the total number of WLs being simultaneously program and read at a time. More details of the embodiments are shown below.

FIG. 1B shows two preferred Vt distribution states of one SLC-based NAND-CAM cell of the present invention. As shown, an Erase state with a Vt below 0V stores a binary digital data denoted as “1” and a Program state with a Vt above a VR voltage storing another digital data denoted as “0”. The complimentary Vt assignment of SLC data is used by the present invention and prior art as well. During a NAND-CAM search operation, both predetermined VR and V_{READ} voltages are applied to each paired WLs that stores each paired complementary data bits when a Y-word matching search scheme is used.

The way of two SLC Vt state assignments of this NAND-CAM design are similar to regular NAND SLC design in terms of bias condition of program, program-verify, and erase operations but one paired Vts representing one bit only of Y-word (U.S. Pat. No. 8,773,909). The disadvantage of V_{READ} assignment is that it is a HV of around 4V and is greater than Vdd. As a result, when a search operation is performed simultaneously on more blocks of the NAND-CAM, it consumes extremely high power energy and slows down the whole chip search operation.

FIG. 1C shows four preferred Vt distribution states of one MLC-based NAND-CAM cell of the present invention. These four Vt distribution states include an Erase state with a negative Vt below 0V for storing a binary digital data denoted as “11”, a first Program-state with a small positive Vt above a VRa voltage but below a VRb voltage for storing another digital data denoted as “10”, a second Program-state with a medium positive Vt above the VRb voltage but below a VRc voltage for storing another digital data denoted as “00”, and a third Program-state with a highest positive Vt above the VRc voltage but below the V_{READ} voltage for storing another digital data denoted as “01”. The complimentary data assignments for MLC-based NAND-CAM cell are shown and used by prior art as well (U.S. Pat. No. 8,773,909).

The MLC-based NAND-CAM can store 2-fold matching words over the SLC-based NAND-CAM at the expense of lower search data quality due to a narrower Vt gap between for adjacent MLC states.

FIG. 1D shows a simplified diagram of an exemplary conventional NAND-CAM block that stores N+1 vertical Key words (Y-words) including Key 0, Key 1, and Key N extended one by one in X-direction or WL-direction. Each Y-word with a bit length of ½ of total number of NAND cells connected in series in a physical string of the NAND-CAM. The Y-word search can be done in a block-based matching operation in one cycle and only one bit line BLn storing the matched key data will result in a conducting cell current with a digital data of “1” shown in each corresponding SA in corresponding bit PB. In the example of FIG. 1D, BL2 is the single matched BL storing one digital data of “1” in the corresponding PB bit, while the remaining BLs do not conduct cell current and will store “0”.

In an embodiment of the present invention, the search of Y-word with one block length can be performed on the basis of one-block by one-block scheme or simultaneous multiple blocks scheme. The maximum Y-word search speed can be done on one half of the conventional NAND CAM array when one shared CSL-ML matching line scheme per two physically adjacent blocks is employed.

FIG. 1E depicts another conventional NAND-CAM block circuit (U.S. Pat. No. 8,169,808). It shows (N+1)-paired complementary bits of Y-word search including a first pair of complementary bits of SLO and SLOB to a last pair of complimentary bits of SLN and SLNB respectively connected to corresponding N+1 pairs of WLs of each NAND-CAM string extended vertically in Y-direction or BL-direction across whole block with a horizontal common source line 452 and one Encoder/Sense Amplifier 410. As shown, one Search Word Register 402 with a sizable physical silicon area outside the NAND-CAM array to store N+1 paired matching bits is used. In this Y-word search scheme, a current starts to flow between the common source line 452 and corresponding bit of one Encoder/Sense Amplifier 410 when N+1 paired bits of NAND string match with N+1 paired bits of Y-word. But in a NAND-CAM array with a plurality of blocks sharing with a plurality of long BLs, the block that matches with the Y-word bits requires a daisy-chain circuit (not shown here). As shown, a Search Word Register 402 with a sizable physical silicon area is used to store N+1 paired matching bits. The CSL 452 is a power supply line and Encoder/Sense Amp 410 is formed on one-block or multiple blocks. In the left, a real physical circuit of Search Word Register 402 is formed on block base. In other words, one Search Word Register per block is used in the NAND-CAM array. Thus it takes a large real silicon area.

FIG. 1F depicts yet another conventional NAND-CAM (U.S. Pat. No. 8,773,909) that uses similar Y-word matching scheme. It also shows a plurality of paired vertical complimentary Y-word Key bits being respectively connected to N pairs of complementary WLs' digital data of “0” and “1” of each string extending vertically in Y-direction or BL-direction across each block with a horizontal common source line CELSRC between two physically adjacent NAND-CAM strings, where N=48. As shown, two WLs' complementary voltages of V0 (a LV of Vt_{L}) and VREAD (a HV of Vt_{H}) are assigned for two 48-paired keys with few extra rows of ECC WLs. Here, V0 voltage is equivalent to the VR as used in FIG. 1B. The conventional SLC NAND-CAM uses V0 and VREAD voltages for Y-word search, where VREAD is a HV with a value of around 4V that is disadvantageously greater than Vdd, e.g., VREAD>Vdd. The requirement of the HV VREAD in the Y-word search operation will need a HV pump circuit in each Block-decoder in active mode all the time during the whole search operation, As a result, more power consumption is required yet giving a slower search due to the pump of VREAD on WLs or WLBs.

Again, in Y-word search scheme, only one NAND-CAM string will match the Y-word, thus conducting cell current between the matched BL (such as BLn or BLm) and the common CELSRC line. The matched BL means the SLC Vt assignments stored in each 48-bit KEY and each 48-bit complementary KEYB data matches with the 48-paired complementary bits of one Y-word that are applied on 48 paired WLs and WLBs along with SGD and SGS. This Y-word search operation can be performed only on one block by one block basis with 50 μs per one block search. For searching through 2K blocks in a whole NAND-CAM, it totally takes about 100 ms, which is too slow. When number of blocks is increased proportionally to the density increase of a NAND-CAM density in the future, the search latency will be increased accordingly. Thus an improvement to shorten the search latency of NAND-CAM is very much desired.

FIG. 1G shows two preferred SLC Vt distributions assigned with two LV Vt voltages for both Erase and Program states of one SLC-based NAND-CAM cell according to an embodiment of the present invention. This diagram is merely an example, which should not unduly limit the scope of the claims. One of ordinary skill in the art would recognize many variations, alternatives, and modifications. As shown, the two Vt states include an Erase state assigned with a negative lower Vt_{L} and its maximum Vt_{Lmax} smaller than a VschB voltage by a margin of ˜0.5V margin, storing a binary digital data denoted as “1” and a higher Program-state assigned with a positive Vt_{H} and its minimum Vt_{Hmin} above the VschB by a margin of ˜0.5V but below a Vsch voltage with a similar margin of 0.5V, storing another digital data denoted as “0”. As summarized for 1.8V Vdd operation, Vt_{Lmax}≦−0.5V, Vt_{Hmin}≧0.5V, Vt_{Hmax}≦0.8V, Vddₘᵢₙ=1.6V for 1.8V Vdd, VschB=0V, and Vsch=1.6V. The lower portion of FIG. 1G shows a complimentary assignment of SLC data of Logic “0” and Logic “1” as distinguished by Vsch and VschB opposed to the higher V0 and HV of V_{READ} (>Vdd) used by the conventional NAND-CAM in Y-word search operation.

During this preferred LV NAND-CAM search operation, both the predetermined LV VschB and Vsch voltages are applied to pair of word lines WL and WLB that store two complementary data bits of each matched word when a Y-word search scheme is used. One lower SLC Vt state assignment of “1” below Vt_{Lmax}<VschB and one higher SLC Vt assignment of “0” below Vt_{Hmax}<Vsch of this NAND-CAM design are both set less than 1.6V so that a LV 1.8V-Vdd search operation can be performed without pump. These two preferred LV SLC Vt_{L} and Vt_{H} are programmed under the preferred batch-based multiple SLC ABL concurrent program and verify scheme to allow the LV voltages of VschB and Vsch below Vdd to be applied respectively on WL and WLB or vice versa with at least 0.5V margin for a low voltage, low power Y-word search operation performed on whole NAND-CAM in one cycle.

In an embodiment, the maximum voltages that can be passed from source to drain or from drain to source of each NAND string is fully determined by the minimum value of ΔV generated by three following conditions of Vgs−Vt: a) VschB−Vt_{Lmax}=ΔV1=0V−(−0.5V)=0.5V; b) Vsch−Vt_{Hmax} ΔV2=1.6V−0.8V=0.8V; c) VSSL−Vt=VGSL−Vt=ΔV3=Vddₘᵢₙ−Vt=1.6V−0.5V=1.1V. Thus the maximum voltage that can be passed between drain and source of each NAND string is determined by ΔV1=0.5V for this Y-word search.

FIG. 1H shows two preferred Vt distribution states assigned with lower voltages of one SLC-based NAND-CAM cell using a 1-poly NMOS ROM cell according to another embodiment of the present invention. This diagram is merely an example, which should not unduly limit the scope of the claims. One of ordinary skill in the art would recognize many variations, alternatives, and modifications. The detail of the NAND-CAM circuit will be shown below and is referred as ROM CAM through the specification. As shown, similar to previous embodiment, two Vt states include a lower Program state Vt_{L} with a preferred negative center value of −1V with its maximum Vt_{Lmax} below the VschB with at least 0.85V margin by a “Phosphorus implant” for storing a binary digital data denoted as “1” and a higher state Vt_{H} with a preferred positive center value of 0.5V above the VschB with a margin at least 0.65V but below the Vsch with a similar margin of 0.55V during an extremely low-voltage 1.2V Vdd operation for storing another digital data denoted as “0”. This Vt_{H} state is the result of a regular Enhancement NMOS transistor used for peripheral NMOS device as well as the desired ROM cell with “0”, thus no extra Vt implant is required.

The lower portion of FIG. 1H shows a complimentary assignment of SLC ROM data of Logic “1” and Logic “0” as distinguished by the LV VschB and Vsch voltages opposed to the higher V0 value and HV V_{READ} (>Vdd) used by conventional NAND-CAM in Y-word search operation. During this ROM CAM search operation of the present invention, both the predetermined LV VschB and LV Vsch voltages are applied to each paired WLs and WLBs that store each Y-word's two complementary data bits in conventional NAND-CAM. The values of two lower SLC Vt state assignments of Vt_{L} and Vt_{H} and two LV search gate voltages of VschB and Vsch makes an extremely low-power ROM CAM search operation. In an example, VschB=0V and Vsch=1.2V.

Particularly, when all (up to thousand) blocks of the ROM CAM are under the simultaneous search operation, the above novel assignments of the paired LV VshB and Vsch voltages and Vt_{H} and Vt_{L} values can substantially reduce power consumption. In another embodiment of the present invention, with two more additional Boron implants for two positive Vts with one Phosphorus implant for a negative Vt, a 4-state ROM CAM circuit can also be formed as a MLC NAND-CAM.

FIG. 1I is a diagram showing one 1-cycle concurrent Y-word search through all blocks of a whole NAND-CAM array according to an embodiment of the present invention. The same all-block concurrent Y-word search scheme can also be applied to a LV ROM CAM in an alternative embodiment of the present invention. In an embodiment, the whole NAND-CAM (or ROM CAM) chip includes m blocks and each block further includes N NAND strings that store N Y-words with same fixed physical length of 64 complimentary bits (other number of bits are possibly used). Each bit is connected to one local capacitor C_{LBL} or C_{LG} that stores the voltage results of Y-word search message such as “matched” one with a “Logic-low” or a string conducting and an “unmatched one” with a “Logic-high” or a string non-conducting in each Y-word string. In this example, m=1,024 and N=16 KB.

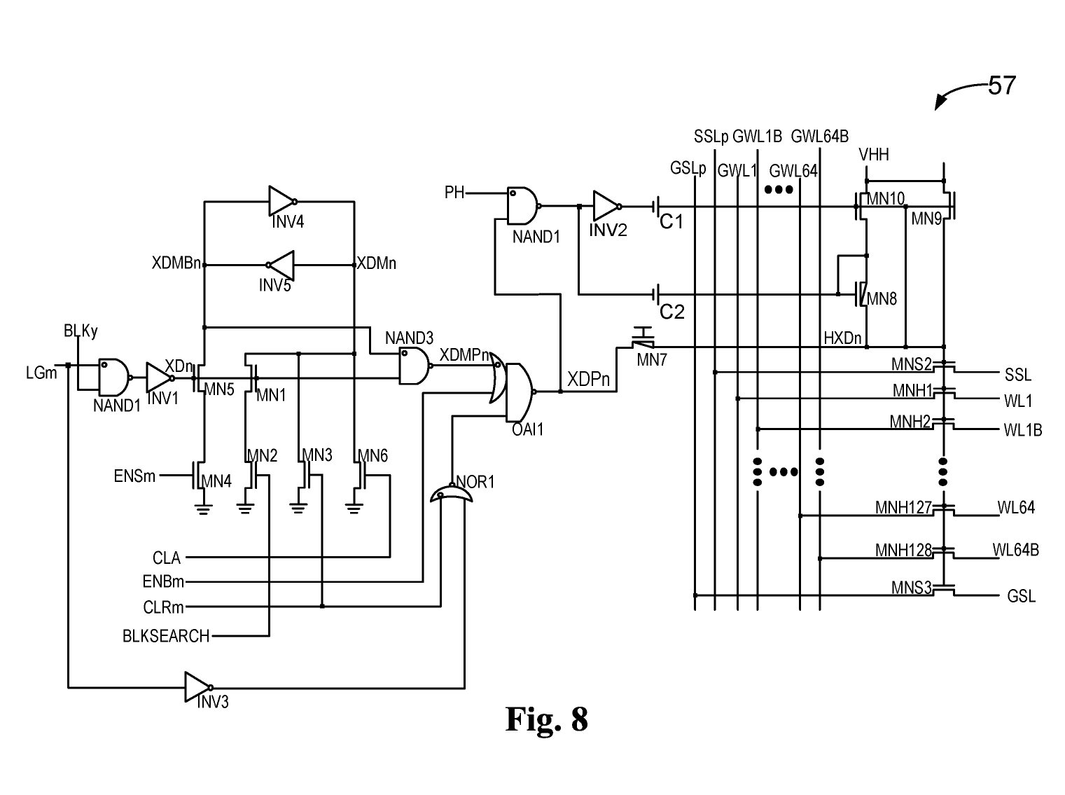

As opposed to the conventional NAND-CAM array using off-array Y-word register taking large silicon area, each Y-word in N-paired complementary bit data voltages are preferably stored and locked in parasitic capacitors associated with the poly lines WLs, WLBs, SSL, and GSL of corresponding blocks. The locking of LV Vsch and VshB voltages on the WLs, WLBs, SSL, and GSL lines of each block can be done by a novel latch designed in each Block-decoder as disclosed in FIG. 8 of this application (see description below).

Unlike prior art where only one block is selected at a time for performing Y-word search, in the present invention all m NAND blocks are selected simultaneously for performing a preferred 1-cycle concurrent Y-word search operation. Particularly, Y-word search inputs to a set of gate lines of 1 SSL, 64 paired complimentary WLs, and 1 GSL of each of the m blocks are respectively connected to one common Y-word with same block length of 1 SSLp, 64 paired complimentary GWLs, and 1 GSLp lines through m block-decoders.

In an embodiment, m sets of LV Y-word search voltages VschB and Vsch applied on corresponding m sets of gate lines of 1 SSL, 64 paired complimentary WLs, and 1 GSL can be either directly connected to above said one common set of voltages in 1 SSLp, 64 paired complimentary GWLs, and 1 GSLp bus lines with all m block-decoders being kept in on-state or locked in a preferred Y-PB's parasitic poly2 capacitors with all m block-decoders being kept in off-state. The details of operation will be disclosed in subsequent sections of the specification. When Y-word length is equal to or less than one block, then all 1,024 blocks can still be loaded with 1-block Y-word in 1 cycle simultaneously with dummy paired bits of Vsch like “Don't-care bits” because the bus lines of GWL, SSLp, and GSLp is physically kept 1-block wide without change.

When Y-word length is equal to or less than 2 blocks, then all 1,024 blocks can be loaded with block-based 2-block Y-word in 2 cycles. For example, all 512 Odd blocks can be loaded and locked first into first 512 Y-PBs with 1-block length of Y-word, and all remaining 512 Even blocks can be loaded and locked with another 1-block length of Y-word into second 512 Y-PBs by properly opening Odd and Even Block-decoders controlled by on-chip State-Machine design.

Additionally, when Y-word lengths are more than 2 blocks it can be done on the same way but requiring more block-based loading cycles. As a result, a flexible length of block-based Y-word can be loaded sequentially and locked into the dynamic poly-parasitic-capacitor-based Y-PBs of this NAND-CAM in several sequential cycles proportionally to the Y-word length in units of block. All Y-word lengths more than 1-block size have to be loaded and locked into corresponding Y-PBs for subsequent whole NAND-CAM search operation in 1-cycle. In the embodiment, each block has one block-decoder with inputs connected to GWLs and GWLBs with a Latch circuit to allow the LV of Vsch and Vsch be supplied and retained. The details of the Y-word search operation will be given subsequently.

FIG. 2A is a block diagram of a hierarchical LG-based NAND-CAM array according to an embodiment of the present invention. This diagram is merely an example, which should not unduly limit the scope of the claims. One of ordinary skill in the art would recognize many variations, alternatives, and modifications. As shown, in a first embodiment of a hierarchical broken-LBL and broken GBL NAND-CAM chip is provided with a NAND cell array 10 being configured by a plurality of groups denoted as HGs, MGs, and LGs (not explicitly shown) respectively associated with group-dividing controllers BHG-dec 51, BLG-dec 52, and MG-dec 53, a Block-decoder with a latch circuit 50, a LG-ROM circuit 139a, a Match-address Aggregator circuit 141a, data register (DR) 30, static CACHE register (SCH) 32, a Y-pass gate circuit 33, a Y-decoder circuit 34, a state-machine circuit 70, and CSL and LBLps lines, etc. In an embodiment, DR 30 includes one PRB (Program and Read buffer) 106 and one SA (Sense Amplifier) 104. In another embodiment, SCR 32 is made of a real glue-logic circuit. In the NAND-CAM array, there is a plurality of capacitor-based Dynamic CACHE Registers (DCRs) that uses zero glue logic circuit. DCR is also referred as a virtual PB in this application. In this LG-based NAND-CAM, each LBLps line acts as one ML (Match line) connected to one corresponding SA referred as LG-SA with layout done in parallel to CSL shared by two adjacent NAND blocks.

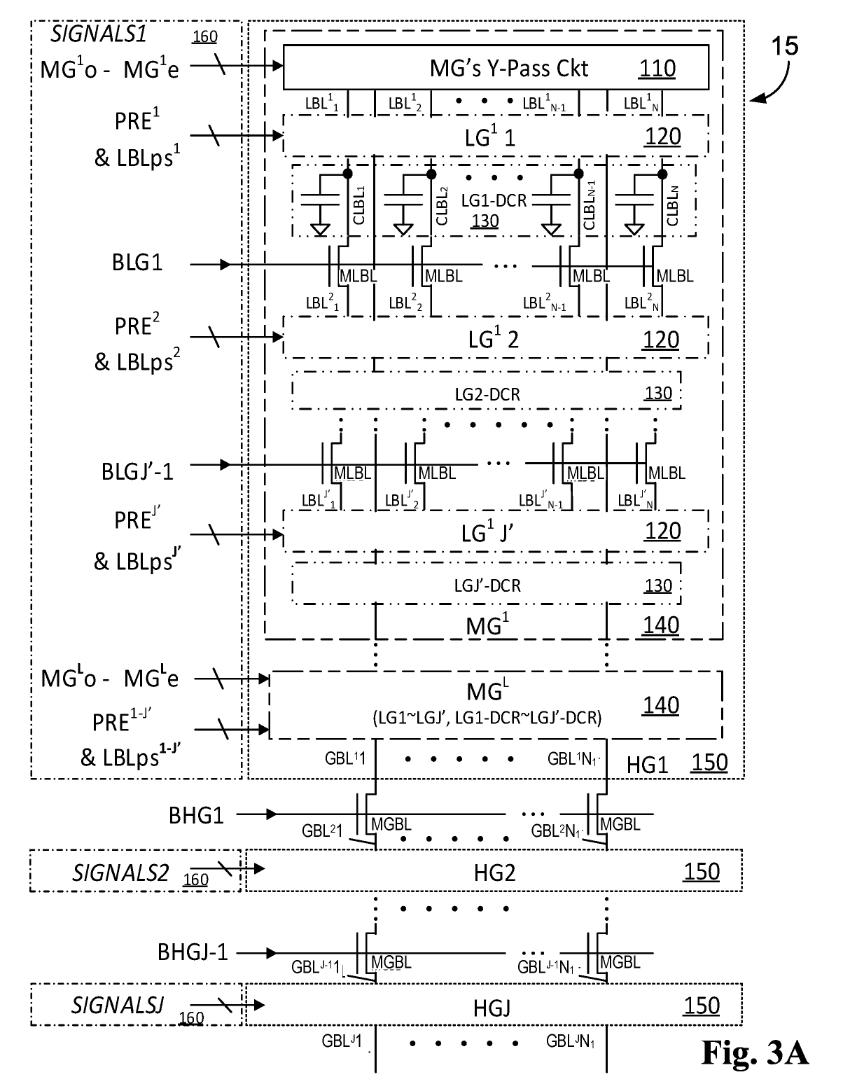

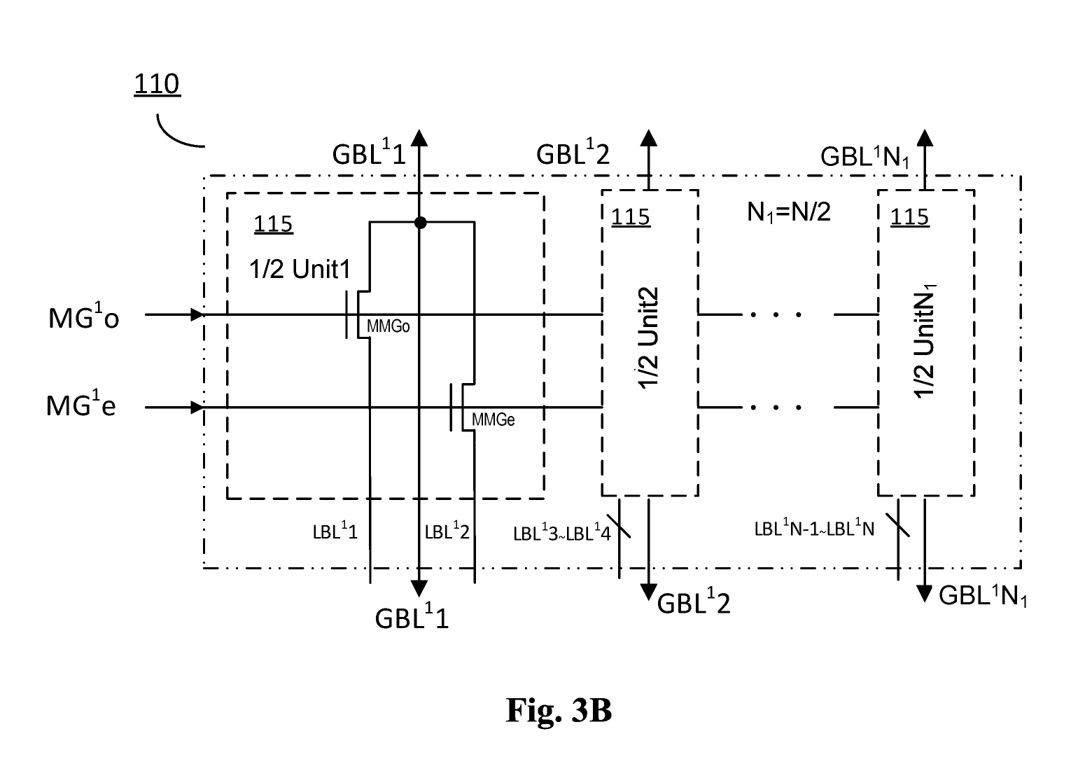

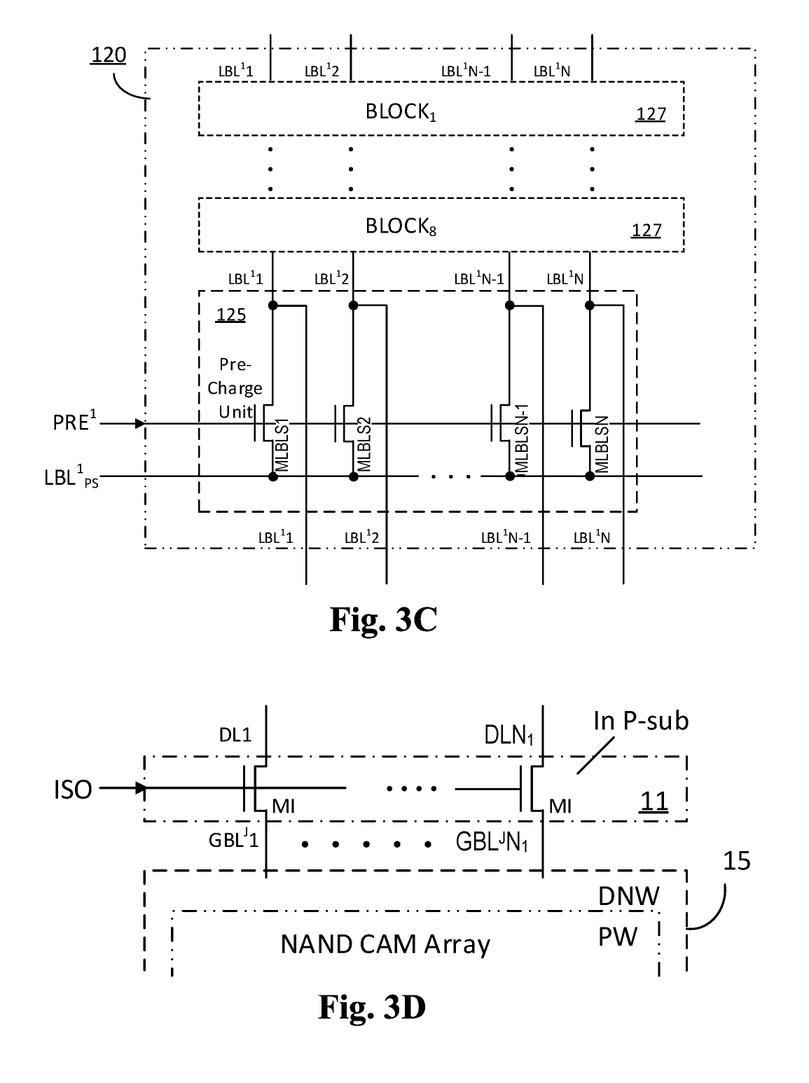

The circuit of each NAND-CAM block is based on but not limited to the one shown in FIG. 1A block circuit. As shown in FIG. 1A, the NAND strings in each block are coupled to m0 layer only LBL lines or a mixed m0 and m1 (higher than m0) layers interleaving Odd and Even LBL lines with a full LBL shielding effect and the common horizontal m0 layer CSL line shared by two adjacent blocks. For the NAND-CAM array 10 there are total H blocks per one LG group. Each LBL line of each m0 or m1 C_{LG} capacitor is used to connect the H NAND blocks as one bit of capacitor-based DCR and is referred as one bit C_{LG}. The length of each C_{LG} has to be optimized as a tradeoff between the optimal C_{LG} capacitance and the overhead of NAND-CAM array area due to the addition of each BLG device (MLBL as seen in FIG. 3A). Each LBL line per block forms a parasitic capacitor C_{LBL} of a length of the block. In other words, the capacitance value of each C_{LG}=H×C_{LBL} in either m0 or m1 layer. In this example, m0 and m1 level capacitance are assumed to be equal for an easier explanation of the inventive concept of the present invention. But they should not be limited as that. Typically, m1 level has less capacitance than m0 level due to the thicker oxide between metal layer and a Triple P-well of the NAND chip, which is connected to Vss.

The length of each m0 or m1 C_{LG} capacitor is used to connect H vertically adjacent NAND blocks within one broken LBL line or LG. This is the basic C_{LG} with an optimized length to allow the temporary storing the 0V and Vinh for respective SLC's and MLC's V_{LBL} during the concurrent and pipelined nLC ABL program, ABL nLC program-inhibit and ABL nLC read voltages. Note, for the NAND-CAM array 10, all 16 KB LBL cells cannot be read out in 1-cycle due to the number of GBL lines is only ½ of LBL lines. But most delay of program-verify, erase-verify, and read operation is LBL precharge and discharge via on-state of a Mega-ohm NAND string resistance. In this NAND-CAM of the present invention with broken LBLs and GBLs, the discharge and precharge can be done at same time as conventional ABL program and read operation because it is done within zero-coupling LBL lines. The data read from Even and Odd LBL to GBL is done by a charge-sharing (CS) technique, which is very quick like DRAM CS operation without suffering any long RC delay due to a high R value in Mega-ohm level of the entire GBL of all NAND strings. Each bit of local C_{LG} contains one Vinh precharge device, MLBLs, gated by either a PREo or a PREe signal with a Vinh supply line of LBLps.

For both SLC and MLC NAND-CAM program and read operations, LBL precharge is preferably performed in ABL manner within one physical page of 16 KB local C_{LG} forming one 16 KB DCR for power saving and reduction of Vpgm, Vpass, and Vread high-voltage stress and latency.

In an embodiment, only one randomly selected page of this NAND-CAM within one LG group can be programmed simultaneously with other single randomly selected pages in remaining LGs in one plane of NAND-CAM array. As a result, the nLC program can be increased proportionally by the number of LGs when LBL voltages of all pages' data are fully loaded and latched in all C_{LG}s (16 KB C_{LG}s per one LG) and all nLC program voltages of Vpgm, Vpass, Vdd, and Vss are also respectively loaded and latched into all sets of one selected WL, 123 non-selecting WLs, one SSL, and one GSL of corresponding blocks selected within all LGs. The parasitic poly line capacitors of all WLs, SSLs, and GSLs are referred as YB-Buffer to store the temporary Program, Read, Verify data as well as Y-word search data of this preferred NAND-CAM but with a duration controlled by on-chip State-machine.

In a specific embodiment, the whole NAND-CAM array 10 is divided into multiple HGs with BHG-dec 51, and then multiple MGs with MG-dec 53, and multiple LGs with BLG-dec 52. Each LG is defined as a minimum memory unit to allow independent concurrent nLC program, read, and verify operations according to embodiments of the present invention. Each LG includes one horizontal power-supply line LBLps used as a Match line (ML) connected to all LBL lines through 16 KB PRE devices associated with LBLps-Dec 54. Each block in the LG includes a CSL (shared by two adjacent blocks) that is connected to all source nodes of NAND strings. Each LBLps line is designed to do the local LBL precharge and discharge in a dramatic faster speed with a low resistance to avoid Mega ohms resistance of NAND string used for charging in all prior art.

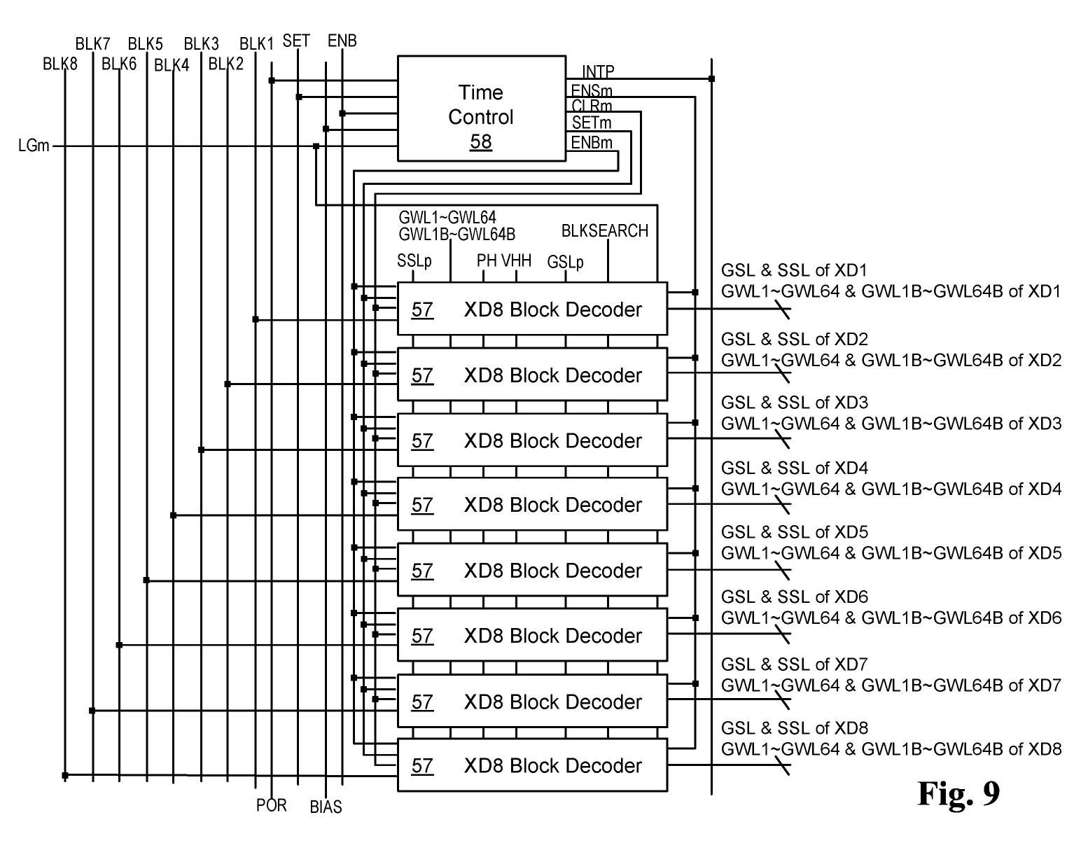

Referring to FIG. 2A, the outputs of Block Pre-decoders 56 and other block control signals (such as CLA, ENBm, CRM and BLKSEARCH shown in FIG. 9) are fed into inputs of all Block-decoders 50 with global signals of one GSLp, one SSLp, and plurality of GWLs generated from one common circuit 55 referred as GWLs, GWLBs, SSLp, and GSLp. Each Block-decoder 50 is equipped with a latch to allow the predetermined Vsh and VshB voltages during Y-word search operation, Vpgm and Vpass during nLC program, and Vread during nLC read operation to be set and locked on respective Block-decoder outputs of SSL, GSL, WLs, and WLBs lines within NAND-CAM array without taking overhead of a real circuit area.

In addition, the peripheral circuits of PRB 106, SA 104, and the existing Y-pass Gate and Block-ML encoder are jointly used for identifying the address of a matched GBL using a preferred Y-word search scheme. The NAND-CAM's LG-based Match-line (ML) detecting circuit is referred as LG-SA and its associated ROM is referred as a LG-ROM, together being used to identify the matched Block address. For performing a preferred Y-word search scheme, this NAND-CAM array uses LG-based Match-line (ML) and LG-ML ROM circuits to search address of a matched block containing the NAND strings that store the data matching with Y-word nLC data. There are at least three embodiments of Y-word search scheme employed by this NAND-CAM array for finding the address of matched blocks. One embodiment uses the LBLps line as the ML coupled with a LBLps SA, while other two methods use the conventional CSL as the ML with a ML SA. Both LBLps SA and CSL SA can be made a same circuit.

For this preferred NAND-CAM Y-word search scheme, it is preferred, but not limited, to perform a LG-search first, a Block-search second, and then a LBL-search. Thus, in each step of the Y-word search operation, some partial addresses are found first by the Block-search via pre-defined on-and-off sequences of LG, MG, and HG operations and ROM. The rest partial addresses are found by LBL-search via pre-defined on-and-off sequences of YA, YB, and YC address search/confirmation operations. All of partial addresses such as the addresses of matched LG, the matched Block and the matched LBL are aggregated to form the fixed length of bits of a fully matched address by the Match Address Aggregator 141a. Once the final address of n-bit matched Y-word is found, it is immediately returned to the off-chip Flash controller via an on-chip Data I/O buffer circuit 90 and pads.

FIG. 2B is a block diagram of a hierarchical Block-based NAND-CAM array according to an embodiment of the present invention. This diagram is merely an example, which should not unduly limit the scope of the claims. One of ordinary skill in the art would recognize many variations, alternatives, and modifications. As shown, the NAND-CAM array has a similar hierarchical broken-LBL and broken GBL structure based on the blocks shown in FIG. 1A made by NAND strings with similar m0 level only or the mixed m0 and m1 levels interleaving Odd and Even LBL lines for a full LBL shielding effect and a m0 level CSL shared by two adjacent blocks. There are also total H blocks per one LG group and each LBL parasitic capacitor C_{LBL} has a length of LG. The difference is that the Y-word search scheme uses preferred Block-based ML and BLK-ML ROM circuits to search the address of one matched block that contains one matched LBL or NAND string in one matched block.

The Block-based-ML NAND (FIG. 2B) uses each CSL as a ML and is preferably divided into a plurality of vertical HGs with BHG-dec, then MGs with MG-dec, then LGs with BLG-dec, then H blocks with H/2 shared common horizontal CSL lines but only one LBLps power line. Each CSL line shared by two adjacent blocks is connected to one Block-SA or BLK-SA, acting as one preferred ML (Match line) with its associated BLK-ML ROM circuit to jointly identify the address of the matched Block. Therefore, the Block-based-ML NAND-CAM (FIG. 2B) has H/2-fold ML-SAs than the LG-based-ML NAND-CAM (FIG. 2A). As a result, the Block-based NAND-CAM can perform Y-word search with approximate H/2-fold faster speed than the LG-based NAND-CAM. In an example, one LG has 8 blocks so that the Block-based NAND-CAM can have 4× search speed of a LG-based NAND-CAM. Besides, the size of the BLK-ML ROM circuit is larger than the LG-ML ROM circuit due to 3 more address-bits because one LG comprises 8 blocks.

In an embodiment, for this preferred Block-based NAND-CAM Y-word search scheme, it is also preferred, but not limited, to perform the direct Block-search first followed by a LBL-search. The LG-search step can be omitted.

Finally, all partial addresses including addresses of the matched Block and the matched LBL are aggregated to form a final matched address by the Match Address Aggregator 141b (see FIG. 2B). The fixed bit length of the matched LBL in the matched Block is fully determined by the NAND-CAM density. Once the final address of n-bit matched Y-word is found, it is immediately returned to the off-chip Flash controller via on-chip Data I/O buffer circuit 90 and pads.

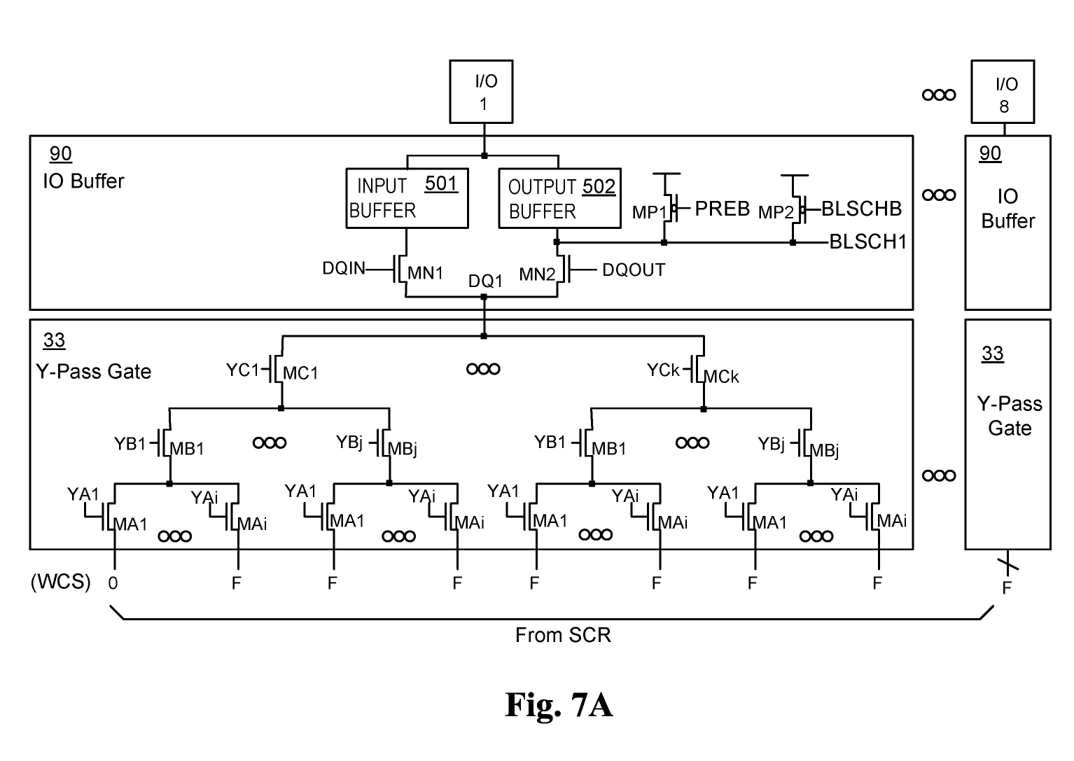

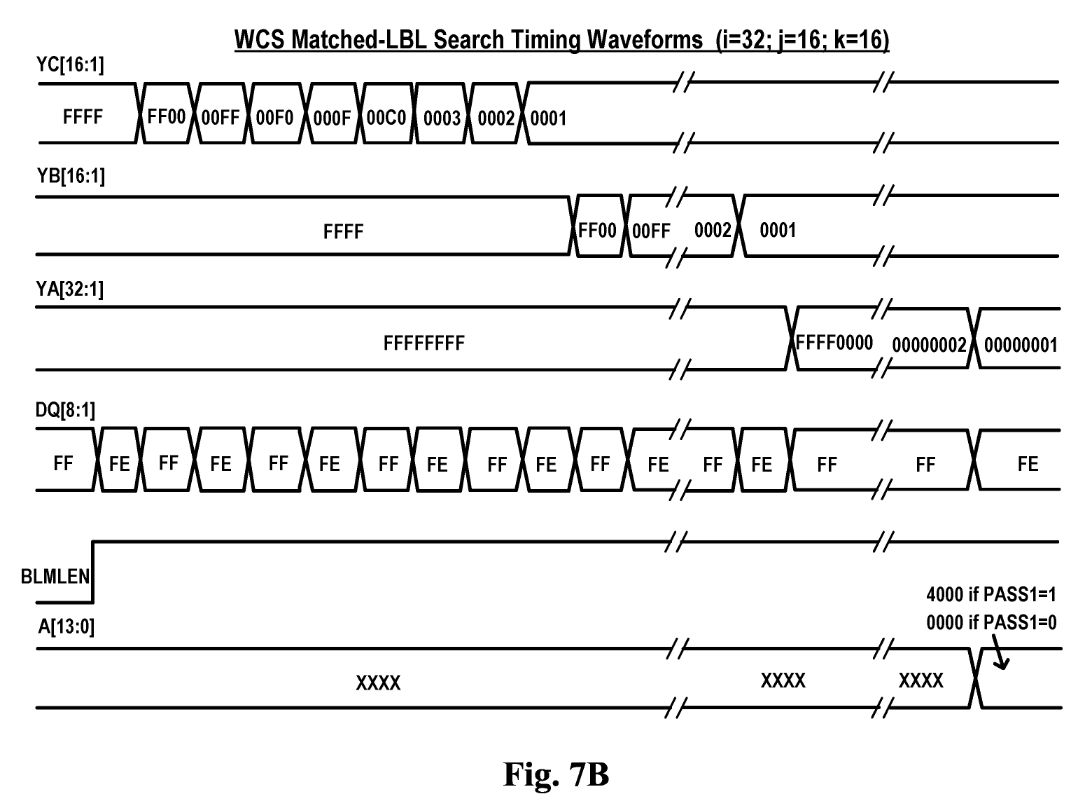

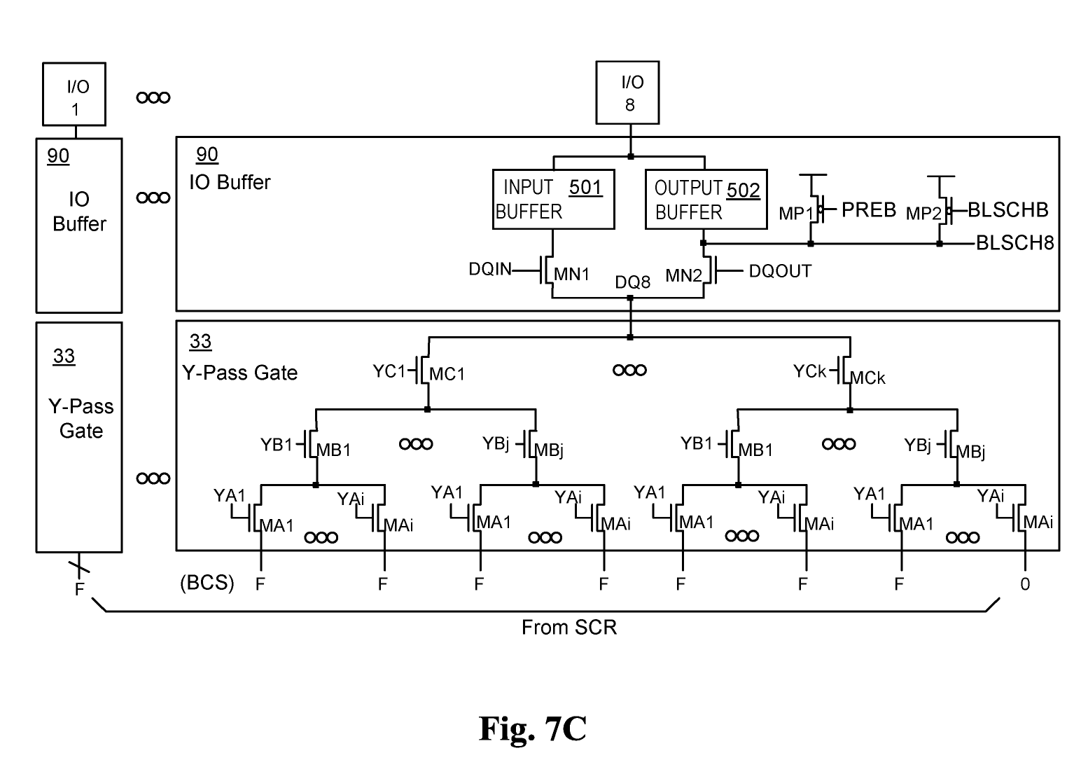

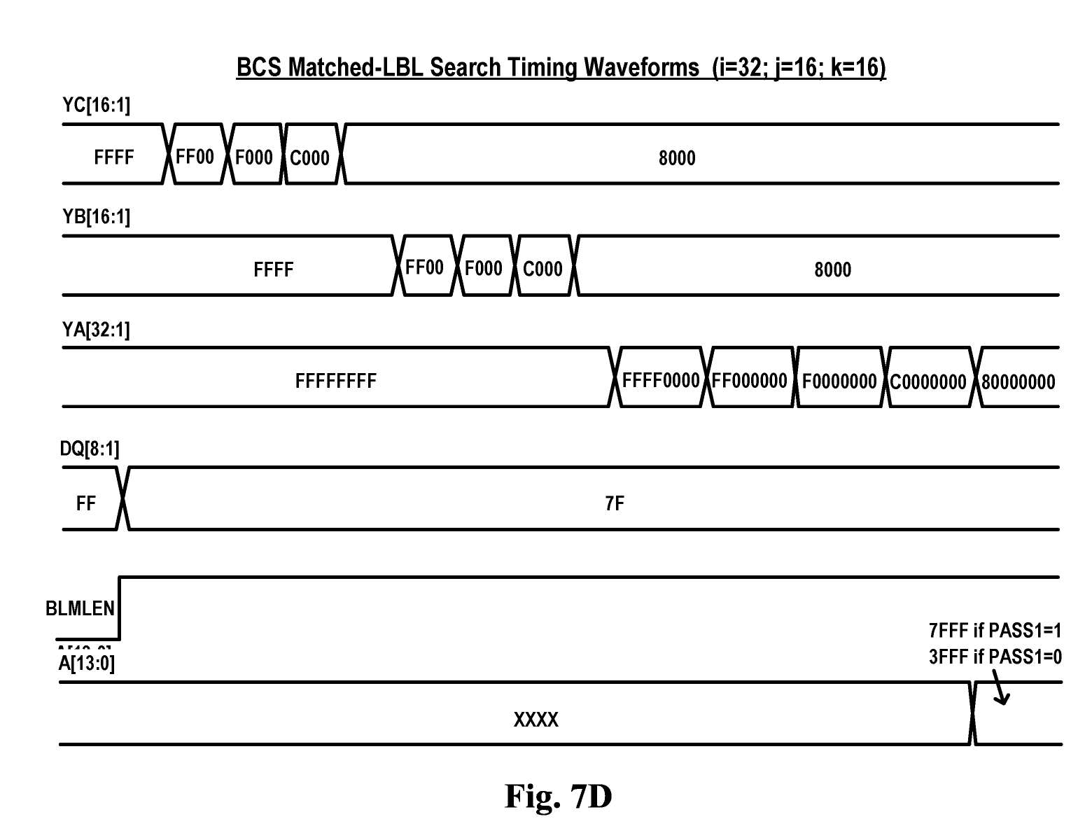

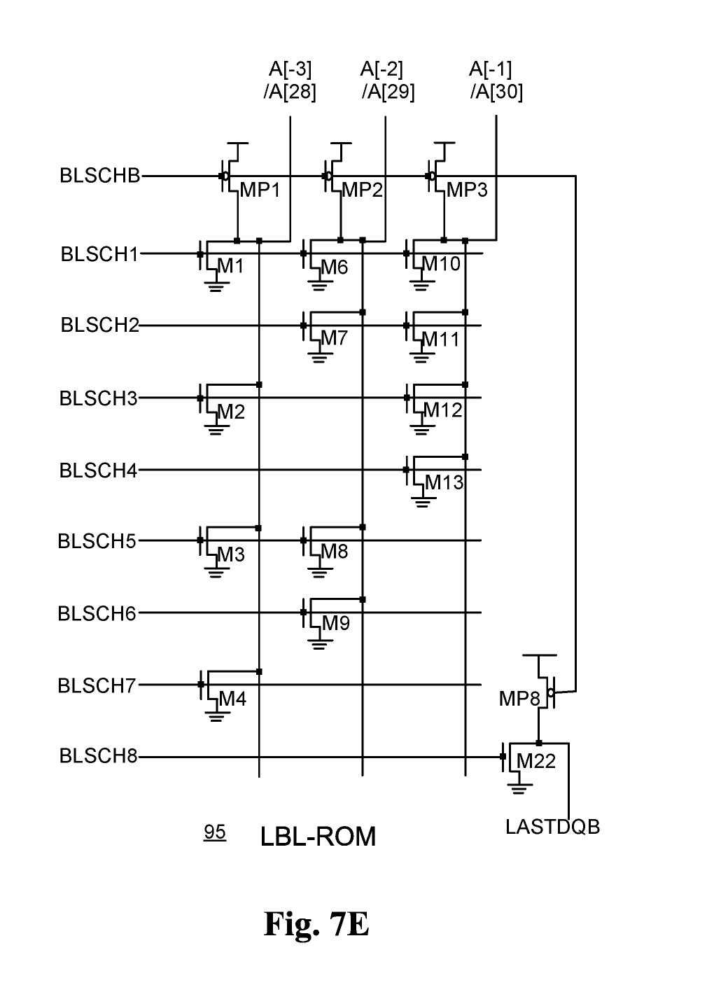

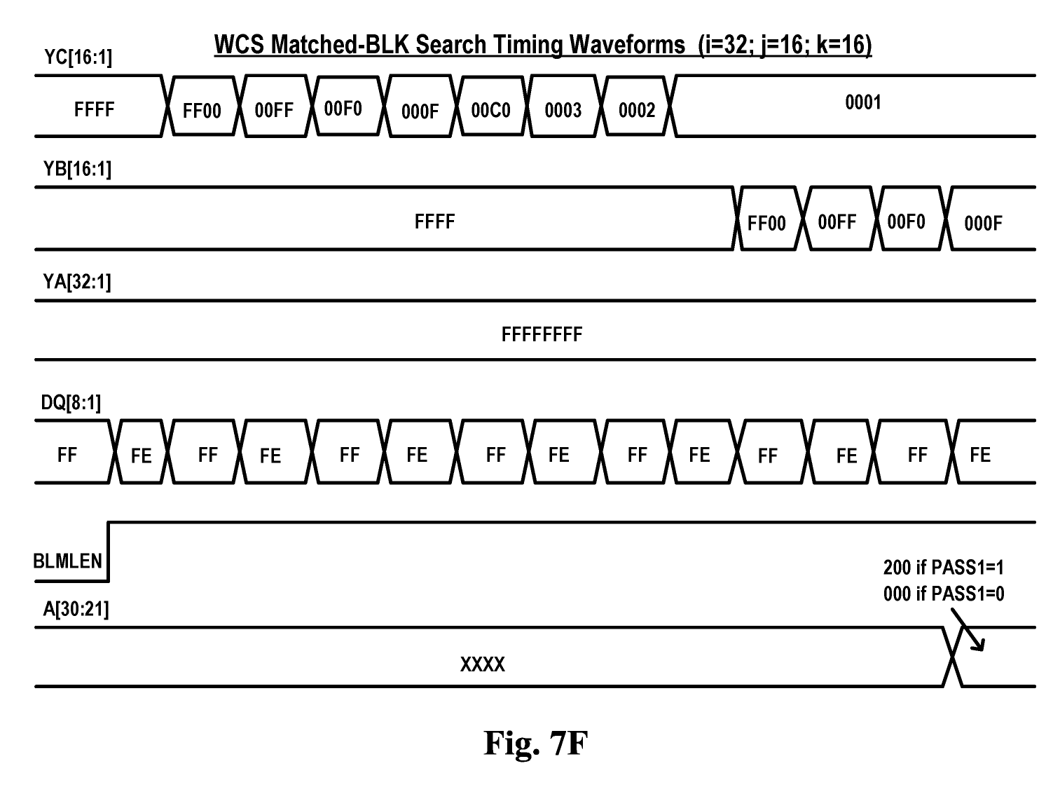

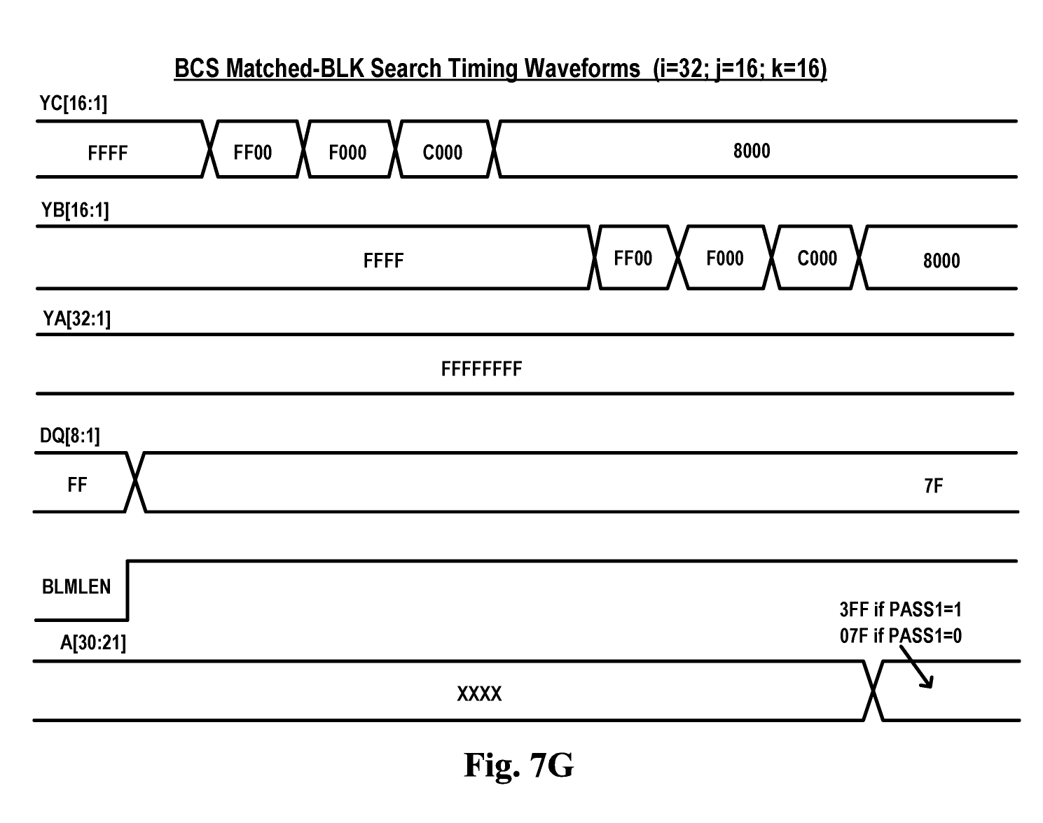

FIG. 2C is a block diagram of a hierarchical non-Block-based and non-LG-based NAND-CAM array according to an embodiment of the present invention. This diagram is merely an example, which should not unduly limit the scope of the claims. One of ordinary skill in the art would recognize many variations, alternatives, and modifications. As shown, this NAND-CAM includes a similar hierarchical broken-LBL and broken GBL structure based on the blocks shown in FIG. 1A made by NAND strings with similar m0 level only or the mixed m0 and m1 levels interleaving Odd and Even LBL lines for a full LBL shielding effect and a m0 level CSL shared by two adjacent blocks. It uses each CSL as a ML but without any BLK-SAs, BLK-ROM, LG-SAs, and LG-ROMs. It is also preferably divided into a plurality of vertical HGs with BHG-dec, then MGs with MG-dec, then LGs with BLG-dec, then H blocks with H/2 shared common horizontal CSL lines only one LBLps power line as the NAND-CAM shown in FIG. 2A and FIG. 2B. But in this NAND-CAM (FIG. 2C), every CSL is used as a ML and each BLK-SA is replaced by each existing SA 104 in each digital register (DR) and each BLK-ML ROM circuit is replace by LBL-ROM 95 (see FIG. 7E below). As a result, a huge saving in silicon areas of SAs and ROMs can be achieved at the expense of a small reduction in Y-word Search speed. The other circuits of varied decoders and DB and SCRs are basically the same as above FIG. 2A and FIG. 2B.

In an embodiment, this NAND-CAM employs a preferred Y-word search scheme that neither uses any LG-ML, LG-SA, and LG-ROM as the NAND-CAM in FIG. 2A nor uses any BLK-ML, BLK-SA, and BLK-ROM circuits as the NAND-CAM in FIG. 2B to search the address of the matched Block containing the NAND strings with data matching with Y-word nLC data. In other words, there are no extra hardware overheads of any sort of above said ML-SA and ML-ROM for this embodiment of NAND-CAM Y-word search scheme by compromising a slightly slower search speed comparing to those given in FIG. 2A and FIG. 2B. However, this embodiment of Y-word search scheme still out-perform all prior art by a large degree in terms of search speed.

In a specific embodiment, the preferred Y-word search scheme is to use existing free hardware circuits of Y-pass and Y-decoders to replace LG-ML ROM or BLK-ML ROM circuits and use existing free SAs to replace LG-SA and BLK-SA along with the on-chip state-machine to perform sequential on and off search operations for identifying addresses of matched BLs. In other words, all existing decoders such as Y-dec 34, Block-dec 50, BHG-dec 51, BLG-dec 52, MG-dec 53, Y-pass gate circuit 33, DR 30, SCR 32, and the LBL-ROM 95 are shared by both the Block-search step and the LBL-search step. This search scheme achieves the least area implementation with a fast Y-word search speed of the preferred NAND-CAM (FIG. 2C).

FIG. 2D is a diagram of one LG group circuit of the hierarchical LG-based NAND-CAM array according to an embodiment of the present invention. This diagram is merely an example, which should not unduly limit the scope of the claims. One of ordinary skill in the art would recognize many variations, alternatives, and modifications. As shown, it is a detailed circuit of one LG-group in the NAND-CAM array of FIG. 2A with N LBL lines formed as N C_{LG} capacitors. Each LG is sandwiched by two rows of N NMOS transistors of MLBL respectively connecting to two BLG gate signals. In the example, N=16 KB.

Total N C_{LG} capacitors form one N-bit LG-DCR (Dynamic CACHE Register) per one LG and each N-bit DCR is used to temporarily store N-bit nLC page data during program, verify, and read operations. Based on this preferred nLC NAND-CAM, up to 128 (1024/8)N-bit LG-DCRs can be used for performing a batch-based concurrent nLC program to dramatically cut program latency. Besides, the N-bit LG-DCR is also used to store the temporarily precharged voltage for each independent Y-word search using either LG-based, Block-based, or LBL-based scheme so that the Y-word search speed can be increased.

As shown in FIG. 2D, the first LG group LG1 of the NAND-CAM array 126a comprises N LBL lines such as LBL¹₁ to LBL¹_{N} or N C_{LG}s between two adjacent LGs divided by one row of N MLBL transistors with N gates tied to BLG1 line. There are 4 CSL lines from CSL1 to CSL4 of connecting to two rows of NMOS transistors of MLBLs in two physically adjacent blocks with a virtual Y-word register referred as Y-PB with a length of 64-paired complimentary WLs and WLBs, and one GSL, and one SSL lines using the horizontal parasitic poly2 capacitors as the temporary capacitor-based CACHE Registers.

In this example, H=8, H NAND-CAM blocks of each LG group is named as Block₁ to Block₈. The Kth LG group is connected by N common bottom-level m0/m1 LBL lines such as LBL^{K}1 to LBL^{K}N. Each LG also has one dedicated LBLps line acting as a ML. Each LG is connected to one LG-SA 138a with its output 142 being connected to corresponding LG-ROM circuit 139a to quickly find one matched block address of Y-word search.

In order to achieve fast Y-word search, all LG-SAs are used for performing all LG-based search. This is done by shutting off all MLBL transistors by setting BLG signal to 0V to isolate all adjacent C_{LG} capacitors in all LGs. Next, all LBLps lines in corresponding LGs are then precharged with Vdd by LBLps voltage drivers so that all corresponding N-bit (16 KB) C_{LG} capacitors in all LGs (or DCRs) in all MGs and in all HGs are precharged with Vdd-Vt initially followed by disconnecting the LBLps voltage drivers.

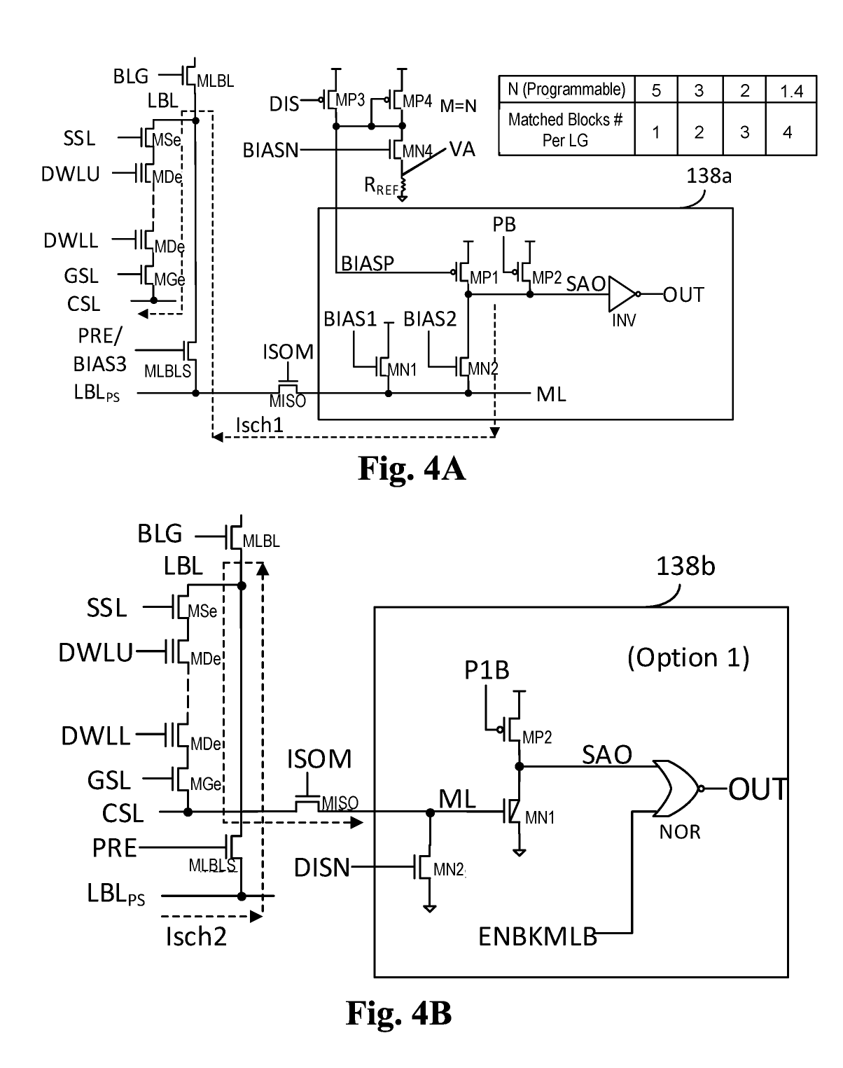

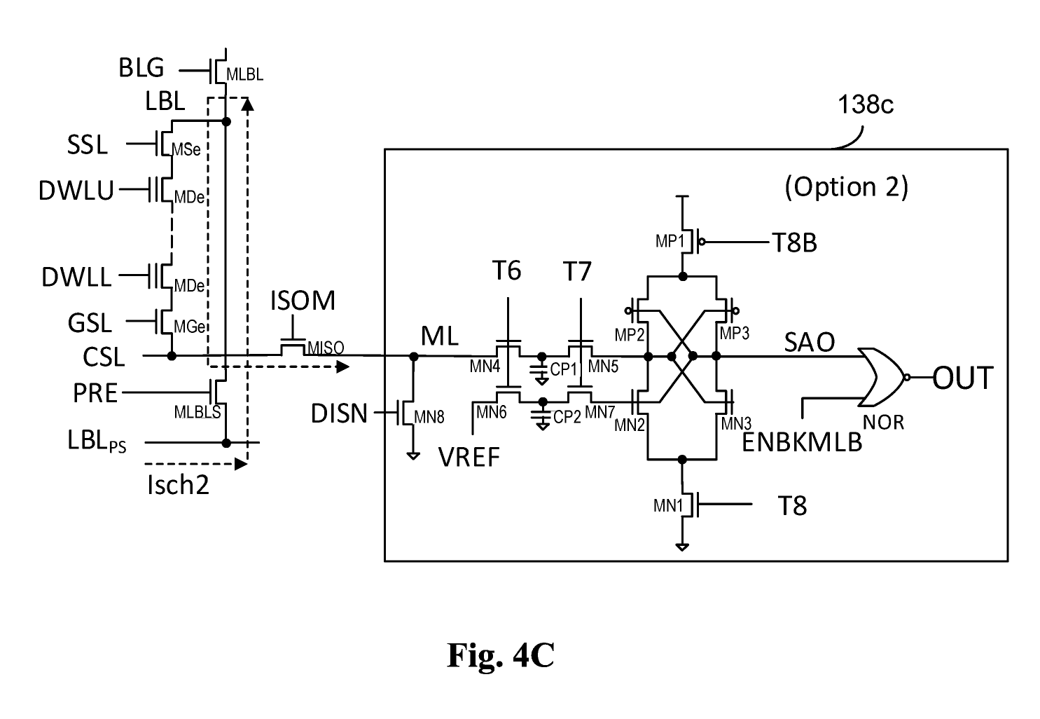

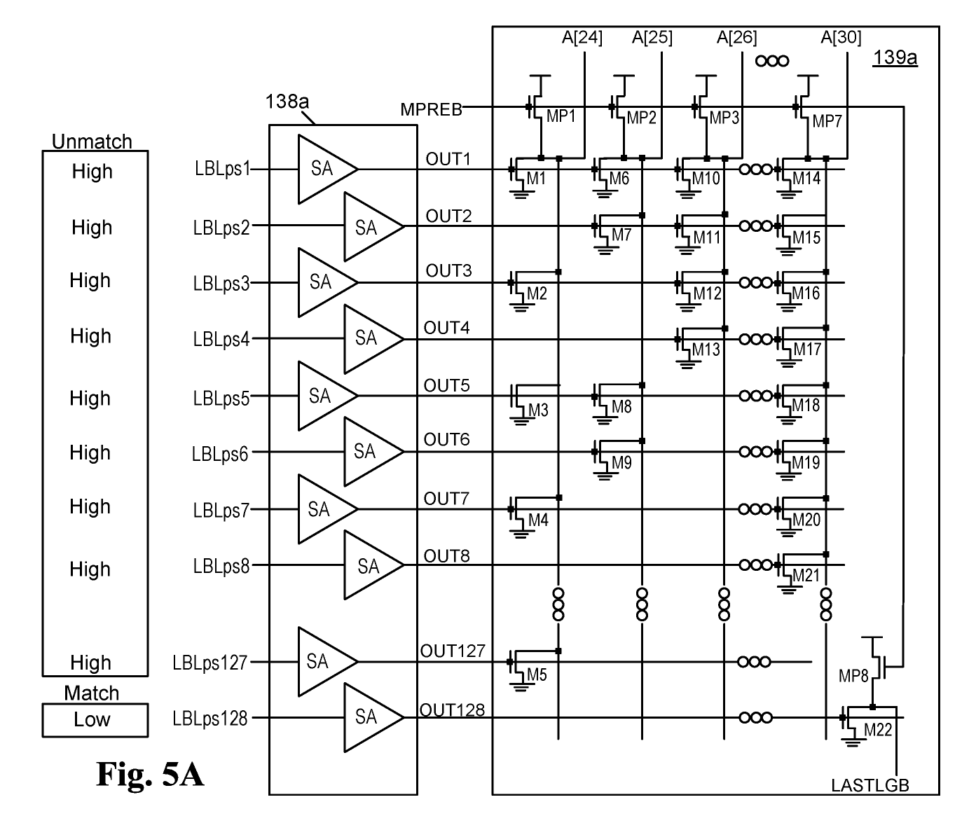

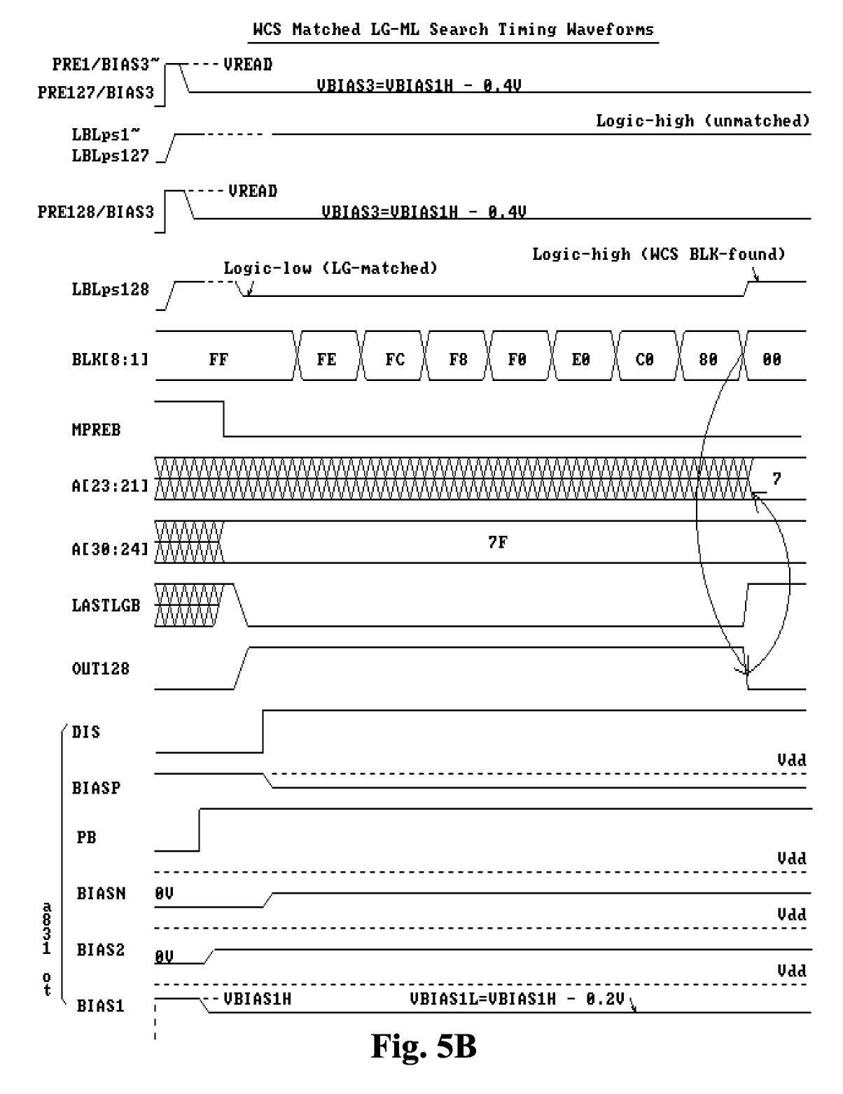

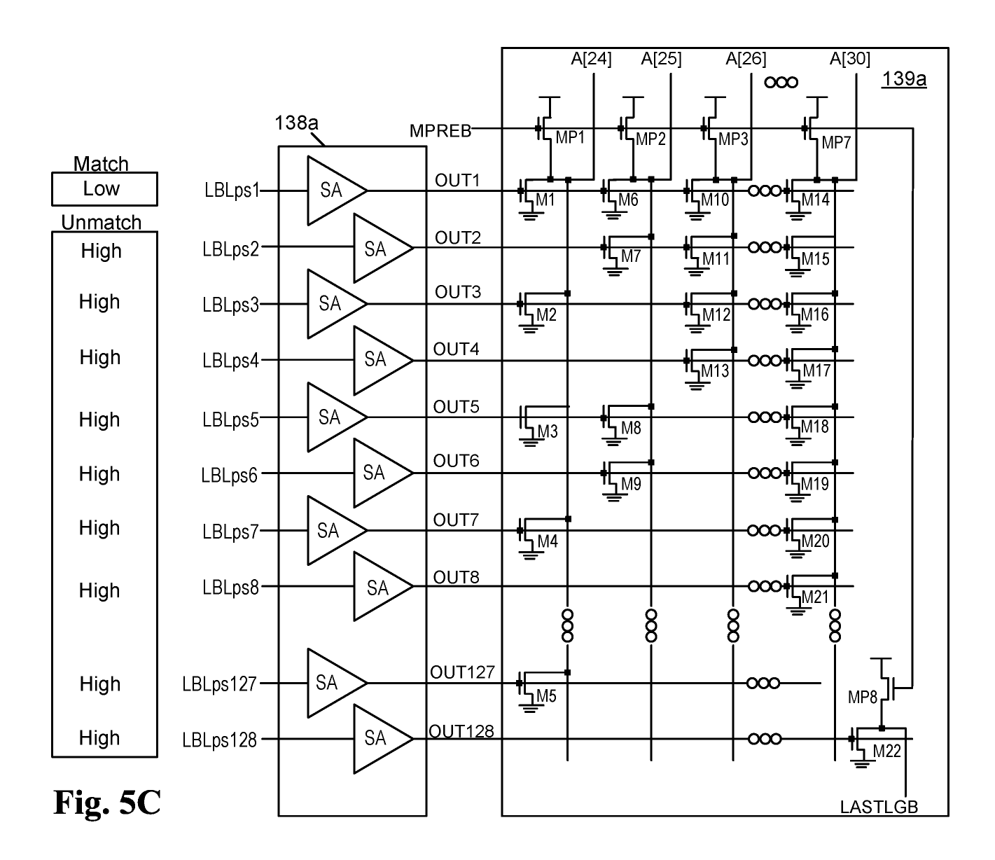

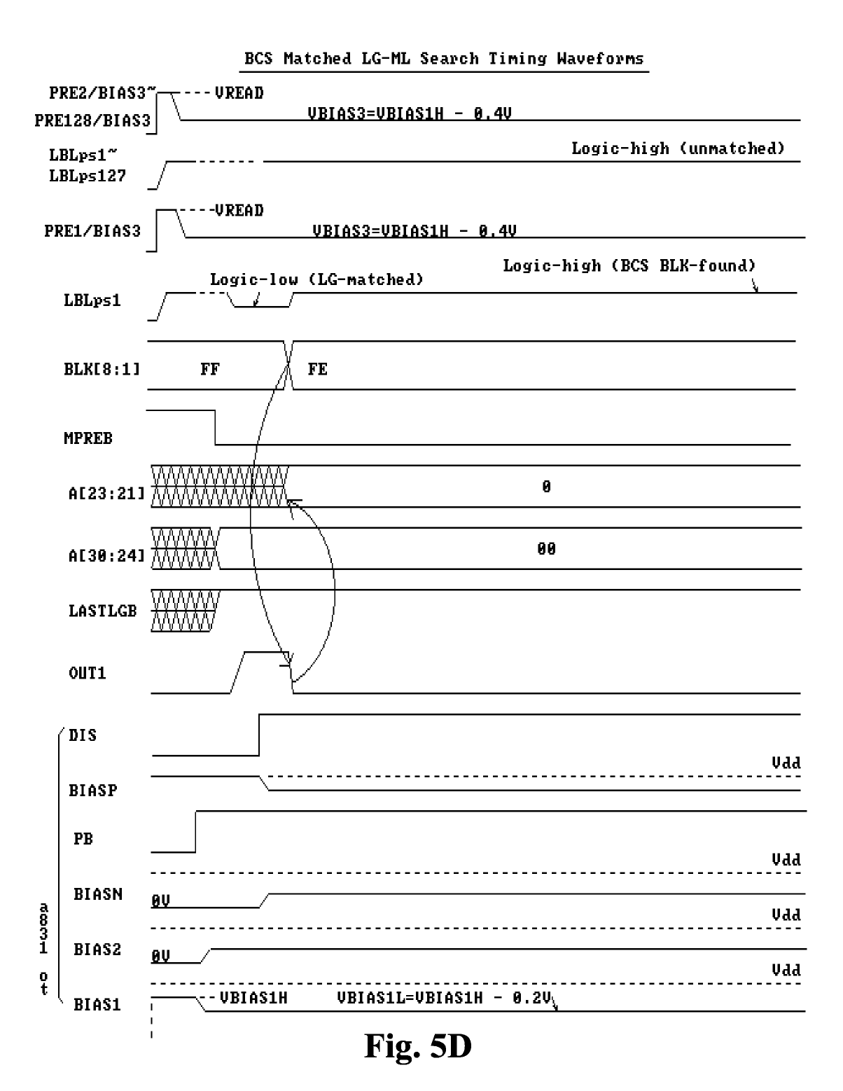

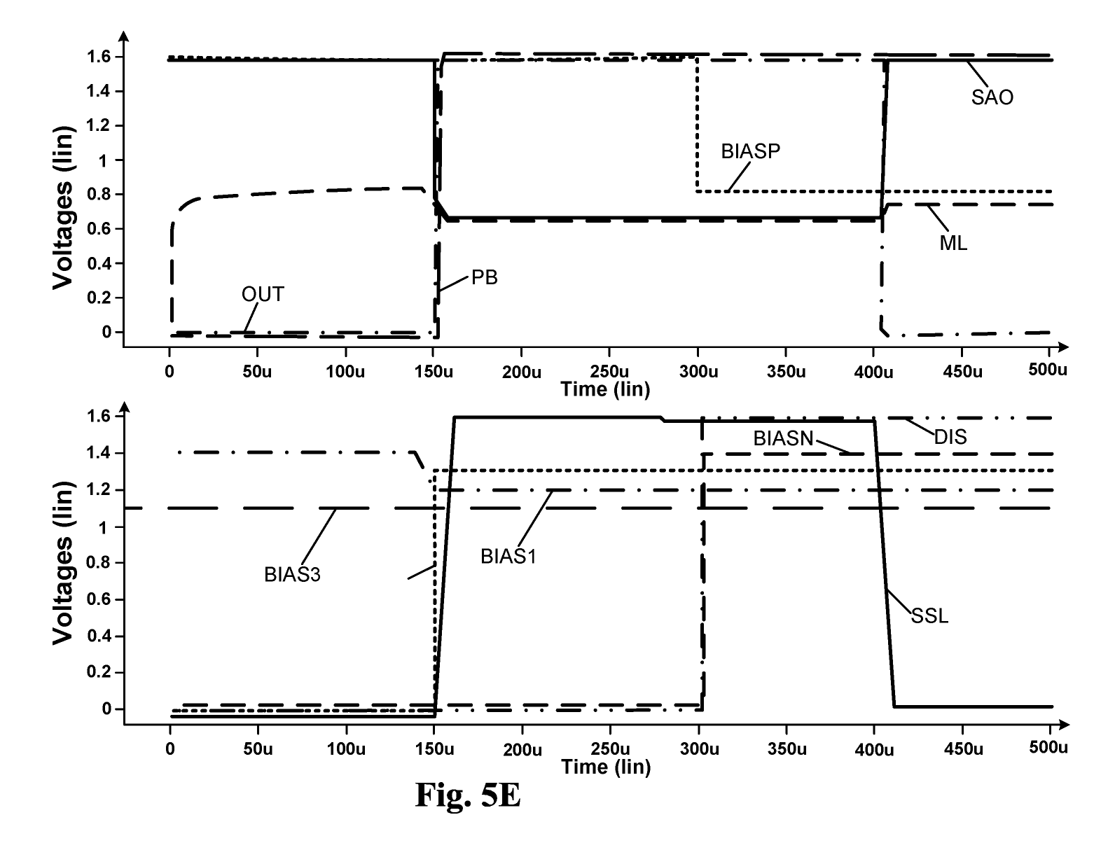

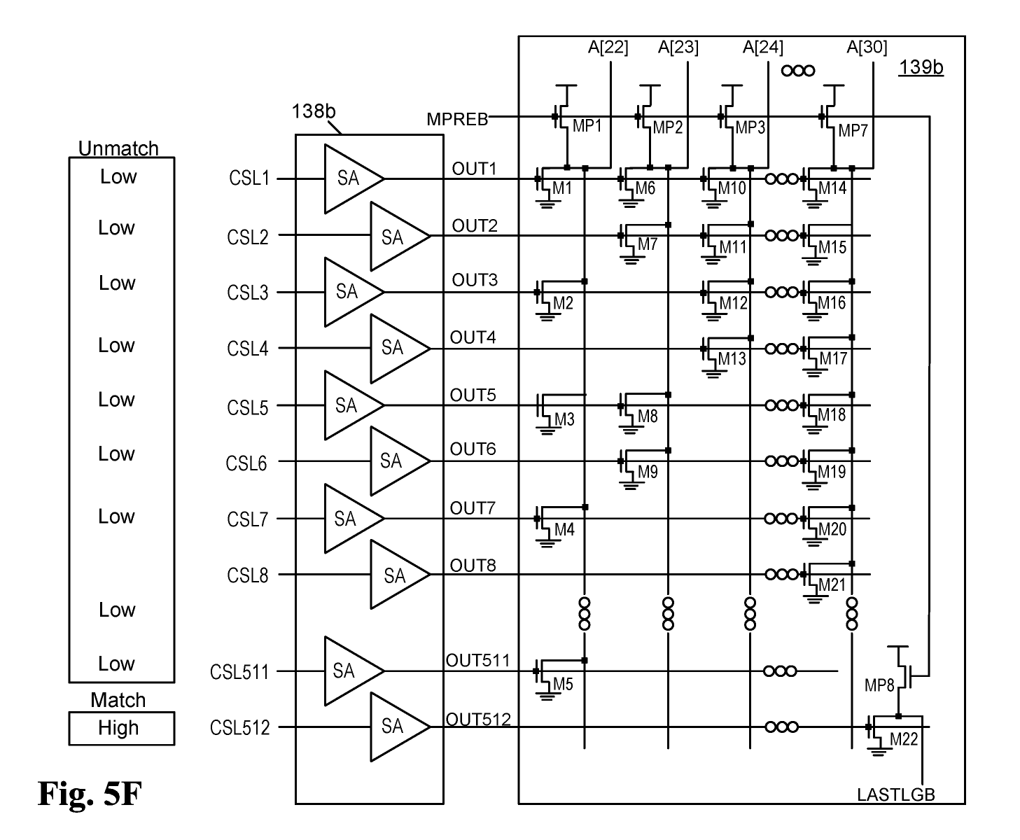

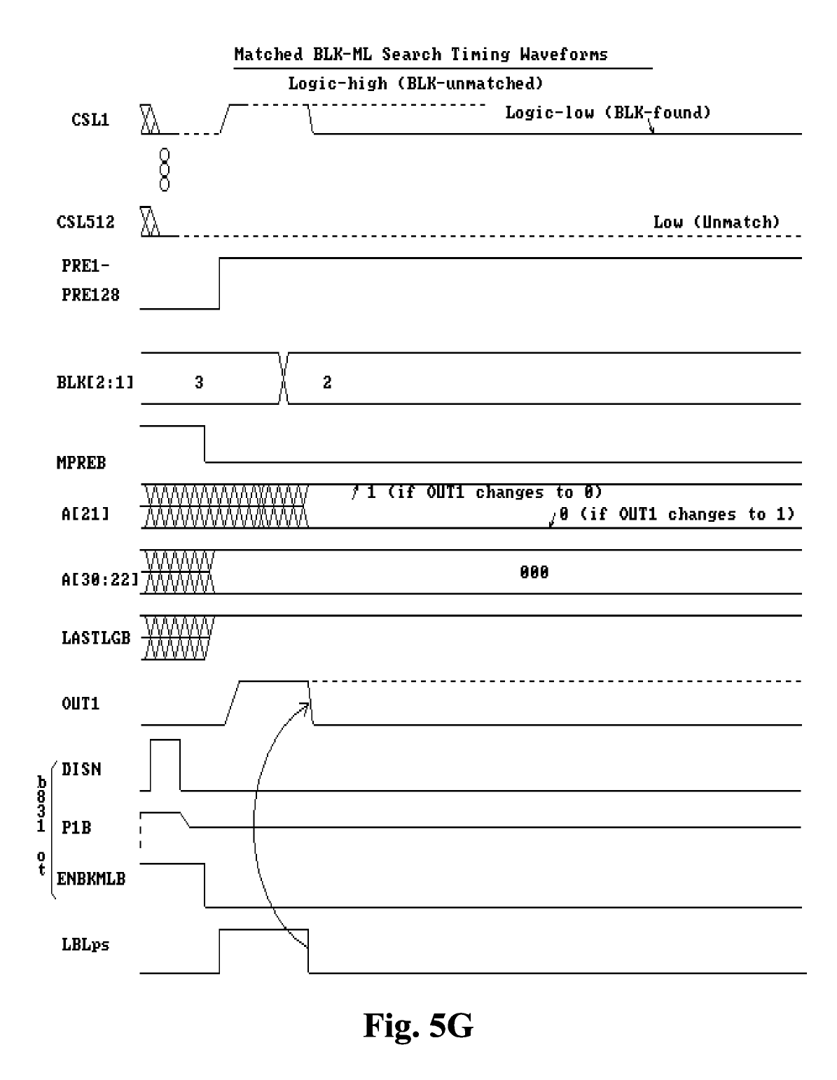

All LG-SAs and all corresponding LG-ROM encoders are enabled to be a ready state so that Y-word Search operation of the whole NAND-CAM can start to allow a quick return of the address of the matched block of Y-word search. Since only the LG-SA and LG-ROM circuits of one LG which occupies 8 blocks of 64-word are added, the overhead of this LG-based NAND-CAM is less than 1%. The total number of LG-SA is 128 in this example. In this Y-word search, an address of one matched LG in whole NAND-CAM is found first in one step, next, an address of one matched block within H blocks of each LG can be found by using a sequential On/Off scheme to control SSL signal of H−1 blocks in H−1 worst-case scenario (WCS) clock cycles. One matched LG will pull down one corresponding precharged voltage (from LBLps line) to a Logic-low voltage so that output of a cascade-typed LG-SA 138a with 3-BIAS control becomes high of Vdd voltage. The detailed circuit of this preferred 3-BIAS LG-SA and operation will be disclosed in accordance with the FIG. 4A to FIG. 5H subsequently.

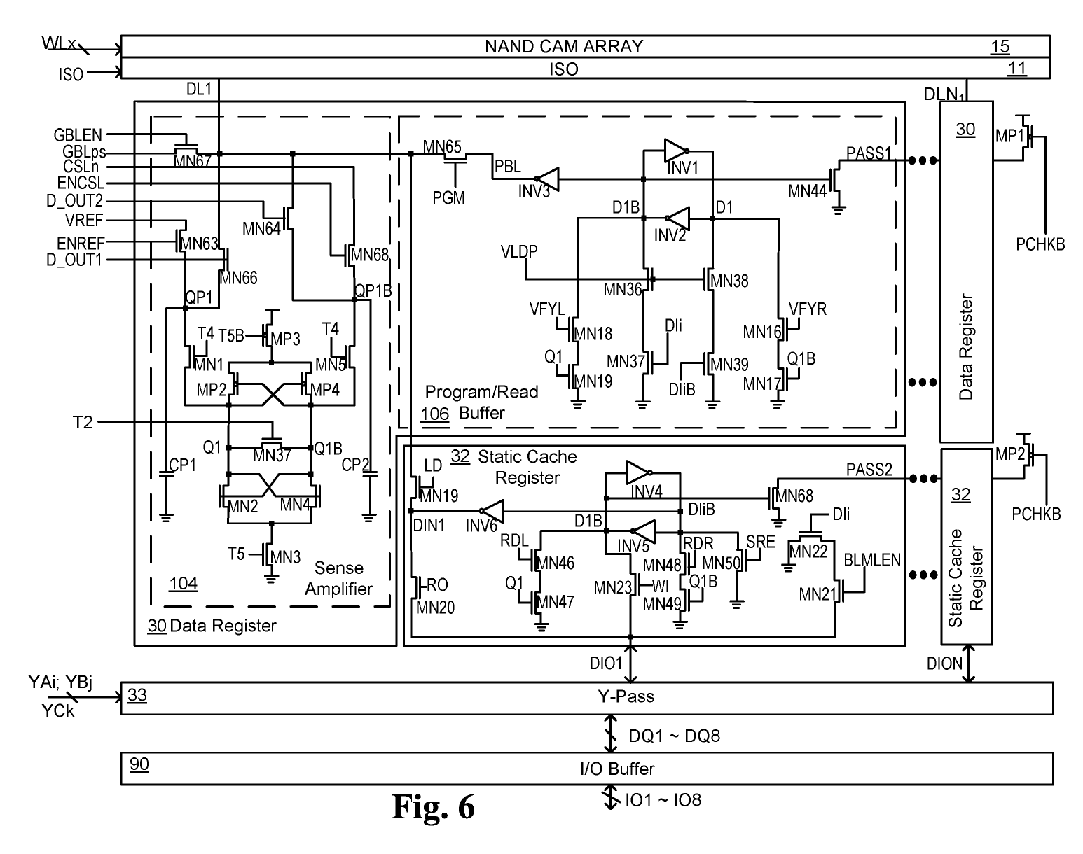

The circuits of Data Register (DR) 30, Static Cache Register (SCR) 32 and Y-pass Gate 33 and LG-ROM 139a and Matched address Aggregator 141a are jointly used to quickly identify matched LBL address of Y-word search and will be illustrated in two exemplary cases, one in best-case scenario (BCS) and another one in worst-case scenario (WCS) as shown in FIG. 6, FIG. 8A and FIG. 8C and flows of FIG. 8B and FIG. 8D.

FIG. 2E is a diagram of one LG group circuit of the hierarchical Block-based NAND-CAM array according to an embodiment of the present invention. This diagram is merely an example, which should not unduly limit the scope of the claims. One of ordinary skill in the art would recognize many variations, alternatives, and modifications. As shown, it is a detailed circuit of another embodiment of a LG group in a NAND-CAM array with a CSL-based ML working along with corresponding search circuits of BLK-SA 138b and BLK-ROM 139b and DR 30, SCR 32, Y-pass 33 and the Match-address Aggregator 141b.

As shown, a first LG group LG1 of the NAND-CAM array 126b comprises N LBL lines such as LBL¹₁ to LBL¹_{N} or N C_{LG}s divided from the LG2 by one row of N MLBL transistors with N gates tied to BLG1 line. In the embodiment, there are 4 CSL lines, CSL1 to CSL4, each connecting to a Block-based SA or BLK-SA 138b (see FIG. 4B or FIG. 4C) and all four outputs 142 of the four BLK-SAs 138b connecting to a BLK-ROM 139b. The number of BLK-ROM circuits (FIG. 2E) is H/2 of LG-ROM circuits (FIG. 2D) with 3 additional address bits because each LG group includes H=8 blocks in this example.

Similarly, each LG group includes N LBL lines formed as N C_{LG} capacitors between two gate lines of BLG^{K-1} and BLG^{K} connecting to two rows of N NMOS transistors of MLBL. The total N C_{LG} capacitors still form one N-bit LG-DCR and each N-bit DCR is used to temporarily store N-bit nLC page data during multiple LG concurrent ABL program, ABL-verify, and ABL-read operations so that multiple LG-based N-bit DCRs can be used to store 128-page of SLC program data or ABL read data for this preferred nLC NAND-CAM to dramatically cut latencies of nLC program, verify, and read operations. Besides, the N-bit LG-DCR is also used to store the precharged voltage for each independent Y-word search so that the Y-word search speed based on the NAND-CAM can be increased.

In an embodiment, the N-bit (16 KB) DCR capacitors in each LG are precharged or discharged by each dedicated LBLps line in one-shot. The NAND-CAM with LG group of FIG. 2E uses CSL lines as the MLs for Y-word search, while the NAND-CAM with LG group of FIG. 2D uses LBLps lines as MLs for Y-word search. In another embodiment, the NAND-CAM array includes 512 BLK-SAs 138b with 512 MLs made of 512 corresponding CSL lines and 512 corresponding BLK-ROMs 139b.

FIG. 2F is a diagram of one block circuit of the hierarchical non-Block-based and non-LG-based NAND-CAM array according to an embodiment of the present invention. This diagram is merely an example, which should not unduly limit the scope of the claims. One of ordinary skill in the art would recognize many variations, alternatives, and modifications. As shown, it is a detailed circuit of yet another embodiment of a LG group in the NAND-CAM array without any CSL-based ML or LBLps-based ML and their associated SAs and ROMs but using existing circuits of Y-pass, Y-dec, and a LBL-ROM (see FIG. 7E below) used by the LBL-search operation. Of course, all LG-based LBLps lines (not shown) are still required for the NAND-CAM array during batched-based concurrent nLC ABL program, ABL verify, and ABL read operations.

In an embodiment of the Y-word search scheme, total 512 CSLs for 1,024 total blocks of this NAND-CAM array are coupled via 512 vertical lines to DR30, SCR 32, and Y-pass Gate 33 before connecting to a Match Address Aggregator 141c. Theoretically, each CSL is still served as a ML for executing the Y-word search under this NAND-CAM array. 512 existing SAs (e.g., SA 104 of FIG. 6) located within one 8 KB DR 30 and 512 existing registers within one 8 KB SCR 32 (see FIG. 6) and a Y-pass 33 are available or in idle state thus are free to be employed during the search cycle of one matched block.

Similarly, each LG is comprised of same N LBL lines formed as N C_{LG} capacitors per one LG between two rows of N NMOS transistors of MLBLs respectively gated by two signals BLG^{K-1} and BLG^{K}. Total N C_{LG} capacitors form one N-bit DCR per one LG as in other embodiments and each N-bit DCR is used to temporarily store N-bit nLC page data during program. Multiple LG-based N-bit DCRs can be used for the preferred batch-based concurrent nLC ABL program for this preferred nLC NAND-CAM array to dramatically cut program latency. Besides, each N-bit DCR is also used to store the precharged voltage by each dedicated LBLps line in one-shot for each independent Y-word search so that the Y-word search speed can be increased.

As shown in FIG. 2F, a novel circuit layout connecting 512 horizontal CSL lines to their respective DR's SAs is provided. Since total bit number of SAs is 8 KB and there are only 512 CSL lines from CSL1 to CSL512, only one of every 16B (8 KB/512) or 128 SAs in each DR is connected to 512 CSL lines through the 512 vertical lines. The space of these 512 vertical lines can take the room of regular Vss lines available in conventional NAND array as well as in the above NAND-CAM array according to embodiments of the present invention. Thus, no additional silicon room is required. Again, these 512 CSL lines can be laid at either m0 level, m1 level or even m2 level of available metal layers in this NAND-CAM chip to save the area.

In an example, one option of selecting 512 SAs for connecting to these 512 CSL vertical lines is shown in Table 1.

TABLE 1

| CSLn = MLn | CS1 | CS2 | - - - | CS511 | CS512 |
|---|---|---|---|---|---|
| SAn | 128^{th} | 256^{th} | - - - | (128 × 511)^{th} | (128 × 512)^{th} |
| Selection | SA | SA | | SA | SA |

FIG. 2G is a block diagram of a hierarchical LG-based ROM CAM array according to an embodiment of the present invention. This diagram is merely an example, which should not unduly limit the scope of the claims. One of ordinary skill in the art would recognize many variations, alternatives, and modifications. As shown, it is a hierarchical LG-based ROM CAM array that uses each dedicated precharge power line LBLps as a match line ML. The array is preferably divided into a plurality of HG groups respectively by rows of devices controlled by signals from a decoder BHG-dec. A HG is then divided into multiple MG groups respectively by rows of devices controlled by signals from a decoder MG-dec. Then A LG is further divided into H Blocks respectively by rows of devices controlled by signals from a decoder BLG-dec. The H blocks have H/2 (each shared by two blocks) common source lines (CSLs) laid in word line direction and has only one precharge power line LBLps also laid in the word line direction. In this LG-based ROM CAM array, each LBLps line acts as one ML connected to one corresponding sense amplifier referred as LG-SA.

In an embodiment, the LG-based ROM CAM array and the peripheral circuits are differentiated from the counterpart of the LG-based NAND-CAM array and the peripheral circuits in: 1) No central HV pump circuit, 2) No pump circuit for ROM Block-decoder, and 3) each ROM cell uses implant to adjust cell threshold voltage Vt. In this case, the implant is phosphorus.

FIG. 2H is a block diagram of a hierarchical LG-based ROM CAM array according to another embodiment of the present invention. This diagram is merely an example, which should not unduly limit the scope of the claims. One of ordinary skill in the art would recognize many variations, alternatives, and modifications. As shown, a LG group circuit 126d uses the precharge power line LBLps as ML, referred as LBLps-ML, and is working along with associated Search circuits including at least LG-SA 138a with outputs 142 connected to a LG-ROM encoder circuit 139a, a first Y-pass gate circuit 81, Data Register 82, a second Y-pass gate circuit 83 and the Match-address Aggregator 141a.

In an embodiment, a first LG group of the ROM CAM array includes N LBL lines such as LBL¹1 to LBL¹N forming N metal parasitic capacitors C_{LG}s between two adjacent LGs. Two LGs are divided by one row of N MLBL transistors with their gates commonly tied to a BLG1 line. For each LG with 8 Blocks, there are 4 CSL lines, referred as CSL1 to CSL4, each being shared by two Blocks. Each LG connects to two rows of N NMOS transistors of MLBLs in two physically adjacent Blocks with a virtual Y-word register referred as Y-PB with a length of 64-paired complimentary WLs and WLBs, and one GSL and one SSL lines using the horizontal parasitic poly capacitors as the temporary capacitor-based dynamic CACHE Registers, DCR.

Again, no HV charge pump circuit is needed for this LG-based ROM CAM array and the Block decoder has no local pump circuit as well. The search operation is similar to NAND-CAM array shown in FIG. 2A.

FIG. 2I shows the cross-sectional and topological view of two desired interleaving LBL metal lines, m0 and m1, used in a NAND block as shown in FIG. 1A as well as NAND-CAM array of the present invention. As shown, two sets of LBL lines adopted by this 2-level hierarchical-BL NAND-CAM array structure are laid at two different levels, m0 and m1. Each set is made of a plurality of tight metal line with 1λ, width and 1λ, spacing. One set is interleavingly mixed with the other set in assigning a non-zero LBL voltage, V_{LBL}, or 0V in respective Odd or Even LBL lines at m0 and m1 level.

In a specific embodiment, one Odd m0 LBL line having V_{LBL1} is connected to a first drain node of a first (Odd) string for storing a first 1-bit of data. One adjacent Even m0 LBL line is not connected to a second drain node of a second (Even) string but is grounded at 0V. These are further repeated in every other Odd and Even strings in layout so that all Even m0 LBL lines serve first-level shielding LBLs for all Odd m0 LBL lines. Likewise, one Even m1 LBL line with V_{LBL2} is connected to the second drain node of the second (Even) string for storing a second 1-bit of data. One adjacent Odd m1 LBL line is not connected to the second string but is grounded, thereby serving as one of second-level shielding LBLs.

As shown, in all embodiments of NAND-CAM arrays of the present invention with 2-level LBLs being configured as above, a full page data is divided into two interleaving groups with two alternatively mutually shielded m0 and m1 LBLs. As a consequence, an All-BL, All-threshold-state, and alternate-WL NAND program scheme can be realized without suffering any AC coupling effect during nLC read and verify operations.

FIG. 3A is a simplified diagram of preferred memory divisions of this NAND-CAM array divided into 3 hierarchical broken GBL and LBL groups according to an embodiment of the present invention. This diagram is merely an example, which should not unduly limit the scope of the claims. One of ordinary skill in the art would recognize many variations, alternatives, and modifications. As shown, this NAND-CAM array 15 is electrically divided into 3 hierarchical BL groups in layout but 2-level topologically in process. From top to the bottom of the figure, the NAND-CAM array with N₁ global bit lines (GBLs) at top-level m2 is divided into J HG groups 150 and each GBL is divided into J broken-GBLs. All HG groups are formed in same P-well within a same DNW. Any two adjacent HG groups are connected by a row of N₁ HG-divider devices MGBL commonly gated by a BHG signal. There are total J−1 rows of MGBL devices respectively gated by J−1 BHG signals such as BHG1 to BHGJ−1.

In an embodiment, the length of each HG group 150 can be made equal or unequal, depending on the design applications. For example, if the J-th group HGJ is made physically as the nearest HG to the PB, then the length of HGJ can be made the shortest one because the sensed nLC read data has the least charge-sharing (CS) dilution between a selected LBL parasitic capacitor C_{LG} (see definition below) of a selected LBL associated with a bottom-level LG group within the HGJ group and the GBL parasitic capacitor C_{HG} associated with the HGJ. On the contrary, the first HG group HG1 is preferably made with a largest GBL capacitor C_{HG1} because the sensed nLC read data from LGs within HG1 will suffer more CS-induced signal dilution, thus it needs more capacitance for LBL capacitor C_{LG1} signal to ensure the reliable nLC data when all C_{LG}s in each GBL column are using the same SA with same amplification capability.

Each HG group 150 is being further divided into L middle-level MG groups 140 connected in parallel through MG's Y-pass circuit 110 between N₁ broken-GBL metal lines at top-level m2 and N LBL metal lines at middle-level m1/m0 running through each MG group only. In a specific embodiment, N₁=N/2, i.e., one broken-GBL is shared by 2 LBL lines through MG's Y-pass circuit 110.

Each MG group 140 is further divided into J′ bottom-level LG groups 120 so that each LBL is divided to J′ broken-LBLs by J′−1 LG-divider devices MLBL gated respectively by J′−1 signals such as BLG1 to BLGJ′−1. All N broken-LBLs metal lines in one LG group 120 form one page of capacitor-based N-bit dynamic cache register (DCR) 130. Each bit is a metal line capacitor such as C_{LBL1}, C_{LBLN}, where C_{LBL1}⁼⁼C_{LBLN}⁼C_{LG}. In an example, N-bit is 8 KB or 16 KB.

Furthermore, each MG forms one C_{MG} of a larger sized 1-bit of DCR, which is the minimum capacitance used for a batch-based nLC program-verify, erase-verify, and read operation. In this preferred NAND-CAM, program operation does not need to consider the Charge-sharing effect between each C_{MG} and whole C_{HG} (C_{HG}=J×C_{MG}). By contrast, in DRAM read operation, the CS effect needs to be well planned for cell signal. Here, each C_{MG} acts as one DRAM cell capacitance, while the whole C_{HG} acts as C_{BL} of DRAM. One role of HG-divider device MGBL and LG-divider device MLBL is used as the respective broken GBL and broken LBL devices and another role is used as the programmable device to expand the each DCR's capacitance. Each C_{HG} forms one largest DCR bit capacitance, while each C_{MG} forms the medium DCR bit capacitance and each C_{LG} forms the minimum DCR bit capacitance of this NAND-CAM array or NAND arrays of previous pending patents filed by the same inventor of this application. The minimum length or capacitance of each C_{LG} can be one block-length at the expense of higher area overhead of more number of MLBL devices and resistance of whole GBL from bottom to top in each column of NAND-CAM array.

In an embodiment, each 2D or 3D NAND-CAM block includes N NAND-CAM strings cascaded in WL-direction (row-direction or X-direction). In an example, a basic 2D NAND string of a 2D block is one shown previously in FIG. 1A, as long as the NAND-CAM arrays are configured into same hierarchical BL structures with either CSL-based or LBLps-based MLs and SAs for Y-word search applications. During program or Y-word search, all BHG signals are set to 0V to isolate all adjacent LGs 120 to allow each N-bit DCR 130 to store the nLC program page data or to store precharged voltages independently and collectively.

But during the concurrent nLC program-verify or read operations of this NAND-CAM array, all J′−1 BLG signals are set to Vdd or Vread so that all LGs 120 are connected together within one MG 140. In this case, each C_{LG} capacitance is increased by J′−fold to a C_{MG} (C_{MG}=J′×C_{LG}) so that the read and verify voltages stored are calculated in unit of C_{MG}. As a result, the subsequent charge-sharing (CS) operation for the batch-based concurrent read, program-verify, and erase-verify operations can have a stronger CS-signal which can be reliably sensed by each corresponding SA in each DR. Outside the NAND-CAM array, a row of ISO devices 11, as shown in FIG. 2A or 2B or 2C, is inserted to isolate NAND-CAM array HV operations from damaging those LV circuits such as DR 30, the LV CACHE (SCR) registers 32, Data I/O Buffer 90, and Byte-based I/O pad and Match Address Aggregator 141 and more. Note, this memory circuit is also used for ROM CAM array during the wafer testing for a faster Read using CS-technique.

FIG. 3B is a simplified diagram of a detailed MG Multiplexer circuit as seen in FIG. 3A. This diagram is merely an example, which should not unduly limit the scope of the claims. One of ordinary skill in the art would recognize many variations, alternatives, and modifications. As shown, a MG Y-pass circuit 110, as seen on upper part of FIG. 3A includes N₁ 2/1 unit circuit 115 made of one paired Y-select transistors, one Odd LBL device of MMGo and one Even LBL device of MMGe, respectively gated by 2 signals MG¹o to MG¹e. In general, each unit 115 of the Y-pass circuit 110 can be a M₁/1 circuit, where M₁=2, 4, or higher. Each M₁/1-unit circuit comprises M₁ NMOS Y-select transistors gated by M₁ signals. In FIG. 3B, it is referred as 2/1-unit. The pair of Y-select transistors shares one top-level GBL line. Note, if LBLs use both m0 and m1 levels for providing LBL-LBL shielding effect by grounding every Odd/Even LBL at m0/m1 level, the top-level GBL is at m2 level above m0 and m1 level. If LBLs only use m0 level, then the top-level GBL is at m1 level to save one metal layer at the expense of providing no LBL-LBL full shielding effect.

The MG Y-pass circuit 110 acts as a Multiplexer or MG-divider to separate N₁×M₁ lower-level (m0/m1) LBL lines from top-level (m2) GBL lines such as GBL¹1 to GBL¹N₁. In other words, each GBL is shared by M₁ local LBL lines. But the number of GBL is equivalent to the number of PB. Therefore, the size of PB of the present invention is reduced by N₁-fold, where M₁ is defined by the equation of N₁=N/M₁. In this example shown in FIG. 3B, M₁=2, each GBL line is split to two LBL lines by each 2/1 unit circuit 115. Therefore, the size of PB of the present invention is reduced by 2-fold. Following the same design, more reduction like 4-fold, 8-fold can be realized by having 4 or 8 LBL lines sharing one GBL line.

The device characteristics of MIVIGo to MIVIGe are preferably made identical to regular NAND string select transistors MS or MG as a NMOS 1-poly transistor with BVDS specification set to be about Vdd if a LV precharging scheme is used in certain embodiments or set to be about Vinh 7V or higher if a MHV precharge scheme is used in other embodiments. This MG Y-pass circuit is also used for ROM CAM but corresponding device BVDS of Y-select transistors MIVIGo and MMGe is a LV of Vdd.

During final search of the matched LBL address of all NAND-CAM array of the present invention, there are two steps to connect one matched LBL line to the corresponding SA via this circuit. In a first step, connecting Odd LBL line through each corresponding GBL to the SA first by setting MG¹o=Vdd and MG¹e=Vss. In a second step, connecting Even LBL line through each corresponding GBL by setting MG¹o=Vss and MG¹e=Vdd. To save the bit number of DB, one bit of PRB and one bit of SCR are used to store the sensed bit data from Odd and Even LBL cells of the WL from the matched block.

FIG. 3C is a simplified diagram of a detailed LG group circuit as seen in FIG. 3A. As shown, the LG group circuit 120 is one of the circuit block seen in FIG. 3A in the preferred NAND-CAM array. In an embodiment, this circuit includes H NAND blocks 127 such as Block₁ to Block_{H} connected by N bottom-level (m0/m1) LBL lines such as LBL¹1 to LBL¹N and one shared LBLps-precharger 125 per one LG circuit 120. In this example of FIG. 3C, H=8.

Each LBL-precharger includes N 1-poly NMOS transistors MLBLS, commonly gated by a control signal PRE, configured to respectively connect to LBL¹1 to LBL¹N across all H blocks to one horizontal metal power line LBLps. The PRE signal is used to connect or disconnect one selected LBLps line to or from all N C_{LBL} or N C_{LG} of each selected LG of NAND-CAM array. Each metal power line LBLps is connected to one common power-supply (not shown). The power supply is configured to provide voltage up to a predetermined Vinh for program-inhibit and precharging LBL for pipeline nLC program, nLC read, and erase-verify operations. Alternatively, the same LBLps power line is also served as a discharge line connected to a set voltage below Vdd down to ground level of 0V. It is also used to precharge the Vdd-Vt by setting LBLps=Vdd during the Y-word search operation if LG-SA and LG-ROM are used as seen in FIG. 2A.

In an embodiment, formation of the metal power line LBL¹ps can use a layout technique by mixing two metal line levels m0 and m1 to get around corresponding m0/m1 LBL connections between two physically adjacent LGs to avoid increasing the number of metal layers in this NAND-CAM array for cost and line resistance reduction. This LG group circuit is also used by LG-based ROM CAM.

In a specific embodiment, the whole LBL lines, LBL¹1 to LBL¹N, are interleavingly split into an Even group and an Odd group with their respective common gates of 1-poly NMOS transistors connected by two control signals PRE¹e and PRE¹o. A function of this LG group circuit 120 is to form a preferred N C_{LG} or N C_{MG} capacitors as a N-bit DCR that independently and flexibly allows the least precharging and discharging current for performing preferred ABL nLC pipeline program and ABL nLC pipeline read and verify operations.

FIG. 3D is a simplified diagram of a detailed ISO circuit as seen in FIG. 3A. As shown, a preferred ISO circuit 11 is configured to dispose a row of N₁ 20 V NMOS 1-poly devices MI as a buffer to isolate one 20V HV erase voltage at each GBL line of GBL^{J}1 to GBL^{J}N₁ in the NAND array from damaging corresponding N₁ LV PB located in the peripheral circuit. Each MI device connects one of GBL nodes of GBL^{J}1 to GBL^{J}N₁ to one of respective data lines of DL1 to DLN₁ of the PB. Note, in current example, N₁ is 8 KB.

The isolation is achieved by coupling the common gate signal ISO of the row of MI devices to ground during erase operation but to a voltage ≧Vdd to connect the NAND-CAM array to DR during other operations such as nLC's program and read operation, as well as nLC page data loading from the PB into N DCRs in the NAND array (as described earlier). During all search operations based on NAND-CAM embodiments of the present invention, the ISO circuit is turned on to connect NAND-CAM array to the PB. The MI device is made outside the NAND array area without being formed within the same P-Well (PW) in a deep N-well (DNW) as the regular NAND memory cells. The BVDS design of each MI device is made to sustain a required erase voltage Verase of more than 20V generated from the selected PW in the DNW of NAND-CAM array during erase operation so that all LV devices placed in the peripheral area outside the NAND-CAM array can be isolated from being damaged by this Verase. In this example, the number of ISO devices MI are reduced to N₁=N/2, half of the number of LBLs. However, this circuit is eliminated from LV ROM CAM because there is no need of 20V protection as no PW and DNW are used by ROM CAM array where the ROM cell array is directly formed on P-substrate.

FIG. 4A is a diagram of a sense amplifier of Y-word searching circuit for LG-based searching operation according to an embodiment of the present invention. This diagram is merely an example, which should not unduly limit the scope of the claims. One of ordinary skill in the art would recognize many variations, alternatives, and modifications. As shown, a Y-word searching circuit is designed with a LG-based LBLps match-line (ML) and sense amplifier (SA) 138a coupled to a simplified BIAS generator circuit. A matched NAND string with a current flow direction is shown for one matched LG within the preferred NAND-CAM array shown in FIG. 2A of the present invention.

The LG-based LBLps-ML scheme means to use one LBLps line per LG as a ML for the NAND-CAM. This ML is shared by H blocks within one LG. In other words, in this LG-based NAND-CAM it only allows one out of H blocks of each LG to be turned on at a time to perform a preferred Y-word search operation if Y-word length is one block, regardless of one full block length without using any maskable (“Don't Care”) bits or one partial block length using the maskable bits.

In a specific embodiment, the LG-based Y-word Search operation with 1-block Y-word length includes 3 steps, as briefly described below.

1) C_{LG} precharge step. This is done by setting a gate signal BIAS1 to turn on NMOS device MN1 in the LG-based SA 138a. When the gate signal is coupled with a V_{BIAS1max} voltage in each LG-SA 138a to precharge corresponding ML and the LBLps line via a MISO device biased with V_{ISOM}≧V_{READ} to reduce its resistance, with a gate voltage V_{BIAS3} for the LBL-precharger device MLBLS being set to Vdd and a gate voltage V_{BIAS2} for another NMOS device MN2 being set to Vss with an enabled BIASP node initially.

All selected 16 KB LBL capacitors C_{LG}s (only one C_{LG} is shown in FIG. 4A) within one LG are precharged to V_{BIAS1max}−Vt in one cycle, where Vt is the threshold voltage of each MN1 of LG-SA 138a. This can be done by setting PRE signal to Vdd in one-shot in accordance the circuit shown in FIG. 3C to turn on LBL-precharger transistors such as MLBLS1 to MLBLSN. Also, BHG signal is set to 0V (see FIG. 3A) and GSL signal (for all string-select devices of a selected block) is set to 0V to block NAND string leakage. After this step, all 16 KB capacitors C_{LG}s in each LG charged up with V_{BIAS1max}−Vt are locked there when the PRE signal is switched to 0V in one-shot at the beginning of search operation. Now, it is ready for the subsequent discharge operation when the search operation starts and when the Y-word matches one NAND-CAM string in one of H blocks within the corresponding LG group.

2) ML-LBLps setup step. In this step, every LBLps line per LG in the NAND-CAM array is connected to every corresponding ML and is connected to a SAO node of the LG-SA 138a by setting gate signal BIAS2 of the NMOS device MN2 to a predetermined voltage to be in conducting state with V_{sAO}=Vdd and V_{OUT}=Vss via an initial precharge operation. The LG-SA 138a is enabled by setting control signal BIASN to Vdd to set a desired BIASP voltage for current-mirror control over a load PMOS device MP1 and set a PB node voltage at Vdd to shut off the initial precharge operation before the connection between the ML and SAO node. In this step, V_{BIAS1max} is set up a little higher to charge maximum voltage on the ML correspondingly a little higher than the previous value of V_{BIAS1max}−Vt, where Vt is the threshold of MN1 NMOS device with certain bias conditions defined below: V_{BIAS1min}<V_{BIAS2}<V_{BIAS1max}. A minimum ML voltage is V_{BIAS1mub}−Vt−ΔV, where ΔV is induced by one conducting NAND string that matches the Y-word. A maximum ML voltage is V_{BIAS1max}−Vt.

3) ML search step. The SAO node is also connected to ML and detects the ML voltage. Turning on all blocks by setting the following conditions: setting string-select signals SSL and GSL to Vdd and common source line CSL to Vss; setting all WL voltages to VR or Vread, depending on Y-word search data; and setting all dummy cell signals DWLU and DWLL to Vdd. When Y-word matches stored complimentary bits of a NAND string, then the one matched string is turned on to pull the corresponding LBL voltage to low, thus LBLps line voltage to low, thus ML becomes a Logic-low at a voltage of V_{BIAS1min}−Vt−ΔV, where ΔV≧0.1V. As a result, the SAO node is also pulled to V_{BIAS1min}−Vt−ΔV which is lower than a trip point of Inverter INV in the LG-SA 138a. The OUT node of the LG-SA of the matched LG switches from low to high (at Vdd) to indicates the detection of a matched block within the matched LG. Thus, the address of the matched LG can be returned to an Aggregator by the help of a LG-ROM circuit (see FIG. 2A) connected to the OUT node.

For other N−1 unmatched LBLs in each LG, their LBL voltages remain at V_{BIAS1max}−Vt without dropping or charge-leaking to the shared LBLps line so that the ML search speed would not be degraded. As a result, only one matched C_{LBL} capacitance loading will be triggered on each corresponding ML and LBLps line, thus a very fast search speed can be achieved under this LG-based ML scheme.

FIG. 4B is a diagram of a sense amplifier of Y-word searching circuit for Block-based searching operation according to an embodiment of the present invention. This diagram is merely an example, which should not unduly limit the scope of the claims. One of ordinary skill in the art would recognize many variations, alternatives, and modifications. As shown, a Y-word searching circuit is designed with a preferred Block-based CSL-ML and BLK-SA 138b in an embodiment of a NAND-CAM array shown in FIG. 2B of the present invention. The Block-based ML scheme means to use one CSL line per two blocks as a ML. Any two adjacent NAND blocks share one ML. Each LG includes H blocks, thus has H/2 CSL lines respectively connected to H/2 SAs per block for search operation. In an embodiment, two initial steps are performed to determine a last matched block for initiate a Y-word search operation. In the first step, all blocks are turned on to find the matched the matched CSL line or ML. Next, in the second step, it is determined which one out of 2 blocks of sharing same CSL or ML is the matched block for the Y-word search operation if the Y-word length is one block, regardless of one full block length without using any maskable bits or one partial block using the maskable bits.

The Block-based Y-word search operation with 1-block length is performed in 3 steps as explained below. 1) C_{LG} precharge step. All selected 16 KB LBL capacitors C_{LG}s within all LGs are precharged to a voltage Vdd-Vt by coupling each metal power line LBLps per LG to Vdd via a driver (not shown) connected to one end of the LBLps line. The precharge can be done in one cycle by turning N LBL-precharger transistors such as MLBLS1 to MLBLSN in every LG in accordance with circuit shown in FIG. 3C by setting common gate signal PRE to Vdd in one-shot with a predetermined duration. As a result, all N C_{LG}s in all LGs are precharged with a voltage of Vdd-Vt where Vt is the threshold voltage of each NMOS device MLBLS as seen in FIG. 4B and FIG. 3C, with every BHG gate signals being set to 0V to block the current flow between any two adjacent LGs. After this step, all 16 KB C_{LG}s in each LG are filled up with charge of Vdd-Vt. At least one matched CSL (or ML) line is charged up from Vss to a Logic-high level when a gate signal ISOM of 1-poly transistor MISO is set to 0V. Now, it is ready for subsequent discharged operation when the search operation starts and a Y-word matches one NAND string in one of H blocks within the LG. In an example, H=8.

2) LBLps and ML setup with BLK-ROM enabled. In this step, 4 CSLs (assuming H=8) in each LG are respectively connected to 4 corresponding MLs and 4 BLK-SAs 138b by setting corresponding V_{ISOM} to V_{READ} to make the MISO device at a low-resistance state and one Logic-high voltage from CSL can be fully passed to each corresponding ML. As a result, only the matched NAND sting in one matched block of one matched LG would charge up the corresponding ML to a Logic-high level to pull down a NMOS 1-poly transistor MN1 in the BLK-SA 138b so that voltage at SAO node of the BLK-SA 138b switches from initial precharged Vdd to Vss, causing voltage of OUT node of the BLK-SA to switch from Vss to Vdd. The voltage level of each Logic-high of ML is determined by 3 Vgs-Vt in each NAND string. If the ML voltage is not high enough, then another NMOS 1-poly transistor MN2 in the BLK-SA 138b can use a native device with Vt less than 0.5V of an enhancement NMOS device. In other words, the NMOS 1-poly transistor MN1 can be either an enhancement NMOS device or a native device, depending on voltage level of ML Logic-high. Typically, for Vdd=3V operation, voltage for a Logic-high ML is much higher than Vt=0.5V of an enhancement NMOS device, thus the MN1 device should be able to use an enhancement NMOS device. By contrast, when working at a lower Vdd=1.6V, then it is preferable to use a native NMOS device for the MN1 for the BLK-SA to properly perform SA operation. Note, during operation of the BLK-SA 138b, VENBKMLB=0V.

For other N−1 unmatched LBLs in all unmatched 127 LGs, their V_{LBL}s at Vdd-Vt cannot be passed to corresponding 511 CSL lines and subsequently 511 MLs because every unmatched string data blocks the current flow between corresponding LBL and CSL. As a result, thus voltages of all other 511 MLs remain at Vss level. As a result, voltages of all SAO nodes of all unmatched blocks remain at Vdd and OUT node at Vss.

3) Identify one match-block from one pair of matched blocks that share the matched CSL. This step is performed with the BLK-ROM circuit 139b (see FIG. 2B). More details on performing this step will be shown in terms of FIG. 5E and FIG. 5F below. Once one match-block of the two matched blocks is found via above step, then the one out of the two blocks can be identified via a ML-ROM circuit (not shown) connected to each OUT node of all BLK-SAs of this Block-based NAND-CAM.

FIG. 4C is a diagram of a sense amplifier of Y-word searching circuit for Block-based searching operation according to another embodiment of the present invention. This diagram is merely an example, which should not unduly limit the scope of the claims. One of ordinary skill in the art would recognize many variations, alternatives, and modifications. As shown, a Y-word searching circuit is alternatively designed with a preferred Block-based CSL-ML and BLK-SA 138c based on NAND-CAM array shown in FIG. 2B of the present invention. This Y-word search scheme also uses the Block-based ML scheme by employing one CSL line per block as a ML. But the BLK-SA design uses a DRAM-like clocked Latch-type SA.

In an alternative embodiment, DRAM-like clocked Latch-type SA 138c is used for a LV Vdd operation such as 1.8V or below, a final level of ML Logic-high voltage may not be high enough over threshold voltage of the NMOS transistor MN1 to allow the SA to be properly operated under previous scheme. Thus DRAM-like BLK-SA 138c with a much high amplification gain without any NMOS Vt concern is used for achieving more reliable sensing margin on ML Logic-high voltage.

In the alternative embodiment, the Block-based Y-word search operation with 1-block length is performed in 3 steps. 1) C_{LG} precharge step. This is same as the first step for performing Block-based Y-word search operation under previous embodiment shown in FIG. 4B. All selected 16 KB LBL capacitors C_{LG}s within all LGs are precharged to Vdd-Vt by coupling each LBLps line to Vdd via a LBLps driver. The precharge can be done in one cycle by turning N LBL-precharger transistors such as MLBLS1 to MLBLSN in every LG in accordance with circuit shown in FIG. 3C by setting common gate signal PRE to Vdd in one-shot. As a result, all N C_{LG}s in all LGs are precharged with a voltage of Vdd-Vt where Vt is the threshold voltage of each MLBLS device as seen in FIG. 3C, with every BHG gate signals being set to 0V to block the current flow between any two adjacent LGs. After this step, all 16 KB C_{LG}s in each LG are filled up with a voltage Vdd-Vt and at least one matched CSL is charged up from Vss to a Logic-high level when V_{ISOM} is set to 0V. Now, it is ready for subsequent discharged operation when the search operation starts and a Y-word matches one NAND string in one of H blocks within the LG. In an example, H=8.

2) SA setup step. This preferred DRAM-like BLK-SA 138c is configured with a two-step sensing scheme. The first sensing includes latching two sensing voltages on both ML and V_{REF} into respectively two capacitors CP1 and CP2 by setting a common gate signal T6 at Vdd or higher for both MN4 and MN6 devices and another common gate signal T7 at Vss for MN5 and MN7 devices with T8B being applied with an one-shot pulse of Vdd and T8 being kept at Vss to shut off the DRAM-like BLK-SA 138c. Note, V_{REF}=½ of ML Logic-high voltage from an on-chip voltage generator. The ΔV of SA input is ½ of the ML Logic-high voltage, which is more than 200 mV for this search operation. The second sensing includes transferring the two sensing voltages latched at CP1 and CP2 on first step to two opposite nodes Q and QB of the latch circuit by setting one-shot pulse of Vdd to T7 and Vss to T6 with T8B being set at Vdd and T8 being at Vss to shut off the DRAM-like BLK-SA 138c. Now, the BLK-SA 138c is enabled to amplify the latched signal of ΔV. First it sets T8B to Vss followed by setting T8 to Vdd. After this step, a digital pattern of Vdd/Vss is amplified at the SAO node. For the matched pair of blocks, the SAO node is at Vss the same as FIG. 4B.

3) LBLps and ML setup with BLK-ROM enabled. In this step, 4 CSLs in each LG are respectively connected to 4 corresponding MLs and 4 BLK-SAs 138c by setting V_{ISOM}=V_{READ} to make the MISO transistor at a low-resistance state and one Logic-high voltage at CSL can be fully passed to each corresponding ML. As a result, only the matched NAND string in one matched pair of blocks of one matched LG would charge up the ML to a Logic-high level. Similarly, for other N−1 unmatched LBLs in all unmatched 127 LGs, all V_{LBL}s at Vdd-Vt cannot be passed to the corresponding 511 CSLs and 511 MLs because each unmatched string data blocks the current flow between corresponding LBL and CSL. As a result, all other 511 ML voltages remain at Vss level. Thus, voltages of all SAO nodes of the SAs associated with all those unmatched blocks remain at Vdd and corresponding OUT nodes at Vss.

Finally, it is to identify one match block from one pair of matched blocks that share the matched CSL. Again, this has to be done with the BLK-ROM. The details will be shown in association with FIG. 5F. Once one of matched 2-block pair is found above, then the one out of the two blocks can be identified via a ML-ROM connected to each OUT node of all SAs of this Block-based NAND-CAM.

FIG. 5A is a diagram of detailed circuits of a LG-ROM and LG-SAs along with LBLps as ML for operating the preferred NAND-CAM of FIG. 2A under Y-word search in worst-case scenario. As shown, a detailed portion of the LG-ROM 139a and LG-SAs 138a is provided for performing a preferred Y-word search operation with LBLps-ML scheme of the present invention. An associated Low-voltage LG-ROM circuit 139a and is configured to find the address of one matched block in accordance with the NAND-CAM array shown in FIG. 2A. This LG-ROM and LG-SA LBLps-ML search circuits can only find one matched LG address of 7 bits of A[24], A[25], A[26], A[27], A[28], A[29], and A[30] out of 128 LGs. To further find one matched block out of above 8 blocks of one matched LG, an On/Off Sequential-block search method is proposed.

There are best-case-scenario (BCS) and worst-case-scenario (WCS) cycles to search the matched block. The WCS search cycle means that the matched block is not the first block of eight blocks in each matched LG. Instead, it is the last or 8th block found to match Y-word after 7 sequential On/Off search operation. By contrast, the BCS search cycle means that the matched block is the first block (first block of H=8 blocks in one LG) found to match Y-word in the first cycle without further turning on and off of the rest of 7 unmatched blocks. The detailed waveforms of operating this LV LG-ROM 139a in WCS and BCS are shown respectively in FIG. 5B and FIG. 5D below.

Taking total 1,024 blocks and 8 blocks per one LG as an example, the number of LG-ML is 128 such as LBLps1 to LBLps128 and the number of LG-SAs 138a is also 128 as depicted from top to bottom across the whole array. Each LG-SA 138a has a single input LBLpsN and one associated output OUTN, where N=1 to 128. An ISOM 20V device MN3 is placed to separate the NAND-CAM HV array from LV part of the LG-SA 138a.

For fully encoding 1,024 blocks of 128 LGs of this LG-based ML NAND-CAM (FIG. 2A), it requires the LV LG-ROM 139a to have 7 addresses, which are defined as A[24], A[25], A[26], A[27], A[28], A[29] and A[30] as seen in FIG. 5A.

Every ROM cell of the LV LG-ROM 139a uses a regular LV enhancement NMOS transistor with an optimal size to make ROM encoding speed less than 20 ns from 128 inputs (or 128 SA outputs) to the 7 address outputs of the LV LG-ROM 139a.

ROM configuration is a fixed connection for each encoding output. For example, OUT1 is connected to 7 NMOS pull-down devices, thus it generates A[24]==A[30]=0000000 when OUT1=Vdd. In other words, when LBLps1 is at Logic low, OUT1 node will be at Vdd, indicating that the LG1 contains the matched block of Y-word search. The remaining 127 outputs of OUT2 to OUT128 are set at Vss. In other words, for each Y-word search, only one OUT node is set to be high for decoding 7 addresses. The last extra row of the LV LG-ROM 139a has only single NMOS pull-down device M22 reserved just for LBLps128 because this LV LG-ROM cannot distinguish a fake or real logic state of LBLps128 when OUT128 is at Vss.

In an embodiment, the LG-ROM array operation can be enabled by setting a common gate signal MPREB of a row of PMOS devices to Vss at the same time with 128 LG-SAs (as seen in FIG. 4A) being enabled by biasing PB node to Vss, DIS node to Vss, then biasing PB to Vdd and DIS node to Vdd along with one predetermined BIASN signal being applied to the gate of transistor MN4 connected to Reference-current generator circuit made of one MN4 and one MP4 being configured into a PMOS-diode as shown in FIG. 4A. The reference current Iref=VA/Rref=(VBIASN-Vt)/Rref is predetermined. The size ratio of PMOS device MP1 over MP4 in LV ROM 139a is to set a ratio R, defined by MP1-resistance over NAND-string resistance, optimally at least no smaller than 3 for a reliable sensing. The NAND-string resistance is resistance of one matched string that matches the Y-word with a length less than or equal to one block of the present invention.

Referring to FIG. 4A, each ML is initially precharged to a V_{BIAS1max}−Vt by NMOS device MN1 with its gate being applied to BIAS1 to push off another NMOS device MN2 when BIAS2 voltage is less than BIAS1 voltage so that all SAO nodes stay at the initial Vdd level and VOUT stays at Vss. Once the matched string conducting the current, then ML voltage is pull down so that MN2 is in conduction state to set SAO node at a same ML voltage at V_{BIAS1min}−Vt-ΔV below the predetermined trip point of SA's INV to turn on the LG-SA 138a. The OUT node of each SA of the matched LG would switch from its initial Vss to Vdd and the next stage LG-ROM 139a will encoder the corresponding 7 addresses of A[24] to A[30] for the matched LG and Block by 7 sequential on-and-off methods as explained in FIG. 5B waveforms below.

FIG. 5B is a diagram of several key timing waveforms of Y-word search operation of the NAND-CAM of FIG. 2A in worst-case scenario. As shown, several key WCS searching waveforms are provided with relative slow search speed to find the 8^{th} block of 8 blocks in one matched LG for Y-word search scheme using the LG-based LBLps as a ML based on LG-SAs circuit 138a shown in FIG. 4A and LG-ROM circuit 139a as shown in FIG. 5A, as well as in accordance with NAND array (group and block) structure disclosed in FIG. 2D and FIGS. 3A-3C. The WCS means that addresses of corresponding 8 blocks are turned off sequentially in 8 cycles, and only upon the 8^{th} or last cycle, the matched 128^{th} block is found when the metal line LBLps switches from its initial “Logic-low” as the 128^{th} LG is found to be matched with Y-word. The matched LG corresponds to all eight blocks being in “on” state of “FF” to a “Logic-high”. The 8^{th} block is found to be the matched block after 8 SSLs of corresponding String-select devices of 8 blocks are orderly turned off one by one in 8 cycles through On/Off codes as shown as FF→FE→FC→F8→F0→E0→C0→80→00. Note, here “1” means “ON” and “0” means “Off” for each SSL signal in this Sequential On/Off operation. 8 SSLs of 8 corresponding blocks of the matched LG are in “1” state, thus 8 “1” make the code of “FF.” Decoding 8 SSLs of 8 blocks of one LG requires 3 additional bits to decode the matched block that contains the matched Y-word with the length of 1-block.

During the searching period of the 8^{th} matched block, all unmatched 127 LBLps lines (LBLps1 to LBLps127) stay in a “Logic-high” state without flipping 127 corresponding LG-SAs, thus 127 OUT1˜OUT127 signals remain at Vdd and only OUT128 switches from Vdd to Vss as seen in the waveform of FIG. 5B.

In a specific embodiment, the key waveforms under a WCS search scheme include signals of PRE1-PRE128, LBLps1-LBLps128, 8 block addresses of BLK[8:1], 7 LG addresses of A[30:24], LASTLGB, OUT128, DIS, BIASP, FB, BIAS2, BIAS3, etc., as seen in FIG. 5B. The single matched block is found to be located at the 8^{th} or last block of the last group LG128 of total 128 LG groups by executing the following operations:

1) An one-shot pulse up to V_{AD} is applied initially to each enable signal from PRE1 to PRE128 to enable all 128 SAs.

2) All 128 LBLps lines are precharged at V_{BIAS1max}−Vt with Logic high in each LBLPs line or ML with all N (16 KB) LG-based capacitors C_{LG}s as DCRs being filled with charges of Vdd-Vt. Only the single matched LBLps128 line in the 128^{th} LG pulls down the 128^{th} ML to a Logic low level, while the rest of 127 unmatched LGs sustain corresponding 127 MLs at a Logic high level. Thus, the address of the matched 128^{th} LG is found.

3) This WCS matched address of the 128^{th} matched LG has a block address at FF (8 bits) to keep the 128^{th} ML at Logic low. An On/Off sequential technique is applied in 7 cycles to identify which one of 8 blocks in the 128^{th} LG is the real matched block. 4) The 8 blocks had 3 extra decoding addresses over 7 LG addresses from A[24] to A[30]. These 3 extra addresses are assigned with A[21], A[22], and A[23] as indicated in BLK[8:1] waveform.

5) The selected block is turned off sequentially in 7 cycles from initial FF, to FE, FC, FB, F8, then C8, and finally 80 to reset LASTGB signal back to Vdd from Vss. This is done when the 8^{th} or last block of the 128^{th} LG shuts off cell-string conducting current to reset the LBLps128 line back to a Logic high level to reset 128^{th} SA. Thus OUT128 node is set to Vss and LASTLGB is set to high to accurately encode total 10 bits of the 8^{th} block of the matched 128^{th} LG as the matched block for this WCS Y-word search operation.

In another specific embodiment, the voltages levels of BIAS3, BIAS2, and BIAS1 of each SA are properly set with an optimal value to properly operate this preferred cascade LG-SA in ABL manner to sense all 16 KB C_{LBL} voltages without experiencing any C_{LBL}-C_{LBL} AC coupling effect of all 16 KB C_{LG}s because only one match C_{LBL} in whole 16 KB C_{LBL}s will pull down the corresponding LBLps line, regardless of either 2-metal (m0/m1) LBL scheme or 1-metal m0 LBL scheme. In an 1-metal C_{LBL} array scheme, two HBL settings in accordance with 8 KB Old and 8 KB Even MLBLS transistors and two separate gate controls such as BIAS3e and BIAS3o (not shown) for a HBL program are required. But the 1-metal C_{LBL} search sensing can still be done in an ABL manner because again only one match C_{LBL} will pull down the voltage of LBLps ML line. Thus this LG-based ML and LG-ROM have combined to achieve a very fast Y-word search speed of less than ˜50 μs to identify the address of matched paired-blocks because all paired LGs searches are performed with one cycle that takes about 30 μs from DCR precharge and discharge in all LGs, SA, and ROM circuit setup plus another 8 cycles for performing On/Off Block searching take about 16 μs, or 2 μs per cycle, in WCS to find the 8^{th} block as the matched block of the matched LG. In summary, total Y-word search for finding out 10-bit address of the matched block takes about 50 μs. For total 1K blocks, on average, the estimated search time for each block of 16 KB Y-words is about 50 ns for SLC NAND CAM. The average per Y-word search speed is 50 μs/16 KB ˜0.3 ps. For a MLC NAND CAM, it would take about 110 is to find out 11 addresses of the matched block of total 1,024 blocks in a NAND CAM array.

FIG. 5C is a diagram of detailed circuits of a LG-ROM and LG-SAs using each LBLps as one ML for operating the preferred NAND-CAM of FIG. 2A under Y-word search in best-case scenario. FIG. 5D is a diagram of several key timing waveforms of Y-word search operation of the NAND-CAM of FIG. 2A in best-case scenario. As shown jointly in FIG. 5C and FIG. 5D, the BCS Y-word search waveforms with corresponding search speed are provided for the same LG-based ML and LG-ROM circuit with 128 identical units of the basic LG-ROMs 139a as shown in FIG. 5A and 128 LG-SAs 138a shown in FIG. 4A with same 128 individual LBLps power line acting as 128 MLs.

Referring to FIG. 5C, the first search sensing is find out one matched paired LGs in ABL manner, thus the first metal power line LBLps1 is a ML having a value of “Logic low”, as shown in FIG. 5D. The rest of 127 MLs and corresponding 127 LBLps lines are non-matched ones remain at “Logic high” as indicated in the waveforms of LBLps2 to LBLps128 in FIG. 5D. As a matter fact, the search speed of every LG is almost the same, regardless of LG1 to LG128 and regardless of 2-metal m0/m1 CLBL array or 1-metal m0 CLBL array. The true difference in the Y-word search speed of finding the matched block within one LG is determined by the block location-decoded ordering therein. In this example, the block turning-off ordering during the Y-word searching starts from the 1^{st} block, then the 2^{nd} block, and finally ends with the 8^{th} block being turned off last in the 8^{th} cycle as defined and controlled in a fixed manner.

Since this is the BCS searching scheme the matched block is the 1^{st} block so that the matched decoding address code of BLK[8:1] as shown in the operation waveforms (FIG. 5D) is first one of FE without further performing 7 more On and Off cycles to determine the matched block of the remaining 7 blocks.

The BCS block searching operation for this LG-based NAND-CAM can be done approximately less than 30 μs with about 2 μs search per block for SLC NAND-CAM and about 4 is per block for MLC NAND-CAM. The execution of whole BCS search operation is similar to that for WCS one described above.

FIG. 5E shows the timing simulation results associated with the current sensing scheme of LG-SA 138a as shown in FIG. 4A under adjusted voltage conditions for BIAS1, BIAS2, and BIAS3. The simulations of SAs of another current scheme of SA 138b in FIG. 4B and voltage sensing of DRAM-like SA 138c are similar and thus are skipped herein for description simplicity.

As shown in waveforms, the VML is precharged to VBIAS1−Vt initially with VSAO=Vdd by setting VPB=Vss to turning on a little larger size of PMOS device of MP2 to help shorten the charge-up time, thus VOUT=Vss during the simulation interval between 0 to 150 Note, VBIAS1 is set to be larger than VBIAS2 at this interval so that VML can be pulled up with a faster speed to set VSAO=Vdd. Note, using the longer simulation interval is to clearly show the Logic level. In fact, a short interval can be used instead to reflect the true legacy.

During the sensing VML is dropped between time line 150 μs to 200 μs because BIAS1 is set to be little lower value than VBIAS2 (Not shown) so that VML will be controlled by BIAS2 during the current sensing interval between the time lines of 300 μs to 400 μs.

During the current sensing search period between the time lines of 300 μs to 400 μs the SA is enabled by switching VBIASN from Vss to a predetermined analog voltage level to turn on MN4 device so that the reference current is set to a value of (VBIASN-Vt)/Rref=VA/Rref, which will be mirrored from a PMOS transistor MP4 to another PMOS transistor MP1, depending on the size ratio of (MP4)/(MP1) and the size of MP4=MP1 for a better tracking. For those unmatched paired LGs, the MLs maintain a “Logic-high”, thus VOUT=Vss. On the contrary, for one matched paired LGs, the MLs maintain a “Logic-low”, thus VOUT=Vdd. Thus the detected LG address will be returned to the external flash controller.

FIG. 5F is a diagram of detailed circuits of a BLK-ROM and BLK-SAs using each CSL as one ML for operating the preferred NAND CAM of FIG. 2B under Y-word search in worst-case scenario. FIG. 5F shows the second detailed circuit of whole Block-based ROM referred as BLK-ROM 139b and whole 512 Block-based SAs 138b referred as BLK-SAs for the preferred Y-word search scheme of NAND CAM that uses CSL lines as the MLs of the present invention. In this example, the whole NAND CAM comprises 1,024 blocks, thus contains 512 units of the basic BLK-SAs because 2 physically adjacent NAND blocks sharing one common horizontal CSL. The WCS matched block is the Odd block of one matched 2-block as explained below.

This whole BLK-ROM 139b has fixed 512 inputs such as OUT1 to OUT512 but encoded into 9 predetermined addresses such as A[22] to A[30] for the matched 2-block address that shares one CSL. The 512 OUT signals are generated from 512 corresponding BLK-SAs 138b with 512 inputs of 512 MLs such as CSL1 to CSL512.

This Block-based BLK-SAs and BLK-ROM are designed to improve over the LG-based LG-SAs and LG-ROMs as shown in FIGS. 5A and 5C for a faster Y-word search speed at the expense of a bigger silicon overhead of 4-fold BLK-SA number, when each LG is comprised of 8 blocks.

The circuit of BLK-SA 138b used in FIG. 5F is different from the BLK-SA 138a as used in FIG. 5A and 5C. The detailed circuit of each BLK-SA 138b is the one shown in FIG. 4B, which is much simpler than LG-SA 138a design because the ways of operating CSL-ML and LBLps-ML in respective search operations are quite different by the present invention.

For example, in LG-SA search operation shown in FIG. 4A, each ML line is equivalent to one LBLps line which is detected by a cascade SA. Its operation starts with an initial precharge by BIAS1 pull-up with a Logic-high V_{BIAS1max}−Vt and then discharged to a Logic-low of V_{BIAS1min}−Vt−ΔV when the LBLps is pulled low by one matched NAND string containing nLC data matching with Y-word in 1-block length, where ΔV is about 0.1V−0.2V drop due to the current flow through one matched NAND-CAM string. In other word, VML(matched)=Logic-low.

Conversely, for those unmatched 511 LBLps lines or MLs, the VML(unmatched) will stay at Logic-high, i.e., VML(unmatched)=Logic-high of V_{BIAS1max}−Vt without being pull-downed because no NAND conducting current happens. Note, the lowest V_{WLmin}=V_{BIAS1min}−Vt1-ΔV has to be higher than V_{BIAS3}−Vt2 with 0.1V or 0.2V margin to prevent the stored charges in all 16 KB C_{LBL}s in every LG during the precharged cycle would not leak out to the common bus of LBLps and ML, where Vt1 is the Vt of MN1 but Vt2 is the Vt of MLBLs, which is identical to MSe or MGe of NAND string select transistor with oxide-thickness around 80 A-90 A.

In other words, the whole sensing method of LBLps-ML employed by the LG-SA is for detecting a small analog swing in LBLps or ML signal, thus LG-SA design is more complicate like an Analog SA design. The multiple optimal bias voltages of BIAS1, BIAS2, and BIAS3 have to be well tuned to ensure the success of this LG-based Search operation.

On the contrary, in this FIG. 5F example for the Y-word search design, BLK-SA is a sort of digital detecting operation on CSL-ML, thus it is much simpler and faster design. In this example, the CSL512 is the only one matched ML but having a value sort of “digital-like High” referred as VML_{H}, while the rest of 511 MLs of CSL1 to CSL511 are the non-matched lines with a value of “digital-like Low” referred as VML_{L}. The value of VML_{H} is subject to Vdd and values of Vsch and VschB and Vt_{Hmax} and Vt_{LmaX} as shown in FIG. 1G of the programmed cell of NAND string. For a 3V Vdd operation, VML_{H}≧1.5V, while 1.8V Vdd search operation, then VML_{H}≧0.5V but averagely still larger than the analog swing signal of LBLps as developed during the LG-SA search operation.

The whole BLK-ML Y-word search operation is performed in unit of LG between one LBLps line as a current supply line and four CSL lines as the current-channel lines and their associated 4 BLK-SAs in accordance with the circuit of 138b as shown in FIG. 4B and the following steps.

Initially, the voltage of all 128 LBLps lines in all 128 LGs are set to be Vdd, e.g., VLBLps=Vdd and VDISN=0V and ENBKMLB=0V and P1B=0V to enable SA with VBLG=VMG=VBHG=0V to isolate all LG, MG and HG groups.

Set all PRE¹=Vdd in accordance with FIG. 3C, so that all 16 KB C_{LG}s=Vdd-Vt through 16 KB MLBLS in every LG, where Vt is the threshold of MLBLS. In other words, total 128 LGs' 16 KB C_{LG}s would be precharged with Vdd-Vt.

Y-word complimentary data and voltages are applied and latched dynamically in the Y-PB of all blocks with 1-block length. And only the single matched block will conduct current so that CLG node voltage at Vdd-Vt would be passed through one of the matched NAND string of one matched block in one of matched LG to charge up one corresponding CSL line or ML to a so called “Digital-like High” with a value determined by Vsch-Vt_{Hmax} with ISOM node being set to Vread. As a result if VML_{H}=Vsch-Vt_{Hmax}>Vt of MN1 with a margin, then a right W/L ratio of MP2 over MN1 would pull-down SAO and then VOUT=Vdd with VENBKMLB=Vss. In this case, the matched CSL is CS512, thus CSL512=Digital-High and OUT512=Vdd. Note, MN1 is preferred to be Enhancement device under 3V Vdd operation and Native device under 1.8V Vdd operation.

All other 511 MLs will remain at Vss to keep SAO node at Vdd and OUT voltage at Vss. In other words, CSL1, CSL2, and CSL511 lines are at Vss and OUT1=OUT2==OUT511=Vss. As a result, the 9 addresses of matched 2-block of 512 of WCS are encoded with LASTLGB=Vss.

Since two adjacent blocks share one CSL, thus one more step is required to determine one matched block out of above matched 2-block sharing 512^{th} CSL. This BLK-SA and BLK-ROM final searching operation becomes much simpler and faster than LG-SA and LG-ROM operation because only 1-cycle is needed to find the matched block out of two of the matched 2-block by just turning off one SSL of the two as explained below.

With all VLBLps=Vdd, shutting off all Odd SSL gates of all paired SSLs sharing the same CSL first when VML=Logic High. For example, 1^{st} SSL, 3^{rd} SSL, . . . , and 1023^{th} SSL are set to 0V but keep 2^{nd} SSL, 4^{th} SSL, . . . , and 1024^{th} SSL at Vdd. This step is to disconnect all 512 Odd strings from 512 CSL lines to check if matched ML voltage is affected when a next step is performed (see below).

Set all LBLps=Vss to see if one of matched V_{ML} switches to Vss from Logic-High as obtained from step of 2-block match operation. If V_{ML}=0V, it means the matched block is the Even block of 1,024^{th} block, otherwise the 1,023^{th} block is the matched block. The BCS search is when the Even block is the matched block of this approach.

The time takes to finalize above one matched block from two matched 2-block is the RC discharge time of a short C_{LG} capacitor. It is about 2 As a result, the whole of this second CSL-ML Y-word search operation takes approximate 20 μs only to find one matched block out of total 1,024 blocks of this NAND-CAM array.

FIG. 5G is a diagram of several timing waveforms during Y-word search operation in the NAND-CAM of FIG. 2B for identifying matched block out of a matched paired-block according to an embodiment of the present invention. As shown, the waveforms are associated with the Y-word search operation to find the matched block out of a matched paired-block. As explained above, the BCS search means the matched block is an Even block (of the paired-block). It is a 1^{st} block that shares the matched CSL1 with an Odd block which is the 2^{nd}-block. The BLK[2:1]=3 when CSL1 is found matching and then BLK[2:1]=2, the CSL1 switches back to Vss and OUT1=Vss. Here, both BCS and WCS of the CSL-ML Y-word search scheme has only about 2 μs speed difference. Thus, both BCS and WCS speed is almost same for this second CSL-ML, BLK-SA, and BLK ROM Y-word search scheme of the present invention. The detailed explanations are similar to FIG. 5F, FIG. 5D, and FIG. 5B.

FIG. 6 is a diagram of detailed circuits of Data Registers, SCRs, and Y-pass/ML Encoder, I/O Controller, and ISO circuit associated with NAND array block according to an embodiment of the present invention. This diagram is merely an example, which should not unduly limit the scope of the claims. One of ordinary skill in the art would recognize many variations, alternatives, and modifications. As shown, circuits of a Data Register (DR) 30 with 8 KB size, a Static CACHE Register (SCR) 32 with 8 KB size, a Y-pass circuit 33, and an I/O Control circuit 90, forms a part of page buffer (PB) implemented in association with the NAND-CAM array 15 coupled via an ISO circuit 11, as described in FIG. 2A or FIG. 2B. All 8 KB DRs 30 include an independent output PASS1 generated from 8 KB Program-Read Buffers (PRBs) 106. Another independent output PASS2 is generated from 8 KB SCRs 32.

In an embodiment, each DR circuit 30 includes one sense amplifier (SA) 104 using DRAM-like CS input signals with two fully tracking input paths and capacitances, and one PRB circuit 106. The SA 104 is a LV SA, including paired inputs QP1 and QP1B connected to one common input DL1 during nLC program, verify, and read operations. The SA 104 in the DR 30 further includes two separate tracking flexible inputs with the first input being connected from either CSLn line or GBLps line or DL1 line and the second input being connected from DL1 line or VREF signal during search operation.

Referring to FIG. 3D, DL1 is connected to one of N₁ GBLs of the NAND-CAM array 15 via a 20V ISO protection circuit 11 in accordance with other circuits of FIG. 2A, FIG. 2B and FIG. 2C. Therefore, the number of SAs, PRBs of DRs, and SCRs is same as the number N₁ of all GBLs, which is ½ of the number N of all LBLs. In this case, N=16 KB, N₁=N/2=8 KB. Thus the bit size of DR and SCR is reduced by half from 16 KB to 8 KB to save huge silicon area on the chip. Although DR and SCR sizes are cut in half, this NAND-CAM array can still perform ABL program, ABL program-verify, and ABL read by storing all 16 KB page data in all corresponding 16K LBL-based parasitic DCRs with programmable C_{LG} capacitances. For nLC program, each capacitance unit C_{LG} is used for storing 1-bit of the nLC page data, while in read and verify operations, each C_{LG} is expanded to C_{MG}=J′×C_{LG} with a larger capacitance to allow reliable read and verify operations with LBL-GBL charge-sharing scheme.

The SA 104 in the DR 30 also is a clocked Latch-type SA with one pair of outputs of Q1 and Q1B, respectively connected to both PRB 106 and SCR 32. From SA design perspective, both PRB and SCR are treated as same, thus the SA provides a flexibility to allow analog read data from the NAND-CAM array to be sensed, amplified, and transferred to both PRB and SCR in digital form equivalently. This is very important for ABL Y-word search operation, where ABL stands for All BLs (of 16 KB) of the NAND-CAM array. During a final Y-word search, the address of one matched LBL line will be searched through all 16 KB NAND strings with a search result stored in 16 KB LBL lines but through only 8 KB GBLs connected to 8 KB SAs. Therefore, in order to take advantages of the same design of PRB and SCR, 8 KB Odd numbered LBLs are connected to 8 KB GBLs first and then 8 KB SAs. After evaluation of the sensed 8 KB Odd LBL voltages, the SAs transfer the final values of all 8 KB Odd half-page data into corresponding 8 KB PRBs. Next, the search operation proceeds to connect the remaining 8 KB Even numbered LBL lines to 8 KB SAs again for evaluation via the same 8 KB GBLs. The 8 KB Even half-page data corresponding to the Even numbered LBL lines, after the evaluation by SAs, are transferred to corresponding 8 KB SCRs. In summary, there is no need to increase the number of SAs but uses PRBs and SCRs to store respective Odd and Even half-page LBL sensed voltages in a digital form.

In another embodiment, the SA 104 has two stages of paired tracking sensing inputs. The first paired input includes two capacitors CP1 and CP2. CP1 is isolated between two NMOS transistors MN64 and MN5 and CP2 is isolated between another two NMOS transistors MN63 and MN1. The CP1 capacitor is used to temporarily store the sensed an Odd/Even sensed voltage connected to node QP1. The CP2 capacitor is to temporarily store a LBL reference voltage connected to node QP1B. The LBL reference voltage can be generated from one tracking C_{LG} capacitor having half of program-inhibit voltage Vinh of the NAND-CAM array during concurrent nLC program-verify operation. But in Y-word search operation, the LBL reference voltage for CP2 is directly connected to half of Vdd from the second input of CP2. The LBL voltage coupled to CP1 is either Vdd of those 16 KB-1 unmatched NAND strings without conducting string current or Vss of a single matched string that conducts the cell current to discharge the precharged voltage of Vdd to Vss.

In yet another embodiment, the SA 104 senses at least two LBL string voltages of Vdd and Vss from DL1 to store at CP1 by setting D-OUT1 node with one-shot Vdd. At the same time the reference voltage is also sensed and stored at CP2 by setting D−OUT2 node with one-shot Vdd. During these CP1 and CP2 sensing and storing, T4 control signal is set to 0V to isolate outputs Q1 and Q1B of the SA from CP1 and CP2.

Next, T4 control signal is applied with one-shot Vdd to transfer V_{LBL} value at CP1 and reference value at CP2 to corresponding outputs Q1 and Q1B for full amplification to a digital value of Vdd and Vss by clocking T5B control signal to Vss and T5 control signal to Vdd.

In an alternative embodiment, PRB 106 in the DR 30 is configured with a latch design made of two inverters INV1 and INV2. The PRB 106 has a first pair of input transistors MN19 and MN17 with their gates being connected from the outputs Q1 and Q1B of the SA 104. When VFYL and VFYR signals are applied with Vdd, the SA transfers its data to the PRB in a reversed phase. When VFYL and VFYR signals are at Vss, SA data is not transferred to the PRB.

The PRB 106 has a second pair of input transistors MN37 and MN39 with their gates being connected from the inputs Dli and DIiB, which are coupled to corresponding output nodes of SCR. When VLDP signal is applied with Vdd on both MN36 and MN38, then SCR digital data is transferred to each corresponding PRB in a reversed phase. When VLDP signal is at Vss, SCR digital data is blocked to transfer to PRB.

The PRB 106 includes one output node PBL which can be connected to DL1 line only when PGM signal is Vdd and greater. The PRB 106 also includes one match-line circuit made of a NMOS transistor MN44 with a drain node PASS1 being ORed with 8 KB of PRB. When all N bits pass program-verify, all DiB nodes are at 0V. Vpass-Vdd voltage is to indicate the pass of nLC page program-verify of this NAND-CAM array. Note, for this NAND-CAM, the nLC program is preferably performed on a batch-based scheme, which means multiple WLs or pages are programmed and verified simultaneously.

Practically, some bits cannot pass the program-verify of nLC NAND-CAM. For regular nLC NAND, as long as the number of erroneous bits are less than ECC correction capability, then it can be treated a pass. But for the NAND-CAM array according to embodiments of the present invention, the erroneous NAND strings are preferably replaced by the redundant NAND strings with the correct data.

T5 control signal is set to Vdd.

The SCR 32, in an embodiment shown in FIG. 6, is configured with a latch design made of two inverters INV4 and INV5. The SCR 32 has a first pair of input transistors MN47 and MN49 with their gates being connected from a pair of outputs Q1 and Q1B of the SA 104. When RDL and RDR signals are set to Vdd to turn on MN46 and MN48, then SA 104 transfers its data to the SCR 32 in a non-reverse phase. When RDL and RDR are set to Vss, SA's data is not transferred to the SCR. The SCR 32 also has a second single input transistor MN23 with its gate being connected from one input control WI and its source node being connected to DIO1 via Y-pass/BL-encoder circuit 33 by I/O control 90. When WI is at Vdd, then the input data is sequentially loaded into the corresponding bits of SCR byte by byte via a Byte-based I/O as shown in this example. Further, the SCR 32 has one output node DIN1 which can be connected to DL1 through a NMOS transistor MN19 only when LD signal is Vdd and greater.

In an alternative embodiment, the SCR 32 has no match-line circuit as the PRB 106. A NMOS transistor MN67 is used to precharge a DL line to each corresponding GBL in each SA during regular Y-word search operation using CSL-ML scheme. To precharge all 8 KB GBL lines via all 8 KB DLs, the preferred set conditions are 1) applying GBLEN signal with Vdd+Vt and D OUT1 signal to Vss to block the precharge current from the GBLps line flowing to one input Q1 of the SA 104; applying Vdd to GBLps.

In another alternative embodiment, the DRAM-like SA 104 (FIG. 6) is used to replace the SA 138b as shown in FIG. 4C and is used also in FIG. 5F with another two inputs Q1B and Q1. The Q1B input is connected to a CSLn signal via a NMOS transistor MN5 gated by T4 control signal and another NMOS transistor MN68 gated by ENCSL. During search operation, Q1 node is set to a voltage level of Vsch-Vt_{Hmax} for one matched 2-block and Q1 node is set to Vss for remaining 511 unmatched 2-blocks. The Q1 input is connected to VREF signal via a NMOS transistor MN1 gated by T4 signal and another NMOS transistor MN66 gated by ENREF. Note, during search operation: VREF=½ (Vsch−Vt_{Hmax}).

In certain embodiments, not every SA has this input. For example, for every 256 SAs just one SA is selected to have this circuit to connect a GBLps signal. But it has one same BL-match enable circuit made of MN21 and MN22 gated by two respective signals of BLMLEN and DIi. The same circuit is also used by the PRB 106. During nLC NAND-CAM batch-based nLC program, multiple nLC page data such as 8 KB Odd half-page data and 8 KB Even half-page data are temporarily stored in 8 KB SCR first, and then transferred to the 16 KB LBL-based DCRs in 2 cycles through a NMOS transistor MN19 and 8 KB DL lines (DL1 to DLN₁) and 8 KB GBL lines (GBL1 to GBLN₁) respectively to 8 KB Odd DCRs and 8 KB Even DCRs.

The operations of each selected SA for searching the matched 2-block are substantially same as SA operations during verify. The SA's sensed data of 8 KB Odd LBLs and 8 KB Even LBLs are separately loaded in each corresponding PRB and each SCR by two cycles. Once 9 addresses of one matched 2-block is found, either PASS1 or PASS2 will be pulled to Vss to indicate one matched 2-block is found. In this embodiment, the ML sensing and setting are similar to the process flow waveforms shown in FIG. 5H.

FIG. 7A is a diagram of a LBL search circuit with decoding output of BLSCH1 for identifying address of a single matched LBL of a NAND-CAM array according to an embodiment of the present invention. This diagram is merely an example, which should not unduly limit the scope of the claims. One of ordinary skill in the art would recognize many variations, alternatives, and modifications. As shown, a LBL search circuit is used to identify address of a single matched LBL of the NAND-CAM array during the Y-word search operation without taking extra big overhead of silicon area. This LBL search circuit includes multiple Y-pass circuits 33 and multiple I/O control circuits 90.

Multiple Y-pass circuits 33 are configured with inputs being connected to all outputs of 8 KB SCR using existing connections for a regular NAND. Thus, there is no overhead to leverage this connection. In this example, a 3-level Y-pass decoding scheme is designed to connect 8 KB SCR to one byte of Byte-based I/O pins. The 3-level Y-pass gate control scheme includes top-level YC gate control signals YC1 to YCk, middle-level YB gate control signals YB1 to YBj and lowest level of YA gate control signals YA1 to YAi. The bit numbers of each YAi, YBj, and YCk are fully determined by the total LBL number of the NAND-CAM array, in the example, it is 16 KB.

Each of the multiple I/O control circuits 90 includes Input Buffer 501 and Output Buffer 502 and common I/O pads arranged from I/O1 to I/O8. Correspondingly BL-ML encoder output nodes DQ1 to DQ8 are connected to the source nodes of NMOS transistors MN1 and MN2 gated by two control signals DQIN and DQOUT respectively.

The encoder output node is BLSCH for each I/O control circuit, which is connected to a PMOS transistor MP1 with its gate being tied to a PREB control signal, acting as a PMOS load of one sensed NAND string matching with the Y-word. The resistance of MP1 has to be tuned to be at least 3-fold larger than the maximum NAND string equivalent resistance in WCS during LBL search operation. For example, if the matched string current is about 0.5 which is equivalent to 2 MΩ. Then the resistance of MP1 has to be larger than 6 MΩ for a reliable sensing of the matched string that conducts the current. The MP2 has a very high resistance such as Meg-ohm acting a P-load for the matched NAND string during the search operation. Only one matched LBL string will pull down one sense node or one ML node of eight BLSCH such as BLSCH1 for I/O1 to BLSCH8 for I/O8.

Before starting LBL search, parasitic capacitance nodes of each Y-pass circuit have to be precharged with a voltage of Vdd-Vt by setting BLSCHB control signal to Vss in one shot and making MP2 size much bigger than MP1.

Further details of operating this LBL search circuit for Y-word search will be provided in accordance with circuit shown below in FIG. 8A and operating waveforms and sequences disclosed in FIG. 8B of the present invention.

FIG. 7B is a diagram of timing waveforms of several key control signals for performing the preferred LBL-Search operation in worst-case scenario according to an embodiment of the present invention. This diagram is merely an example, which should not unduly limit the scope of the claims. One of ordinary skill in the art would recognize many variations, alternatives, and modifications. As shown, in WCS for performing this preferred LBL-Search operation several key control signals need to apply to quickly find out final LBL address of a single matched NAND string or LBL after the matched block has been found from the NAND-CAM array without hardware circuit overhead.

Again, WCS means that the matched LBL line address is located at a last byte after the maximum sequential search cycles. The maximum number of sequential search cycles depends on the number of LBL lines in unit of byte as defined in the NAND-CAM array. In an example, the number of LBL lines is 16 KB (which need total 16K bytes). Among the 16K addresses in unit of Byte 14 addresses are assigned for all Even and Odd LBLs and can be arbitrarily divided into 3 groups for establishing the 3-level Y-pass scheme that have YAi, YBj, and YCk, 3 sets of gate control signals, where i+j+k=13. The number of YAi=2ⁱ, and the number of YBj=2^{j}, and the number of YCk=2^{k}. In an example, i=5, thus there are 32 YAi low-level gate signals, and j=4, thus 16 YBj middle-level gate signals and k=4, there are 16 YCk top-level gate signals.

The Y-pass On/Off sequence operation for identifying the matched LBL starts from one fixed YCk top-level gate control signal, and then scan though all YBj and YAi. The way of Y-pass scan is different from block-scan as used to find the matched block. Because the execution of Y-pass scan is between PRB and SCR and the Y-pass sensing devices of MP1, the parasitic capacitances of all connections between all Y-pass transistors are much lower than the GBL and LBL capacitance. The pull-down NMOS devices of PRB and SCR latch circuits can be made larger with a higher sinking current and much less resistance in 10KΩ-range than the NAND string resistance in Mega-Ω range. Thus, the Y-pass On/Off search sequence takes 1 bit off to reduce half of searching LBLs each time, unlike block-based ML search to turn off one by one SSL. For an 8-block LG, the WCS search takes 7 or (2³−1) cycles to identify the matched block if the matched block is the 8^{th} or the last one in each LG. In contrast, this Y-pass On/Off search takes bit number to shorten the search speed from YCk, then YBj, and YAi. For total 14 address bits used for YCk, YBj, and YAi, it only takes at most 13 cycles to identify the address of the matched LBL with an acceptable search latency less than 1 μs.

The timing waveforms for multiple control signals mentioned above are summarized in FIG. 7B. As shown, first to select YC1 signal at Vdd with following YAi and YBj bias conditions: All voltage levels for YBj (j=1 through 16) is at Vdd, thus YBj code=FFFF; All voltage levels for YAi (i=1 through 32) is at Vdd, thus YAi code=FFFFFFFF. If one of BLSCH signal is at Vss, then the matched LBL is within YC1=1. Otherwise, YC1=0 has the matched LBL. In the waveform, YC1=1 is using FF00 code, while YC1=0 uses 00FF. In the WCS case, the matched LBL is in YC1=0 of 00FF.

Next is to further turn off another half of the NAND array to ¼ array, thus YC1=00F0. Here, none of BLSCH signal is Vss, thus YCk scan continues from 00F0, then 000E, then 00C0, then 0003, then 0002, and finally to 0001. The matched LBL is found in 9 cycles within the YC16 group with code of 0001 because now at one BLSCH signal at Vss is detected.

Now, YCk=0001 is fixed, then YBj scan starts and takes 8 cycles of FFFF, FF00, 00FF, 00F0, 00C0, 0003, 0002, and 0001 as YCk to identify the matched YBj=0001.

Lastly, with YCk=0001 and YBj=0001 being fixed, YAi starts to scan in search of the matched LBL. It takes 16 cycles to find the matched YAi=00000001.

The 8-bit matched LBL code advances from FF to FE. A[14:0] value is 4000 when PASS1=1 and A[14:0] value is 0000 when PASS1=0.

FIG. 7C is a diagram of a LBL search circuit with decoding output of BLSCH8 for identifying address of a single matched LBL of a NAND-CAM array according to another embodiment of the present invention. This diagram is merely an example, which should not unduly limit the scope of the claims. One of ordinary skill in the art would recognize many variations, alternatives, and modifications. As shown, the LBL search circuit here is substantially the same as one shown in FIG. 7A, including multiple I/O control circuits 90 and multiple Y-pass circuits 33 with a 3-level Y-pass decoding scheme. It is only applied for performing an address identifying operation in a BCS case. Correspondingly, FIG. 7D is a diagram of timing waveforms of several key control signals for performing the preferred LBL-Search operation in best-case scenario according to an embodiment of the present invention. The BCS means that the matched YCk is YC1 with code=8000 for all 16 YC[16:1]. Similarly, the BCS of matched YBj is YB1 with code=8000 for all 16 YB[16:1] and the BCS of YAi is YA1 searching from FFFFFFFF, then FE000000, F0000000, then C0000000, and more till last one 80000000 for YA[32:1] and DQ[8:1] from FF to 7F. Lastly, LG address of A[14:0] has the value of 4000 if PASS1=1 and 0000 if PASS1=0. The search operation is similar to that for WCS case except that it saves lots of cycles in BCS to identify the 13 addresses of one matched LBL.

FIG. 7E is a diagram of a 3-bit LBL-ROM encoder circuit for further narrowing down single matched LBL address after a matched byte is found by a Y-pass circuit according to an embodiment of the present invention. This diagram is merely an example, which should not unduly limit the scope of the claims. One of ordinary skill in the art would recognize many variations, alternatives, and modifications. As shown, a 3-bit ROM encoder circuit 95 is provided for further narrowing down identification of single matched LBL address after the matched byte is found by the Y-pass circuit with 8 decoding outputs BLSCH1 to BLSCH8 at 8 I/O areas as shown in FIG. 7A and FIG. 7C.

In an embodiment, the 3 address bits of ROM encoder are called as A[−3], A[−2] and A[−1], or A[28], A[29] or A[30] in the specification of the present invention, as listed in Table 2 below.

TABLE 2

| Input | A[−3]/A[28] | A[−2]/A[29] | A[−1]/A[30] |
|---|---|---|---|
| BLSCH1 = 1 (Vdd) | 0 | 0 | 0 |
| BLSCH2 = 1 (Vdd) | 1 | 0 | 0 |
| BLSCH3 = 1 (Vdd) | 0 | 1 | 0 |
| BLSCH4 = 1 (Vdd) | 1 | 1 | 0 |
| BLSCH5 = 1 (Vdd) | 0 | 0 | 1 |
| BLSCH6 = 1 (Vdd) | 0 | 1 | 0 |
| BLSCH7 = 1 (Vdd) | 0 | 1 | 1 |
| BLSCH8 = 1 (Vdd) | 1 | 1 | 1 |

FIG. 7F is a diagram of worst-case scenario timing waveforms for searching one matched LBL line according to an embodiment of the present invention. As shown, the WCS waveforms for searching one matched LBL line uses sequential On/Off control over Y-pass gate signals of YA[32:1], YB[16:1], and YC[16:1] in accordance with circuit LBL-ROM 95 as shown in FIG. 7E.

Initially, all 16 YCk, 16 YBj, and 32 YAi are coupled to Vdd to open for connecting all 8 KB PRBs. Then 16 YCk are turned off one by one to pinpoint the matched YCk. The code of YC[16:1] starts from “FFFF”, through FF00, 00FF, 00F0, 000F, 0008, 0002, and 0001 through 8 cycles to find the matched LBL that is located within YC1=0001. Once YC1 is found as a matched YCk, the matched YBj can be found by similarly scanning though all YBj the same way as YCk search. The code of YBj goes through from FFFF, then FFFF, then 00FF, then 00F0 and finally 000F. Next, it takes additional 5 cycles along YAi to determine the matched one in on-state of FFFFFFFF.

FIG. 7G shows the timing waveforms for searching one matched LBL line in a BCS case. Here, a similar sequential On/Off control scheme is applied over Y-pass gate signals of YA[32:1], YB[16:1], and YC[16:1] in accordance with the LBL-ROM circuit 95 as shown in FIG. 7E.

FIG. 8 is a diagram of a circuit of Block decoder associated with NAND-CAM array according to an embodiment of the present invention. This diagram is merely an example, which should not unduly limit the scope of the claims. One of ordinary skill in the art would recognize many variations, alternatives, and modifications. As shown, a preferred Block decoder circuit 57 is provided with a Latch circuit made of two inverters INV4 and INV5 for performing NAND-CAM Y-word search operation and concurrent multiple-WL nLC program, program-verify and erase-verify operations. The Block decoder 57 includes at least three parts: 1) a Latch circuit made of one paired Inverters INV4 and INV5 with an input signal BLKy enabled by LGm signal, 2) a local HV pump circuit with a HV input port VHH and a pump clock input PH enabled by the Latch data and input high logic of the signal BLKy and any other control signals such as CLA, ENBm, CLRm, and BLKSERACH, and 3) a row of HV gate control devices of MNS2, MNS3, and MNH1-MNH128 for connecting or disconnecting a whole set of common signals of GSLp, SSLp, 64 paired GWL1-GWL1B to GWL64-GWL64B to or from the corresponding SSL, GSL, and 128 WLs (WL1-WL128) for 64 paired key bits. The operation of the Block decoder 57 is summarized below.

A LV input BLKy, which is an output of a BLKy-decoder (not shown), is only enabled when the Latch status yields XDMBn node at Vdd and LGm signal is Vdd. The Latch is used to determine if the addressed block decoder is selected or non-selected for this preferred concurrent nLC ABL program and verify. All Latches of all block decoders associated with the NAND-CAM array are reset by a global one-shot Vdd signal CLA to set all XDMn nodes of all Latch circuits to Vss and then all XDMBn nodes of corresponding Latch circuits to Vdd. This global one-shot CLA signal can be generated upon detecting the power-up or a chip-enable signal of each NAND chip.

When a block decoder is selected by the addressed XDn, then XDn at Vdd with one-shot pulse Vdd being applied to ENSm to set XDMBn node to Vss to record the selection and to differentiate the selected block from the non-selected ones. In summary, when XDMBn node is at Vss, some out of all block decoders are selected for the preferred SLC pipeline program and read by the present invention.

When CLRm signal is Vss and ENBm signal is one-shot Vdd, then XDPn node is set to Vdd to enable the PH clock into a local VHH pump circuit so that HXDn node is provided with a high voltage VPP=Vpgm+Vt so that a whole set of GSLp, GWL1-GWL64, GWL1B-GWL64B, and SSLp lines are connected, without voltage drop, to the selected set of SSL, WL1-WL64, WL1B-WL64B, and GSL gate lines to a specific block with their respective predetermined program voltages. Here SSL and GSL are two common gate lines for string-select transistors and WL1-WL64 and WL1B-WL64B are respective 128 word lines.

The precharge of all sets of WLs, SSL, and GSL lines of all blocks within all associated LGs, MGs, and HGs can be done by just directly connecting to one common set of 130 big drivers of SSLp, GWL1-GWL64, GWL1B-WL64B, and GSLp within 5 μs without locking on dynamic Y-PB with all VHXDn nodes from the HV input VHH or being locked on the Y-PB by setting all HXDm nodes at 0V when all complimentary 64-bit (paired) voltages are fully and steadily loaded into the Y-PB. The 64 paired complimentary voltages include VR and Vread. After the address of matched LG, block, and LBL line is found, then all above VR and Vread voltages stored on all Y-PB should be discharged immediately to Vss to eliminate WL Vread gate disturb for a longevity of NAND-CAM usage.

FIG. 9 is a diagram of eight Block decoders for a LG group of NAND-CAM and one shared self-timed delay control circuit according to an embodiment of the present invention. This diagram is merely an example, which should not unduly limit the scope of the claims. One of ordinary skill in the art would recognize many variations, alternatives, and modifications. As shown, a LG-based Group-block decoder is made of eight block-decoders 57 and one shared self-timed delay control circuit 58 to work along with the hierarchical-BL NAND-CAM array to allow highly efficient execution of multiple WLs concurrent/pipeline nLC program operation.

Eight block-decoders 57 have their respective block inputs BLK1 through BLK8 and one common enable input LGm signal decoded from LG decoder and five common control inputs denoted as ENBm, SETm, CLRm, ENSm, and INTP generated by the common self-time control circuit 58 with one set of 130 common inputs including one top string-select input SSLp, 64 paired word line inputs GWL1-GWL64 and GWL1B-GWL64B, a clock input PH, a global HV input VHH, one bottom string-select input GSLp, a single BLKSEARCH input signal, and the corresponding 130 outputs of SSL, WL1-WL64, WL1B-WL64B, and GSL. These output lines are also acting as the poly2 capacitor-based dynamic Y-PB on top of NAND-CAM array to latch the Y-word complimentary voltages or data without taking extra silicon areas.

In an embodiment, the self-timed delay control circuit 58 is configured to generate several varied derivative delays either longer or shorter than one known-delay controlled by one input pulse of ENB signal and other signals POR, BIAS, and SET from the on-chip state-machine. The varied derivative delays are based on a simple but highly tracking and reliable RC circuit.

In a specific embodiment, the self-timed delay control circuit 58 is shared by all 8 blocks within a same LG to save area. All varied derivatives, such as a longer delay of 100 for Tpgm or a shorter delay of 2.5 μs for discharging Vpgm, Vpass, Vread, and Vss in one set of one selected WL, 127 unselected WLs, 1 SSL and 1 GSL and others, are all aligned to the ENBm signal with a known duration of pusleE, which is about 5 μs in an example.

In another specific embodiment, only the selected LG will enable this self-timed control circuit. All unselected ones would be disabled so as not to consume any power consumption during a batch-based concurrent/pipeline nLC program and all verify and read operations.

During the Y-word search operation, the self-time control circuit can be disabled because all LGs have to be done searching the same time to achieve the fast search operation. Thus all the timing control of block decoders is better to be controlled directly from on-chip state-machine that provides the accurate time control.

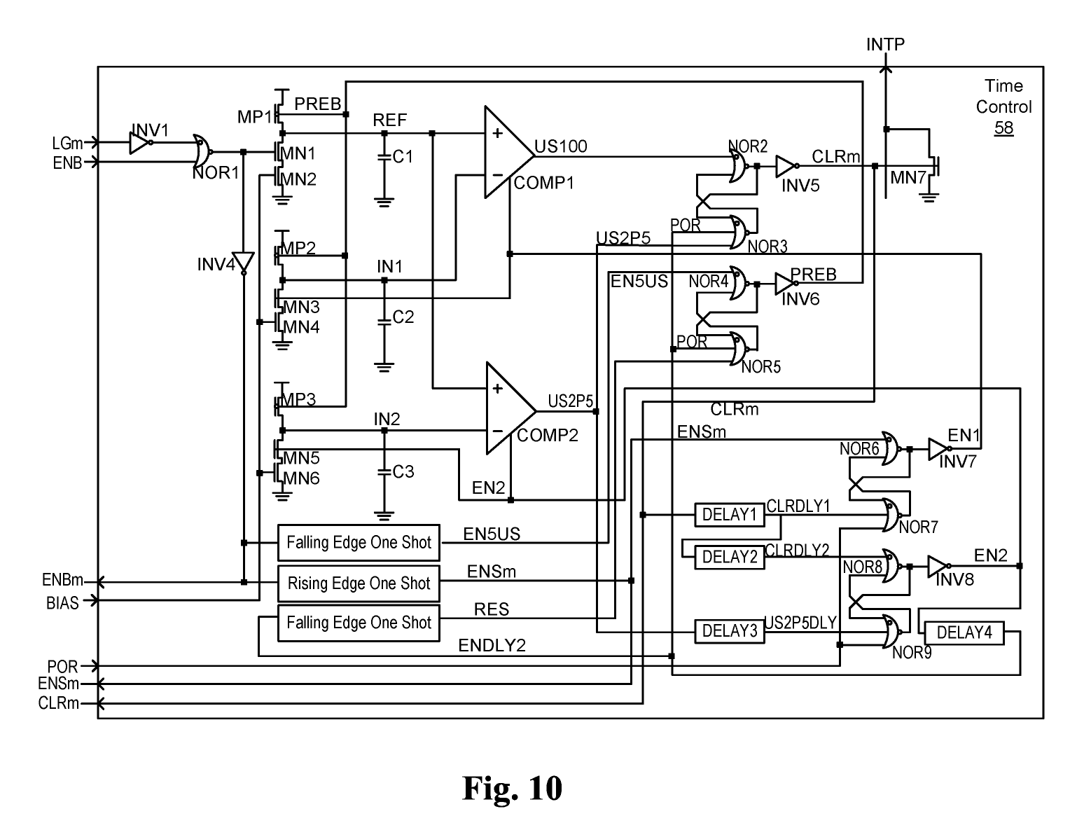

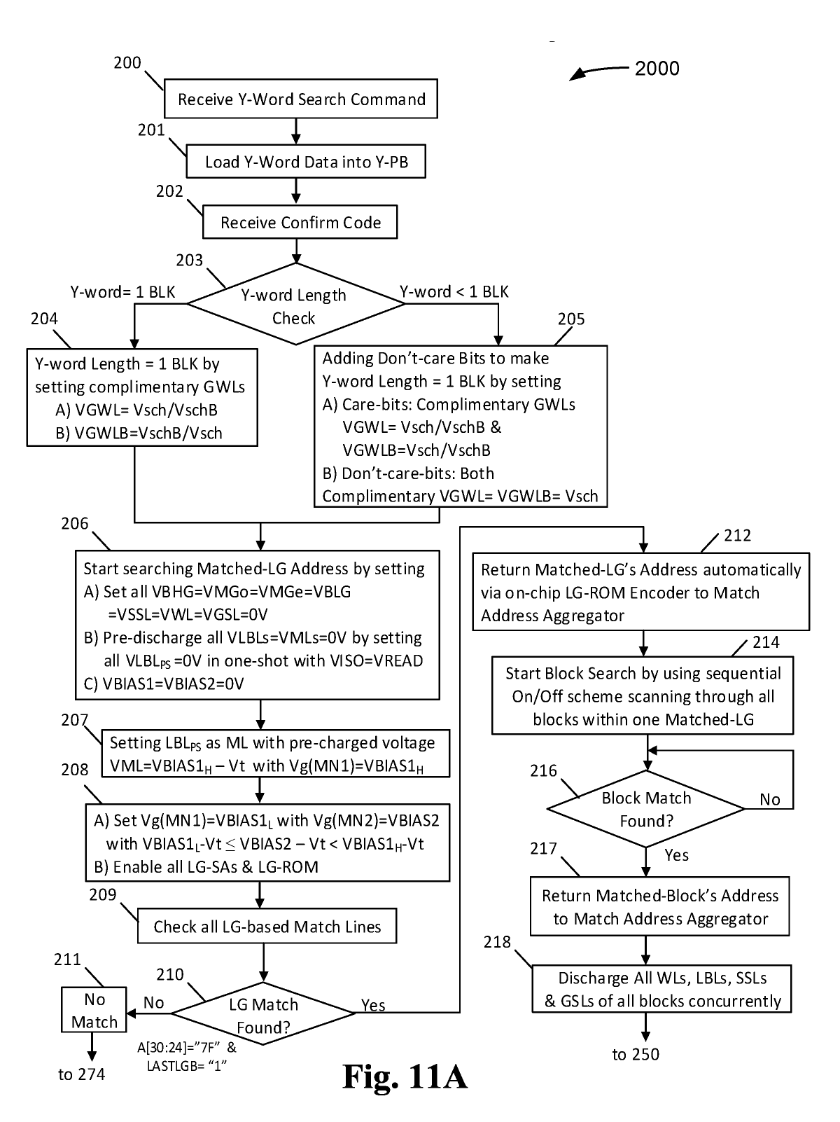

FIG. 10 is a diagram of the self-time delay control circuit of FIG. 9 according to an embodiment of the present invention. As shown, a detail implementation of the self-timed delay control circuit 58 of FIG. 9 is provided. This circuit is used for the batch-based concurrent/pipeline nLC program, all verify and read operations with dramatic latency reduction under the NAND-CAM of the present invention. In a specific embodiment, the self-time delay control circuit includes two differential amplifiers (DA) denoted as COMP1 and COMP2, having one common reference voltage input Vref connected to REF node and “+” node with a C1 capacitor of each DA and two separate inputs respectively connected to two individual “−” nodes, IN1 with a C2 capacitor associated with COMP1 and IN2 with a C3 capacitor associated with COMP2. In another specific embodiment, the self-time delay control circuit includes three current-mirrored discharge RC circuits with 3 identical capacitors C1, C2, and C3 but 3 different resistance R values defined by three ratios of mirrored currents, e.g., three ratios of NMOS W/L values. The Vref is tuned by using one known-duration signal ENB provided by on-chip State-machine to discharge from its initial precharged Vdd to the final Vref through a discharged circuit which is controlled by a constant current mirror circuit. Several controlled delays such as precharge and locking intervals for program can be generated by aligning to the above Vref level with the pre-determined multiplication of RC-delay.

In yet another specific embodiment, the self-time delay control circuit includes an interrupt circuit made by one pull-down NMOS device MN7 with a common drain node being connected to INTP signal and gate being tied to CLRm signal. The Vref input is tuned by using one known-duration signal ENB provided by on-chip state-machine to discharge from its initial precharged Vdd to final Vref value. The discharging is controlled by a constant current mirror circuit with their common gates connected to a BIAS signal.

In still another specific embodiment, the self-time delay control circuit includes several latches. A first latch is made of two NOR gate circuits NOR2 and NOR3. A second latch is made of NOR4 and NOR5. A third latch is made of NOR6 and NOR7. A fourth is made of NOR8 and NOR9. Several small one-shot generator circuits are configured to provide various derivative delays such as DELAY1, DELAY2, DELAY3, and DELAY4 with time durations being kept identical less than 50 ns.

Several required delays such as Tpgm program time span and others can be generated by aligning to the Vref level defined by the discharge time from Vdd to Vref controlled by one pulse of ENm signal with a known duration of 5 μs. As a result, a later long delay generated from this self-timed control circuit does not require the support from the on-chip state-machine and counter so that power consumption and circuit areas associated with the NAND-CAM array can be greatly reduced.

In accordance with one or more preferred NAND-CAM arrays and associated peripheral circuits, selection of ML, ROM, SAs and search schemes, several detailed process flows of NAND search operations are disclosed below. In one or more embodiments, search process flows of the present invention start with Y-word search and end with X-word search. In the following description, all search process flows are based on 2D SLC NAND-CAM and byte-based I/Os only. The ordinary skills in the art would extend the as-described process flows to 3D SLC NAND-CAM, 2D MLC NAND-CAM, 3D MLC NAND-CAM, 2D NOR-CAM with Word-based I/O, 2-Word-based I/Os and the likes, and would recognize many variations, alternatives, and modifications in defining Y-word search command, Y-word data loading and length check/making, detail searching steps including precharging match-line, group/block searching and address matching, and discharging all blocks.

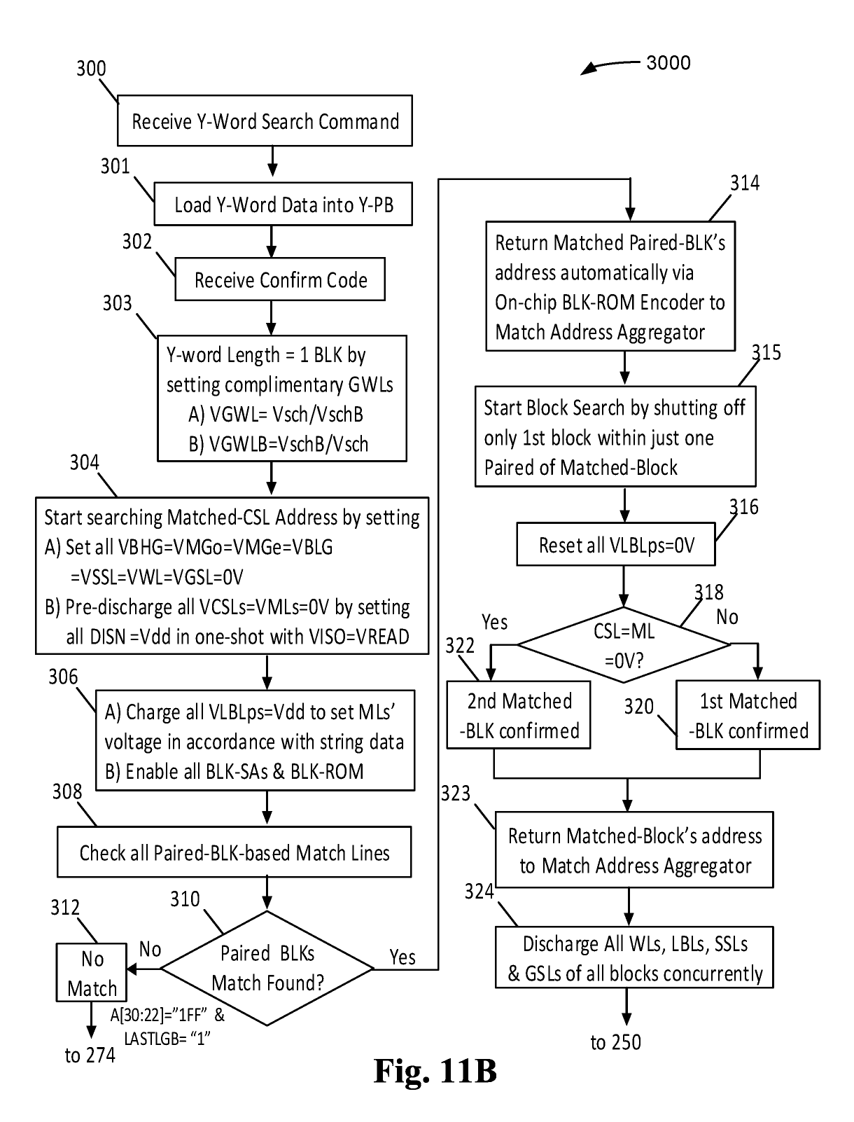

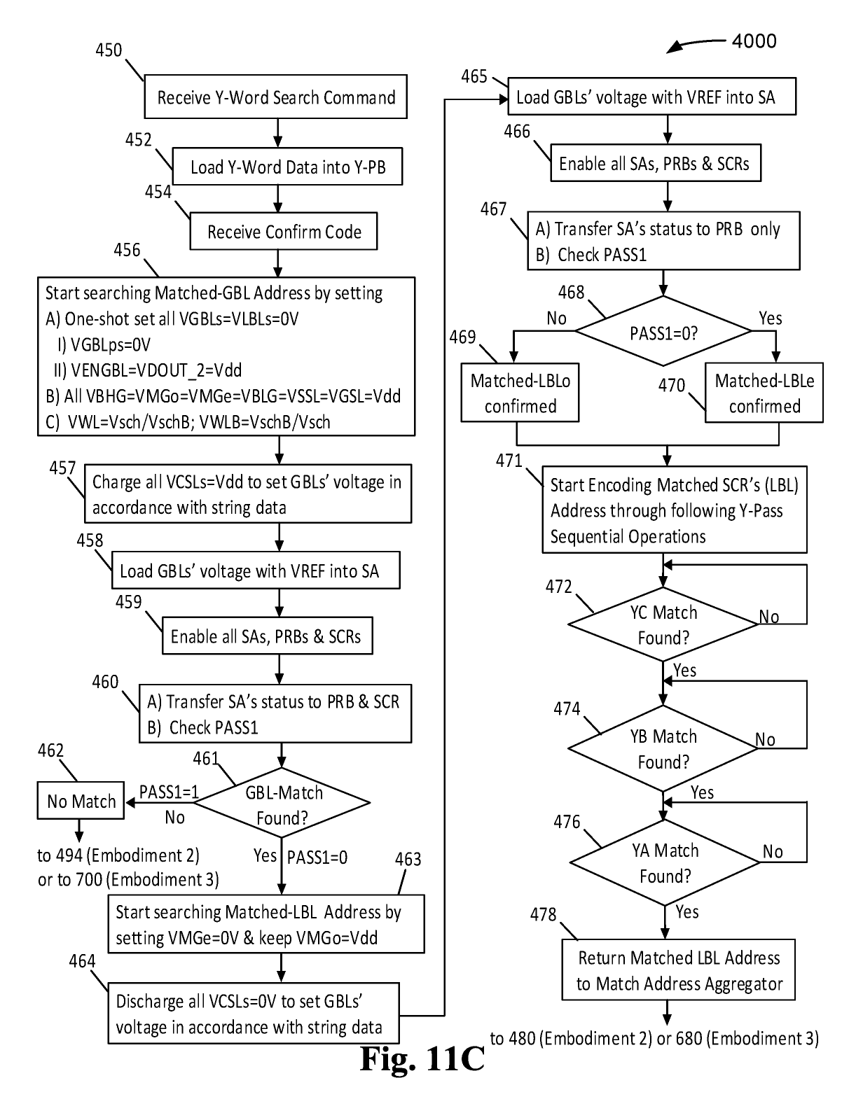

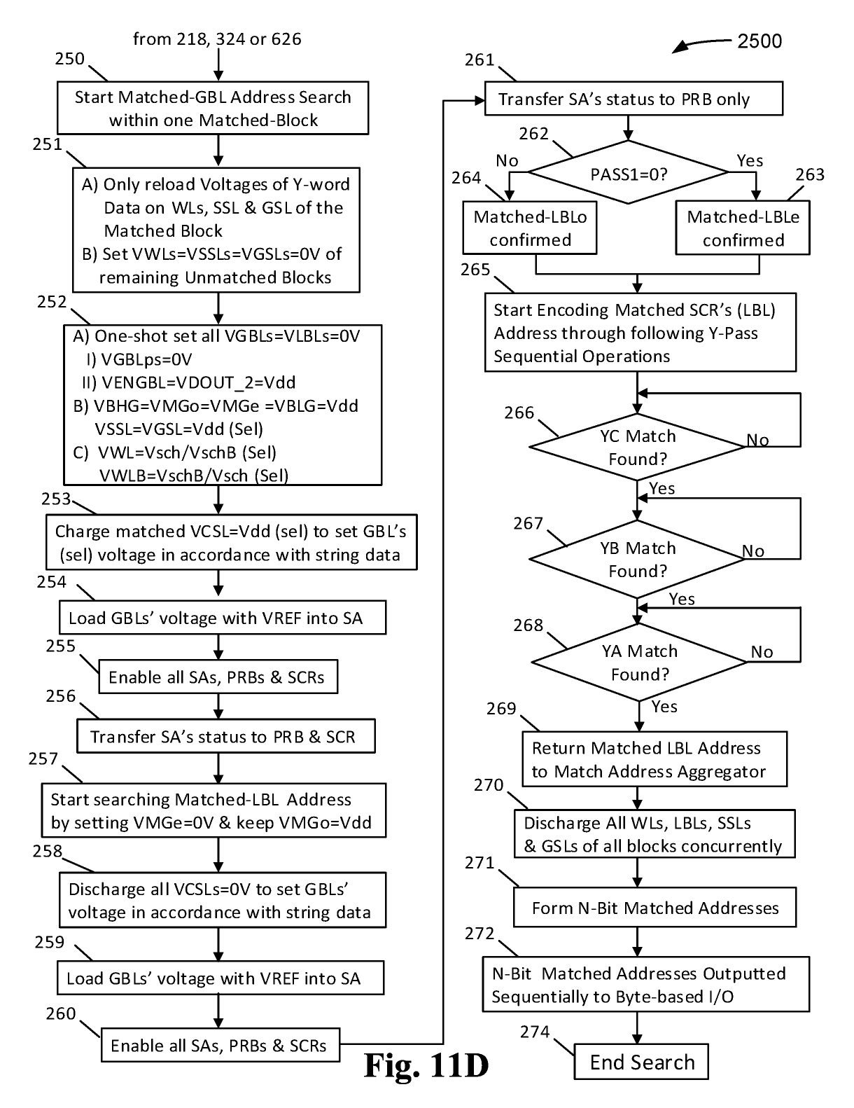

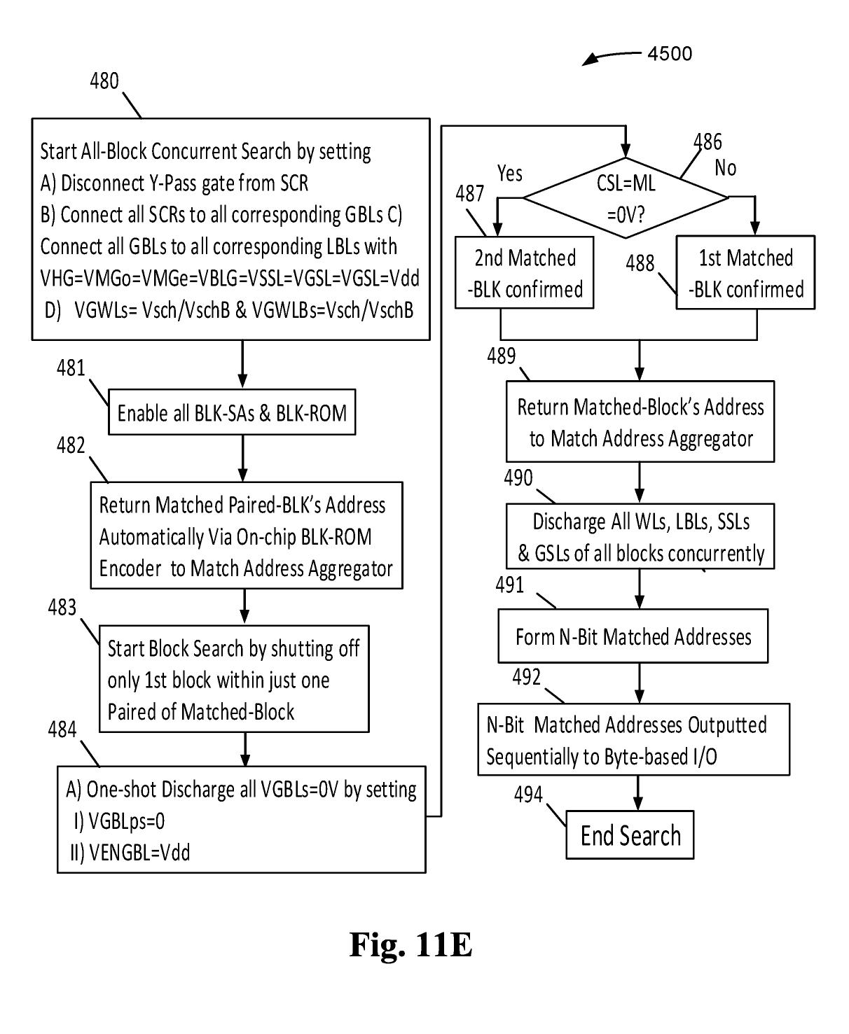

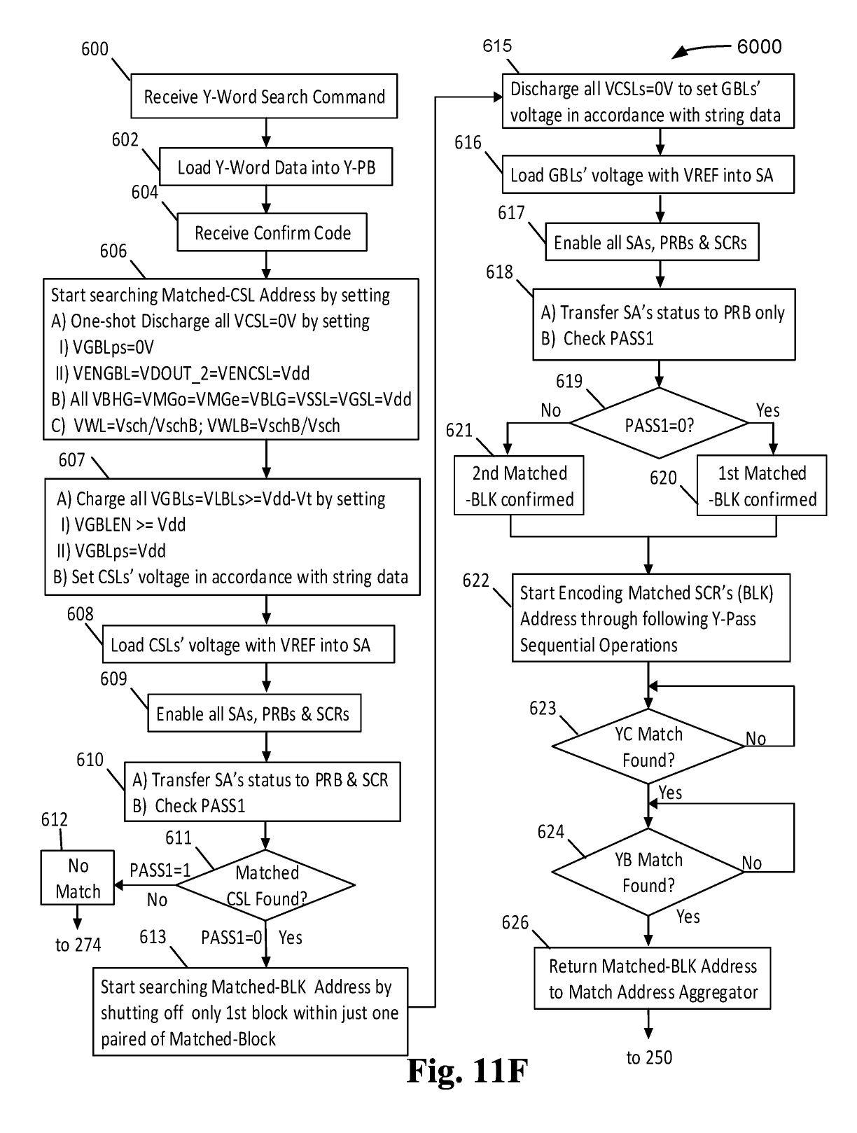

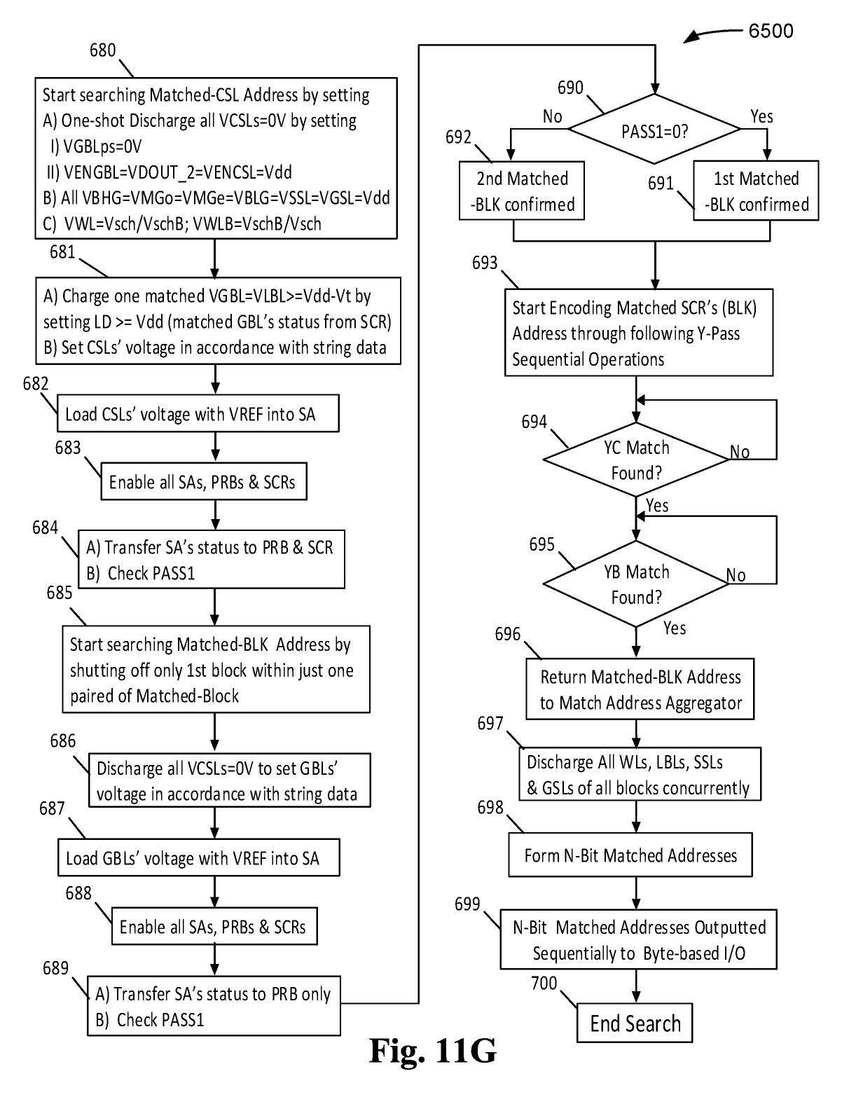

FIG. 11A is a flow chart illustrating a method for performing an operation of Y-word search with variable length according to an embodiment of the present invention. This diagram is merely an example, which should not unduly limit the scope of the claims. One of ordinary skill in the art would recognize many variations, alternatives, and modifications. As shown, the method 2000 for performing an operation of Y-word search starts from a LG-match first and ends with a LBL-match last in accordance with an exemplary LG circuit shown in FIG. 2D in a 2D SLC NAND-CAM chip using a LBLps metal line as ML and a LG-ROM as encoder shown in FIG. 2A for a Y-word length of 1-block according to an embodiment of the present invention.

Briefly, the process flow of method 2000 starts from step 200 for receiving search command with confirmation of search-word (receiving confirmation code in step 202). The method further includes loading (step 201) one set of predetermined voltages of SSLp, GSLP, GWLs and GWLB voltages into all blocks of capacitor-based Y-PB simultaneously with isolated LGs in accordance with Y-word complimentary bits and then checking (step 203) if the status of Y-word is full or partially full in terms of one block-length.

Further, the flow moves sequentially through several steps of searching matched LG-address, setting LBLps line to a ML, setting bias to enable LG-ROM, then entering step 210 to find the address of one matched LG. Furthermore, after a few steps of returning matched-LG address and starting block search using sequential On/Off scheme, the flow continues to find (at step 216) and return (at step 217) the address of one matched block. Finally, the flow moves to step 250 to find the last address of one matched LBL. All these steps, to be shown in more details below, are in association with NAND-CAM circuits shown in FIG. 2A, FIG. 3B, 3C, 3D, and SA circuit 138a shown in FIG. 4A.

Step 200: The method 2000 for performing NAND-CAM search operation starts to sequentially receive Y-word search command and data in units of byte from an off-chip flash controller via byte-based I/Os of the NAND-CAM. The number of input cycles depends of the Y-word length. In order to save the die size, the Y-word complimentary data is stored into the designated bits of Program-Read Buffer (PRB) in a Digital Register (DR) in accordance with the circuit of FIG. 6. The command data is separately stored in the corresponding Command Register 80 shown in FIG. 2A. For the preferred Y-word Search operation, no address data as input is needed. Unlike a typical NAND flash without search function and command, the NAND-CAM according to embodiments of the present invention for the Y-word search operation needs to create a new command for the search operation, in next step 201.

Step 201: In this step, the received Y-word complimentary data with 1-block length in PRB is transferred and connected to a block decoder circuit 55 of FIG. 2A for generating LV search voltages of Vsch and VschB for one set of common search signals of 64 GWLs, 64 GWLBs, 1 SSLp, and 1 GSLp in accordance with the Y-word data. The Y-word data is subsequently loaded and latched into a capacitor-based Y-PB in unit of blocks formed within the NAND-CAM array.

Step 202 includes receiving search confirm command. Since Y-word length is variable, state-machine needs to receive the confirm code in 202 to make sure that the last bytes has been received in step 201 before starting the Y-word search operation.

Step 203: In this step, the length of the Y-word is checked by the search command. If the Y-word bit length is 1-block, then the flow moves to step 204. Otherwise, the Y-word bit length <1-block, then the flow moves to step 205 to add two Vsch (for both GWL and GWLB) for those “Don't-care” mask bits.

Step 204: Since the Y-word length is exactly equal to 1-block, thus all sets of 64 pairs of WLs and WLBs, 1 SSL, and 1 GSL of all 1,024 blocks can be correspondingly connected to one common signal bus of 64 GWLs and 64 GWLB, 1 SSLp and 1 GSLp in one cycle by turning on all pass transistors of SSL, 128 WLs, and GSL such as MNS2, MNH1, MNH2, MN128, and MNS3 with a condition that VXDn=VHH>Vdd+Vt in accordance with the circuit of block decoder 57 shown in FIG. 9. The voltages of VschB and Vsch for total 64 complimentary bits will be fully applied to all 64 pairs of WLs and WLBs without adding the “Don't-care” bits for a full length of 1-block Y-word search operation.

Step 205: Since the Y-word length is less than 1-block, thus some “Don't-care” bits have to be applied with Vsch voltages to make up a full Y-word of 64 paired complimentary bits. Then as in step 204, all 64 paired WLs and WLBs, SSL and GSL of all 1,024 blocks with some “Don't-care” bits can be correspondingly connected to one common bus of 64 GWLs, 64 GWLB, 1 SSLp, and 1 GSLp in one cycle by similarly turning on all SSL, WLs, and GSL pass transistors of MNS2, MNH1, MNH2, MN128, and MNS3 with VXDn=VHH>Vdd+Vt in accordance with the circuit of block decoder 57 shown in FIG. 9.

Now, both step 204 and step 205 will be merged and then move to step 206.

Step 206: This step starts searching the address of one matched LG when all 1,024 blocks of NAND-CAM are searched collectively and simultaneously. This is done by the following bias conditions: 1) Set all VBHG=VMGo=VMGe=VBLG=VSSL=VWLs=VWLBs=VGSL=0V; 2) Pre-discharge all LBLs, all WLs to 0V by setting one-shot Vss to LBLps line per LG, with ISOM signal set to V_{READ}; 3) Set both BIAS1 and BIAS2 signals to 0V. In other words, all LGs are disconnected from each other for independent search operation.

Step 207: Assigning the LBLps line as a match line by setting a pre-charged voltage of V_{BIAS1H}−Vt with gate signal of MN1 transistor being at V_{BIAS1H}.

Step 208: Firstly, to discharge all C_{LG}s to Vss within all LGs, then to connect each LBLps metal line to each corresponding ML with ISOM signal being set to V_{READ}, also to connect to all 16 KB C_{LG}s by setting PRE gate signal to Vdd initially so that 16 KB precharge transistors MLBLS are turned on to allow the precharge current flowing from one big MN1 transistor with gate control signals BIAS1H and MN2 transistor with gate signal BVBIAS2 being set to Vss. Then ML voltage will be the same as the precharged voltage at LBLps line, i.e., V_{BIAS1H}−Vt, where Vt is a threshold voltage of the NMOS transistor MN1 in LG-SA 138a of FIG. 4A. The precharge time should take less than 1 Secondly, to enable the LG-SA 138a by setting PB node to Vdd and BIASP signal is generated at the predetermined voltage by setting BIASN signal to Vdd with VOUT at Vss when SAO node is precharged to Vdd by one-shot pulse at Vss applied to PB node initially. This step is performed on the same time with LBLs precharge operation.

Step 209: This step is for checking all LG-MLs voltages when Y-word concurrent search is performed on all blocks the NAND-CAM array in 1-cycle under certain bias conditions as described below. The gate voltage of the big NMOS device MN1 is set to a lower value of V_{BIAS1min} to clamp the ML voltage value at around V_{BIAS1min}−Vt−ΔV when one of block containing a string that matches the Y-word data is found to conduct a sinking current. It takes less than 5 μs to quickly discharge LBLps or ML to a “Logic-low” voltage below V_{BIAS1min} or VBIAS1_{L} with a faster speed due to less C_{LG} than prior art if the corresponding LG is the matched LG that contains one NAND string matching Y-word. For the remaining unmatched LGs, all LBLps lines stay at an initial precharged “Logic-high” voltage of V_{BIAS1H}−Vt, where V_{BIAS1H}>V_{BIAS1L} by a margin about 0.2V. Thus, this cascade LG-SA 138a will amplify the matched ML's signal and then make VOUT=Vdd so that the corresponding LG-ROM 139a can automatically encode the address of a matched LG if the matched LG is found.

Step 210: If no voltage level of any LBLps line and corresponding ML is at Logic-low, then it means no match is found between Y-word and all stored keys or data in all NAND strings of all blocks. Then the method 2000 moves to step 211, which indicates “No Match” and returns that message to off-chip flash controller. If one LBLps line is found to be at Logic-low level, then it indicates that Y-word match is found.

Step 212: Once a matched LG is found, the NAND-CAM array will automatically return an address of the matched LG to on-chip Address Aggregator 141a as seen in FIG. 2A. Since each LG address is just the partial address of the final matched address, thus it is not ready to inform the off-chip flash controller yet. The search process flow will continue on block searching to find one matched LBL corresponding to a matched block. The flow moves to next step 214.

Step 214: This step is to search for one matched block once the matched LG is found. As explained in prior pages of this application, the search of matched block is done by sequentially scanning through 8 blocks of one matched LG by turning on/off SSLs of 7 NAND strings. In WCS, it will go through 7 cycles if the final 8^{th} block is the matched one, while in BCS, it will takes only 1 cycle. Next the flow moves to step 216. In an embodiment, during LG-search, all 8 SSLs and 8 GSLs are turned within the matched LG to bring ML voltage at Logic-low. But in order to determine which block is the real matched one to cause ML voltage at a Logic-low level, we have to do trial and error to find the matched block by checking if a common node of ML returning back to a “Logic-high” when the string is selectively disconnected from the ML node.

Step 216: Once the matched LBLps or ML voltage switches back from a “Logic-low” to a “Logic-high” upon turning off one specific SSL, then the matched block is finally found. Next one corresponding LG-ROM will immediately encode and return 3 corresponding address bits of the matched block in addition to the address bits of the matched LG. Note, on-chip state-machine will check if total 7 cycles have been performed for finding the matched block? If No, then the process continues to loop. If Yes, then the flow moves to next step 217.

Step 217: Since one matched block is found, then the address of matched block has to be returned to the Aggregator 141a. Then, the flow moves to next step 218.

Step 218: After the matched block is found, the stored charges on all sets of WLs, WLBs, LBLs, and GSLs in Y-PB can be discharged simultaneously in 1-cycle, being ready for next search operation. After that, the flow moves to step 250, in a process flow to be illustrated in later section of the specification.

FIG. 11B is a flow chart illustrating a method for performing an operation of Y-word search with flexible length according to another embodiment of the present invention. This diagram is merely an example, which should not unduly limit the scope of the claims. One of ordinary skill in the art would recognize many variations, alternatives, and modifications. As shown, the method 3000 for performing an operation of Y-word search starts from a Block-match followed by a LBL-match in accordance with one exemplary LG circuit shown in FIG. 2E and the NAND-CAM array using horizontal CSL as ML and BLK-ROM as shown in FIG. 2B of the present invention. The process flow of the method 3000 starts from step 300 for receiving the Y-word search command. The detail operations of all steps are given below by referring to FIG. 2A, FIG. 3B, 3C, 3D, and SA of 138b shown in FIG. 4B.

Step 300: The method 300 for performing the preferred NAND-CAM search operation starts to sequentially receive Y-word search command and complimentary data in units of byte from an off-chip flash controller via byte-based I/Os of the NAND-CAM array, similar as the step 200.

Step 301: In this step, the received Y-word complimentary data with 1-block length in PRB is transferred and connected to the block decoder circuit 55 of FIG. 2A to prepare for generating preferred LV search voltages of Vsch and VschB for one set of common search signals of 64 GWLs, 64 GWLBs, 1 SSLp, and 1 GSLp in accordance with the Y-word complimentary data. The voltages of Vsch and VschB are subsequently to be loaded and latched into the preferred capacitor-based Y-PB in unit of blocks formed on top NAND-CAM array.

Step 302: This step is for receiving search confirm command to start subsequent Y-word search operation.

Step 303: this step is to set complimentary voltages Vsch/VschB paired block decoder bus lines GWLs and GWLBs for the one-block length of Y-word.

Step 304: This step is to prepare for starting Y-word search by setting following conditions: 1) setting gate bias voltages of BHG, MGo, MGe, BLG, SSL, all WLs, all WLBs, and GSL to 0V; Pre-discharging all CSLs and MLs to Vss by using one-shot signal V_{READ} on gate of ISO devices. Then, the flow moves to Step 306.

Step 306: This step is to find out one matched Block by setting the following conditions in accordance with the block circuit shown in FIG. 2E: 1) setting all LBLps lines to Vdd to charge up one corresponding ML voltage to Vdd-Vt of one matched block but to keep all remaining un-matched blocks at initial Vss; 2) enabling all BLK-SAs and all corresponding BLK-ROMs.

Step 308: To start concurrent Y-word search on all blocks simultaneously in 1-cycle. This step takes less than 10 μs by charging one matched ML through one matched NAND-CAM string to a “Logic-high” voltage above Vt of a detecting NMOS transistor MN1 of the BLK-SA 138b (see FIG. 4B) and keeping voltages of those unmatched MLs at initial Vss due to the current flow from LBLps metal line is blocked. Thus, this BLK-SA will amplify the signal of ML voltage and then send an output voltage at OUT node accordingly (see FIG. 4B). Next, the flow moves to step 310.

Step 310: If none of ML voltages is found to be at Logic-high, then it means no match is found between the Y-word and the stored keys or data in any NAND string of all blocks. Then the method 3000 moves the search process flow to a step 312 which returns a message of “No match” by sending out a signal LASTLGB=1 and a 9-bit digital data of “1FF” for corresponding 9 paired-block addresses of A[30] to A[22] to the off-chip flash controller and move to a next step 274 in a flow to be illustrated in a later section of the specification. If one ML voltage is found to be at Logic-high, then it indicates a match of one paired-block sharing the matched ML is found. Next, the search process flow moves to a step 314.

Step 314: One paired-block is found containing matched Y-word, then the NAND-CAM will automatically return address of the matched paired-block to an on-chip Address Aggregator 141b via BLK-ROM 139b as seen in FIG. 2B. Note, the matched paired-block address is just a partial address of a final matched address, thus it does not need to inform the off-chip flash controller. The search flow will continue, starting from next step, to search for a matched block.

Step 315 and 316: These steps are to find one block out of the two blocks in the matched paired-block. The search is effectively performed by disconnecting the two blocks first from one common matched CSL to keep Logic-high voltage at CSL and ML nodes, then reversely setting all LBLps lines at Vss to discharge all C_{LG}s at Vss by setting PRE to Vdd. If the matched CSL or ML of one matched 2-block at Logic-high is discharged to Vss via one matched string. It just needs 1-cycle to identify the one block out of the two matched blocks of NAND-CAM array sharing the matched CSL line. Then the search flow moves to a next step 318.

Step 318: In this step, a second block of the matched 2-block is being turned on with a first block remaining in off-state to check the impact on node voltages of SL and ML due to expected sinking current of a matched block. If the ML voltage switches from a “Logic-high” to a “Logic-low” after the second block is on, then CSL is at ML Logic-low or at 0V. In this case, the matched block is verified as the second block of the matched 2-block. If the ML voltage remains at a “Logic-high” after the second block is on, the matched block is verified as the first block of the matched 2-block. Next, the flow moves to Step 323.

Step 323: Since the matched block is found, then the address of the matched block has to be returned to the Aggregator 141b (see FIG. 2B). Then, the flow moves to Step 324.

Step 324: All voltages of complimentary Vsch and VschB and all WLs, WLBs, SSLs, and GSLs of all blocks during Y-word search can be discharged to Vss once the address of the matched block is finally found to eliminate further WL HV disturbance. Next, the process flow moves to the step 250 to continue finding the final matched LBL.

FIG. 11C is a flow chart illustrating a method for performing an operation of Y-word search with flexible length according to certain embodiments of the present invention. This diagram is merely an example, which should not unduly limit the scope of the claims. One of ordinary skill in the art would recognize many variations, alternatives, and modifications. As shown, a Y-word search method 4000 is performed under the preferred NAND-CAM of the present invention. In a first embodiment based on hierarchical Block-based NAND-CAM array shown in FIG. 2E, the search scheme uses a CSL-SA coupled with a CSL-ROM and regular horizontal (parallel to WL) CSLs as MLs to find one matched block and use corresponding GBL and DR-SA and Y-pass circuits to find one matched LBL. In a second embodiment based on hierarchical non-Block-based and non-LG-based NAND-CAM array shown in FIG. 2F, the search scheme uses DR-SAs, PRBs, and Y-pass circuits along with vertical (parallel to BL) CSL lines as MLs to find one matched block and one matched LBL. In a specific embodiment, the Y-word search 4000 is preferably performed in the following flow sequence, starting from step 450, from GBL-match search, LBL-match search, CSL-match search, and Block-match search.

The flow starts from step 450 for receiving Y-word search command, next step 452 for loading Y-word data to Y-PB, next step 454 for receiving confirm code before moving to following steps 456-462 for performing GBL-match search.

Step: 456: This step is to search for one matched GBL out of 8 KB GBL lines being connected to corresponding 8 KB SAs in 8 KB DRs. In this approach, all 8 KB GBLs lines acting as 8 KB MLs respectively sensed by 8 KB DR-SAs simultaneously in 1-cycle operation. Since each Odd and Even LBL associated with an Odd and Even NAND-CAM string is connected to a DR-SA via a single GBL, thus the LBL-match and address cannot be done directly in 1-cycle and needs to take 2 cycles. This is like the previous CSL-search, which is also performed in 2-block because 2 adjacent blocks share one CSL. Thus 1-block address search cannot be done directly in 1-cycle.

Before connecting 8 KB GBL and 8 KB LBLo or 8 KB LBLe, the voltages in all selected GBL and SSL lines have to be reset to Vss first by setting GLBps signal to 0V and setting EVENGBL and VOUT_2 signals to Vdd to connect each GBL line to each corresponding SA. Additionally, by setting BHG, MGo, MGe, and BLG signals to Vdd and setting two String-select gates signals SSL and GSL to Vdd, all Odd or Even broken-LBLs of one matched block are connected to GBL lines and further to 8 KB DR-SAs. Finally, by loading Vsch/VschB on 64 WLs and 64 WLBs and SSL and GSL on one selected block the LBL search is performed.

Step 457: In order to identify the matched LBL in one matched block, a charge-up on matched GBL by supplying a current from one matched CSL by setting CSL at Vdd through both Y-pass gates MGo and MGe. For the matched GBL that contains one matched LBL, the GBL voltage is detected to be Logic-high by one input of one corresponding DR-SA and ROM in I/O area. For those unmatched strings, the GBL voltages are at 0V.

Step 458: Each latch-type DR-SA has a second input to be loaded with a reference voltage V_{REF} for sensing comparison operation. Both inputs of each SA are respectively loaded with V_{REF} and Vsch-Vt_{H}, where V_{REF}=½ (Vsch−Vt_{H}).

Step 459: All DR-SAs and PRBs are enabled for next GBL and LBL searching operations. Each latch-type DR-SA has a second input to be loaded with a V_{REF} for sensing comparison operation. By the step, the message of 8 KB Odd or Even LBL data is stored in 8 KB SA.

Step 460: This step is to check all 16 KB LBL status. Since the sizes of PRB and SCR are only 8 KB to save the area, it takes 2cycles to transfer two 8 KB Odd LBLe and 8 KB LBLo to respective 8 KB PRBs and 8 KB SCRs. The first sensed 8 KB data in 8 KB SAs are transferred to 8 KB corresponding PRBs and SCRs. Then PASS1 node is checked if it is at 0V before the flow moves to step 461.

Step 461: This is to determine if a GBL-match is found. If no GBL-match is found, then the flow moves to step 462. If a GBL-match is indeed found, then the flow moves to step 463.

Step 462: Since PASS1 node is at Vdd, it indicates there is no GBL-match. Thus the flow moves to step 494 to end the search if the Y-word search is based on Block-based NAND-CAM array in the first embodiment or the flow moves to step 700 to end the search if the Y-word search is based on non-block-based and non-LG-based NAND-CAM array in the second embodiment.

Following steps from step 463 through step 468 are designed to perform LBL-match search, which is similarly performed in same SAs and PRBs using vertical CSLs as MLs as above steps of 456 through 462.

Step 463: This step is to do only 8 KB Odd LBL search by disconnecting each LBLe from one corresponding GBL by setting MGe gate to 0V but MGo gate to Vdd to keep one Odd LBL search operation.

Step 464: This is performed in a reverse manner to sink GBL Vdd voltage by setting CSL at 0V. Thus, all CSLs become 0V after pre-discharge so that GBLs will be set in accordance with the NAND strings stored data in all blocks in all LGs, MGs, and HGs. One matched NAND string associated with the LBLo in the matched block, CSL=0V will sink one GBL to Vss accordingly because the corresponding NAND string of the LBLo matches Y-word and is in conduction state with MGo gate being set at Vdd. This means that the matched LBL is found and it is an Odd LBLo. Conversely, if no LBLo strings sink any GBL voltages, thus all GBLs are at Vdd, then the matched LBL is a LBLe. All these results have to be detected by PASS1 line of corresponding PRB.

Step 465: As explained above, the second sensed LBL-match result has to be loaded into DR-SA for comparison. In this case, both data of VREF at Logic-high and Vss are loaded into the tracking capacitors of CP1 and CP2 respectively before loaded into SA's paired Q and QB nodes with reference to SA circuit shown in FIG. 6.

Step 466: Now all 8 KB SAs, 8 KB PRBs, and 8 KB SCRs are enabled for subsequent sensing operation.

Step 467: As oppose to GBL-match search operation to load the search result into both 8 KB PRBs and 8 KB SCRs, in this LBL-match search operation, the 8 KB search results are only being stored in 8 KB PRB only.

Step 468: This is a step to determine if PASS1 node voltage is not 0V, then the flow moves to step 469. Otherwise, it moves to step 470.

Step 469: Since PASS1 node voltage is determined to be not at 0V, thus it indicates the matched LBL is a LBLo as explained above. Then the flow moves to step 471.

Step 470: Since PASS1 node voltage is determined to be at 0V, thus it indicates the matched LBL is a LBLe as explained above. Then the flow moves to step 471. Here, the matched LBL is found but the corresponding address of this matched LBL has to be further encoded.

Step 471: It is to search for the matched LBL by sequentially turning one YCk address signal at a time via control of YC-decoder and Y-pass circuits and by setting all YAi and YBj signals to Vdd. One matched YCk is found when one of 8 bits BLSCH8 signals is pulled to Vss when the YCk location contains one matched LBL address. The YCk value is literately incremented each cycle from YCk=0 until the one bit of I/O buffer output BLSCH8 signal at Vss is detected, then YCk increment stops. The YCk value is the matched YCk address to be returned to Address Aggregator. Once YCk address is found, the next step for this search flow is to further find the matched YBj.

Step 472: This step is to find one YCk address of one matched LBL. It is reversely performed to check if I/O buffer output BLSCH8 signal is Vdd when the YCk of matched LBL is shut off one at a time to disconnect the matched LBL. If the YCk-match is found, then it moves to step 474. Otherwise, the YCk value is incremented and the step is repeated.

Step 474: This step is to find one YBj address of one matched LBL. It is reversely performed to check if I/O buffer output BLSCH8 is Vdd when the YBj of matched LBL is shut off one at a time to disconnect the matched LBL. If YBj-match is found, then it moves to step 476. Otherwise, the YBj value is incremented and the step is repeated.

Step 476: This step is to find one YAi address of one matched LBL. It is reversely performed to check if I/O buffer output BLSCH8 is Vdd when the YAi of matched LBL is shut off one at a time to disconnect the matched LBL. If YAi-match is found, then it moves to step 478. Otherwise, the YAi value is incremented and the step is repeated.

Step 478: After sequentially finding all the addresses of YAi, YBj, and YCk for one matched LBL, then the addresses of above three Y-decoders will be returned to the on-chip Address Aggregator and then the flow continues to search for the last matched block. If this flow is executed under the first embodiment associated with Block-based NAND-CAM array, then the flow moves to step 480. Conversely, if this flow is executed under the second embodiment associated with non-Block-based and non-LG-based NAND-CAM array, then the flow moves to step 680.

FIG. 11D is a flow chart illustrating a LBL-match search method of Y-word search with flexible length for searching matched LBL according to some embodiments of the present invention. This diagram is merely an example, which should not unduly limit the scope of the claims. One of ordinary skill in the art would recognize many variations, alternatives, and modifications. As shown, a LBL-match search method 2500 is commonly operated within several Y-word search schemes based on hierarchical LG-based NAND-CAM array in FIG. 2D, or hierarchical Block-based NAND-CAM array in FIG. 2E, or hierarchical non-Block-based and non-LG-based NAND-CAM array in FIG. 2F. The method 2500 includes a process flow starting with searching one matched GBL, and then searching one of matched LBLo or matched LBLe out of two LBLs within each matched GBL. Note, each GBL is shared by one LBLo and one LBLe as depicted in each MG group layout (see FIG. 3A).

Step: 250: This step is to search for one matched GBL from 8 KB GBL lines that are respectively connected to corresponding 8 KB SAs in 8 KB DRs. In this approach, all 8 KB GBLs lines act as 8 KB MLs which are sensed by 8K DR-SAs collectively and simultaneously in 1-cycle operation. Since each pair of, Odd and Even, LBLs associated with a NAND-CAM string is connected to each DR-SA via one GBL, thus the LBL-match and address cannot be done directly in 1-cycle but needs to take 2 cycles. This is like the previous CSL-search, which is also performed in 2-block because 2 adjacent blocks share one CSL. Thus 1-block address search needs to be done in 2 cycles.

Step 251: To continue searching for one matched GBL following last successfully found matched block, the address of the matched block is reloaded to select the block with the complimentary Vsch and VschB voltages set for Y-word. Only one set of Y-word data with complimentary Vsch and VschB on GWLs, GWLBs, SSLp, and GSLp is loaded into one corresponding sets of WLs, WLBs, SSL, GSL of one matched block as found in previous block-search operation. For those 1,023 un-matched blocks in the NAND-CAM array, all gate voltages for word lines WLs and WLBs, String-select signals SSLs and GSLs are set to 0V. Then all 16 KB NAND strings of the matched block are connected to 8 KB GBLs in 2 cycles. For example the 8 KB Odd LBLo are connected to the 8 KB GBLs first, and then 8 KB Even LBLe are connected to the same 8 KB GBLs next or vice versa.

Step 252: This step is to reset the voltages in all selected GBL and SSL lines to Vss before connecting 8 KB GBLs and 8 KB LBLo or 8 KB LBLe. The resetting operation is done by setting GLBps signal to 0V, setting both EVENGBL and VOUT_2 signals to Vdd to connect each GBL line to a corresponding SA. Next, gate signals of BHG, BLG, MGo and MGe, SSL and GSL are set to Vdd to connect all broken-LBL to GBL lines to pave a connection from LBLs of one matched block to 8 KB DR-SAs. Further, complimentary voltages Vsch/VschB on 64 WLs and 64 WLBs and SSL and GSL on one selected block are loaded for performing the LBL-match search method 2500 which continues on next step 253.

Step 253: In order to identify the matched LBL in one matched block, a charge-up on matched GBL is performed by supplying a current from one matched CSL (by setting CSL to Vdd) through both gate signals MGo and MGe. For the matched GBL that contains one matched LBL, the GBL of Logic-high can be detected by one input of a corresponding DR-SA and ROM in I/O area. For those unmatched strings (with unmatched LBLs), the corresponding GBLs are set to 0V.

Step 254: Each latch-type DR-SA has a second input to be loaded with a reference signal V_{REF} for sensing comparison operation. In this step, both inputs of each DR-SA have been loaded respectively with V_{REF} and Vsch-Vt_{H}, where V_{REF}=½ (Vsch−Vt_{H}).

Step 255: All DR-SAs and PRBs are enabled for next GBL and LBL searching operations. Through this step, the message of 8 KB Odd or Even LBL data is stored in 8 KB SAs.

Step 256: A first sensed 8 KB data in 8 KB SAs are then transferred to 8 KB corresponding PRBs and SCRs.

Step 257 through step 260 is to repeat the above steps of 252 through 255 for GBL search. Step 257 is performed only for 8 KB Odd LBL search by disconnecting all LBLe from the GBLs by setting MGe gate to 0V and MGo gate to Vdd.

Step 261: Unlike in GBL search the search results are loaded in both PRB and SCR, in this LBL search, the 8 KB search results are only stored in 8 KB PRBs.

Step 262: It is to determine if one matched LBL contains the matched Y-word in this step by checking voltage of PASS1 node of PRB with reference to the DR circuit shown in FIG. 6. If PASS1 node is at 0V, the flow moves to a step 264 below. Otherwise, it moves to next step 263.

Step 263: The matched LBL is determined to be a LBLe and confirmed because the second sensed message is determined from 8 KB LBLo with PASS1 at 0V. It means one of LBLe's data matches Y-word, conducting a current to lower PASS1 node voltage from Vdd to Vss. Next, the step moves to step 265.

Step 264: The matched LBL is determined to be a LBLo and confirmed because the second sensed message is determined from 8 KB LBLo with PASS1 not equal to 0V. Here at least one of LBLo's data matches Y-word, thus conducting current to lower VPASS1 from Vdd to Vss. Next, the step moves to Step 265.

Step 265: Once one matched LBL is found and confirmed, step 265 is to decode the address of this matched LBL by coupling the 8 KB SCR outputs to all Data lines that are connected to a Y-pass gate circuit (see FIG. 7A) via a 3-level Y-decoder and GBL-sensing pull-up PMOS transistors built in 8 I/O Buffers with their outputs connected to a small LBL-ROM shown in FIG. 7E.

Step 266: It is to search for the matched LBL by sequentially turning one YCk signal at a time via the control of Y-decoder and Y-pass gate circuits and setting all YAi and YBj signals to Vdd. One matched YCk is found when one of 8 bits BLSCH8 outputs is pulled to Vss and the YCk location contains one matched LBL address. The YCk value is literately incremented in each cycle from YCk=0 until the one bit of BLSCH8 output at Vss is detected, then the YCk increment stops with a final YCk value is the matched YCk address which is returned to the Address Aggregator. Once the YCk address is found, the method 2500 moves to a next step 267 to find the matched YBj address.

Step 267: Similar to the step 266, it is to find one YBj address of the matched LBL. Specifically, it is to check, in a reversed fashion, if the BLSCH8 output is Vdd corresponding to one of the YBj of the matched LBL that is to disconnect the matched LBL. Further the method 2500 moves to a next step to find the matched YAi address.

Step 268: Similar to the step 266, this step is find one YAi address of one matched LBL. It is performed in reversed fashion again by checking if BLSCH8 output is Vss corresponding to one of the YAi of matched LBL that is turning on to sink the matched LBL to a Vss.

Step 269: After sequentially finding all the addresses of YAi, YBj, and YCk for one matched LBL, then the addresses of above three Y-decoders will be returned to the on-chip Address Aggregator.

Step 270: At this step, all voltages stored in all WLs, LBLs, SSLs, and GSLs of all blocks of the whole NAND-CAM array are then discharged concurrently for reducing the WL gate disturb.

Step 271: All matched addresses generated from the block-search, YAi-search, YBj-search, and YCk-search are used to form one matched LBL address in unit of bytes in the Address Aggregator.

Step 272: Nest, a N-bit matched address of one matched LBL is outputted to an off-chip flash controller via 8 I/O buffers.

Step 274: End the Y-word search.

FIG. 11E is a flow chart illustrating a method of Y-word search with flexible length for searching matched block according to an embodiment of the present invention. This diagram is merely an example, which should not unduly limit the scope of the claims. One of ordinary skill in the art would recognize many variations, alternatives, and modifications. As shown, a Y-word search method 4500 for a hierarchical Block-based NAND-CAM array as shown in FIG. 2E is continued from the previous search method 4000 that finds one matched LBL at the step 478. The method 4500 is to search for the last address of one matched Block for a Y-word length of 1-block of the present invention. The matched LBL data is stored in 8 KB SCRs with one bit data therein is set to be Vdd, and the rest bit data of 8 KB-1 SCRs are set to be Vss.

Step 480: For searching under the Block-based NAND-CAM array, CSL is used as ML. In order to find one matched CSL shared by one paired-block, the method 4500 is to use one matched bit in 8 KB SCRs to charge the matched CSL line through one matched NAND-CAM string in the matched paired-block. Since one matched GBL address is still stored in one SCR bit but the address of one matched block is unknown, thus all sets of all WLs and WLBs, SSLs and GSLs of all 1,024 blocks in all LGs, MGs, and HGs have to be applied with Y-word complimentary-bit data by setting all the control signals in following conditions under the hierarchical Block-based NAND-CAM array and associated peripheral circuits: 1) Disconnecting Y-pass gate circuit from the 8 KB SCRs, because 8 KB GBL data containing one matched GBL of Vdd will be connected to all 8 KB GBL. 2) Connecting all 8 KB SCRs to all 8 KB GBLs. 3) Connecting 8 KB GBLs to all 8 KB LBLo and LBLe lines in all LGs by setting gates for BHG, MGo, MGe, BLG, SSL, and GSL to Vdd so that one of the matched CSL will be charged up via the matched NAND-CAM string. Thus WLs voltages are set to Vsch/VschB and complimentary WLBs voltages are at VschB/Vsch.

Step 481: All 512 on-chip BLK-SAs and BLK-ROMs are enabled for finding one matched CSL shared by a paired-block by detecting a CSL is at Logic-high.

Step 482: This step is to return the address of matched one paired-block to on-chip match Address Aggregator.

Step 483: This step is to find one out of two blocks in the matched one paired-block. The method is to reversely check which block can discharge the matched CSL of Logic-high to Vss through one matched string, one matched LBL, and GBL, to GBLps node at Vss in DR-SA. Here, a first block (an Odd block) is shut off to disconnect it from one matched CSL line.

Step 484: All DL1 lines are set to Vss under following bias conditions with reference to the DR-SA circuit as shown in FIG. 6: GBLps signal is set to 0V, and GBLEN is set to Vdd. Other signals of each DR-SA are set to Vss to isolate DI common node from 2 inputs of SA and paths to PRB and SCR. For example, D_OUT2, ENCSL, PGM signals are set to Vss.

Step 486: This step is to determine if the CSL or ML voltage is at 0V when the first block of the paired-block is disconnected from one matched CSL. If the CSL is found to be 0V, then flow moves to step 487 to confirm the second block (of the paired-block) is Matched block. If the CSL is not 0V, then flow moves to step 486 to confirm the first block is Matched block. Two steps are merged at step 489.

Step 489: this step returns the lastly found address of one matched block to on-chip Address Aggregator.

Step 490: All stored voltages of WLs, WLBs, SSLs, and GSLs in all blocks of Y-PB in the NAND-CAM array are discharged to Vss through concurrently opening all latched Blocks to reduce the gate stress.

Step 491: All found matched addresses of one matched LBL and one matched block are formed N-bit matched address in units of bytes.

Step 492: Lastly, the N-bit matched address of one NAND-CAM string stored data that matches Y-word is sequentially output to an off-chip flash controller.

FIG. 11F is a flow chart illustrating a method for performing an operation of Y-word search with flexible length according to still another embodiment of the present invention. This diagram is merely an example, which should not unduly limit the scope of the claims. One of ordinary skill in the art would recognize many variations, alternatives, and modifications. As shown, a Y-word search method 6000 includes a process flow starting with searching one matched-CSL and ending with a LBL-match search in accordance with the exemplary LG circuits within hierarchical non-Block-based and non-LG-based NAND-CAM array of FIG. 2F.

In a specific embodiment, the order of operations of the Y-word search method 6000 starts with steps of finding one matched CSL (in one matched 2-block), and finalizing the search of a last matched block. The search operation under this method has near-zero silicon overhead with fast speed because it uses only all existing circuits of DR-SA, PRB, SCR, Y-pass gate, and YA, YB, and YC decoders in idle-state with one small LBL-ROM circuit to perform the search operation. Note, in the NAND-CAM array of FIG. 2F 512 CSL lines are bended 90 degrees from horizontal WL direction to vertical BL direction through some Y-direction Vss line areas to connect to 512 chosen SAs with additional input device. The Y-word search method 6000 is performed in accordance with the NAND-CAM circuit shown in FIG. 2F, the circuits of SA, PRB, and SCR shown in FIG. 6, Y-pass gate and GBL-detecting circuit shown in FIG. 7A, and one small ROM to decoder 3-bit for a matched byte BL address shown in FIG. 7E.

Similarly, the method 6000 starts from step 600 through step 604 to receive Y-word search command, load Y-word data to Y-PB, and receive confirm code for preparing search operation described earlier.

Step 606: This step is to set up the whole NAND-CAM array for finding one matched CSL out of 512 CSLs under a search scheme without the LG-SAs, BLK-SAs, LG-ROMs, and BLK-ROMs used in previous methods. To find one matched CSL means to find one matched paired-block which shares one common CSL. The setting conditions include resetting all parasitic capacitors to Vss along a path starting from a GBL to a NAND string before CSL-match search starts. Firstly, a one-shot discharge of all 512 CSL capacitors is done by grounding GBLps line located in SA. GBLps is set to 0V, GBLEN, VDOUT_2, and ENCSL are set to Vdd so that a current is flowing through a transistor MN67 from each GBLps line to each DL line and then to each corresponding GBL and further to all LBLe, LBLo, and two NAND strings connected to one common CSL. Secondly, all gates to BHG, MGo, MGe, BLG, SSL, and GSL are set to Vdd to connect all blocks and LGs, MGs, and HGs to provide a current path from GBL to each Odd and Even strings. Thirdly, voltages of WLs are provided as Vsch/VschB and voltages WLBs are provided complimentarily as VschB/Vsch for Y-word bits on all blocks.

Step 607: this step is to charge all 8 KB GBLs so that one matched NAND string or one LBL out of 16 KB strings or LBLs will conduct a current to charge up corresponding CSL. The matched CSL can be found by each corresponding DR-SA. The following settings are applied to charge all 8 KB GBLs: 1) Charging all 8 KB GBLs and 16 KB LBLs to Vdd-Vt by setting GBLEN≧Vdd and GBLps=Vdd. 2) Setting a Logic-high CSL_{H}=Vsch-Vt_{H} for one matched CSL of a paired-block (sharing the CSL) but setting CSL_{L}=Vss for the rest of 511 unmatched CSLs.

Step 608: The voltages of 512 CSLs (with one CSL being sensed at a Logic-high but 511 CSLs being sensed at Vss) are respectively latched by 512 corresponding DR-SAs via the 512 CSL lines (512 local horizontal CSLs and 512 vertically bending CSLs).

Step 609: This step is to enable all 8 KB DR-SAs, 8 KB PRBs, and SCRs because this Y-word search scheme uses the existing DRAM-like SAs, PRBs, and SCRs, and LBL-ROM circuit, Y-pass gate circuit, and Y-decoder circuits to perform Y-word search without using extra silicon overhead.

Step 610: The sensed voltages stored in 8 KB DR-SAs are transferred to the corresponding 8 KB PRB and 8 KB SCRs at the same time in 1-cycle. PASSS1 node is checked to see if one matched CSL is found, which is determined by 0V at the PASS1 node at next step.

Step 611: This is to check if PASS1 node is 0V. If No, then the flow moves to step 612 and confirms no match of Y-word search in the whole NAND-CAM array. The flow will continue to the step 274 (FIG. 11D). If Yes, then the flow moves to step 613 and confirms one match of Y-word search in the whole NAND-CAM array. Then, the flow continues to find out one matched block from this one matched CSL.

Step 613: This step is to further search for one matched block of one paired-block that finds the matched CSL. A first option is to shut off only the first block of the paired-block having matched CSL, but to keep the second block in conducting state. Conversely, a second option is to shut off only the second block but keep the first block in conducting state. In the above CSL-search, one CSL is charged up by one GBL if one LBL-match is found. Then, all GBLs are at either Vdd or Vdd-Vt. Now to perform the BLK-search, a GBL discharge scheme is used and still sensed by all 8 KB DR-SAs, where the matched CSL data has been transferred to PRB and SCR. Thus, these 8 KB DR-SAs are ready to sense the second matched-block address data.

Step 615: This step is to discharge all CSLs at 0V to set all GBL voltages in accordance with Y-word data in all 16 KB×1,024 NAND-CAM blocks.

Step 616: Load 8 KB GBL voltages of one sensed matched-block data together with one VREF voltage respectively into two inputs per SA of 8 KB DR-SAs for search evaluation.

Step 617: Enable all DR-SAs, PRBS, and SCRs.

Step 618: The sensed voltages stored in 8 KB DR-SAs are transferred to the corresponding 8 KB PRBs only in 1-cycle. Check PASSS1 to see if one matched CSL is found.

Step 619: This is to determine if PASS1 node is Vss=0V. If No, the flow moves to step 621. If Yes, the flow moves step 210.

Step 620: PASS1 node is determined to be Vss under the condition of setting the first block at an Off-state. Thus only the first block can have a chance to discharge GBL to CSL=0V. Thus, this step confirms the matched block is the first block.

Step 621: Conversely, PASS1 node is determined to not equal to Vss under the condition of the first block being set to Off-state. Thus only the 2nd-block can have a chance to discharge GBL to CSL=0V. Thus, this step confirms the matched block is the second block.

Step 622: This step encodes the address of one last matched block via Y-pass sequential decoding method as explained before.

Step 623: This step is keeping on searching an address of one matched block via a first level YCk check. If YCk is found, then moves to step 695.

Step 624: This step continues searching one matched block via a second level YBj check. If YBj is found, then moves to step 696.

Step 626: After the matched block address is found, it is returned to an on-chip Address Aggregator and then the flow moves to step 250 of method 2500 in FIG. 11D.

FIG. 11G is a flow chart illustrating a method of Y-word search with flexible length for searching matched block according to another embodiment of the present invention. This diagram is merely an example, which should not unduly limit the scope of the claims. One of ordinary skill in the art would recognize many variations, alternatives, and modifications. As shown, a Y-word search method 6500 continues from the previous search flow under a hierarchical non-Block-based and non-LG-based NAND-CAM array in FIG. 2F that finds one matched LBL at Step 478 (of method 4000 in FIG. 11C). The method 6500 is to search for the last address of one matched Block for a Y-word length of 1-block of the present invention. The matched LBL data is stored in 8 KB SCRs with one bit is set to be Vdd, and the rest bits of 8 KB-1 SCRs are set to be Vss.

Step 680: In order to find the matched CSL shared by one paired-block in the hierarchical non-Block-based and non-LG-based NAND-CAM array, the method 6500 uses this step for charging one matched bit of 8 KB SCRs and the matched CSL line through one matched NAND-CAM string of one matched paired-block. Since one matched GBL address is still stored in one SCR bit but the address of one matched block is unknown, thus all sets of all WLs and WLBs, SSLs and GSLs of all 1,024 blocks in all LGs, MGs, and HGs have to be applied with Y-word complimentary-bit data. The bias conditions for setting the whole array are provided: 1) Applying one-shot pulse to set GBLps=0V and GBLEN=DOUT 2=ENCSL=Vdd to discharge CSLs to 0V. 2) Setting all gate signals for BHG, MGe, MGo, BLG, SSL, and GSL to Vdd. 3) WLvoltage is set to Vsch/VschB and WLB voltage is set to VschB/Vsch. As a result, CSL line, DL line, GBL, LBLe, and LBLo is set to 0V.

Step 681: Now, this step is to charge up all GBLs with Vdd for finding one matched CSL shared by a paired blocks by detecting which CSL is at Logic-high due to the matched string with Y-word?

Step 682: Load back each CSL's sensed voltages of Logic-high or Vss into one corresponding input of one DR-SA with one VREF appears at another input of SA. Totally, there are 512 CSLs' sensed voltages to be loaded into 512 selected DR-SAs of 8 KB DRs. Then the flow moves to Step 683.

Step 683: This step is to enable all 8 KB DR-SAs, 8 KB PRBs, and SCRs because this Y-word search scheme uses the existing free SAs, PRBs and SCRs and LBL-ROM and Y-ass and Y-decoders to perform Y-word search without using extra silicon overhead. The flow moves to Step 684.

Step 684: The sensed voltages stored in 8 KB DR-SAs are transferred to the corresponding 8 KB PRB and 8 KB SCRs on the same time in 1-cycle. Check PASSS1 to see if one matched CSL is found if V_{PASS1}=0V.

Step 685: This step further searches for one matched block of one paired blocks that share one matched CSL by shutting off only first block of one matched paired blocks.

Step 686: Discharge all CSLs to 0V to set all GBLs' voltage in accordance with NAND string data.

Step 687: Load 8 KB GBLs' voltages with one V_{REF} into two inputs of 8 KB DR-SAs for search evaluation.

Step 688: Enable all DR-SAs, PRBS, and SCRs.

Step 689: A) The sensed voltages stored in 8 KB DR-SAs are transferred to the corresponding 8 KB PRB only in 1-cycle. B) Check PASSS1 to see if one matched CSL is found.

Step 690: The flow moves to Step 690 to check if V_{PASS1}=Vss. If No, then the flow moves to Step 692 to confirm the matched block is the 2^{nd} block. If Yes, then the flow moves to Step 691 to confirm the matched block is the 1^{st} block. Two steps are merged at Step 693.

Step 693: This step encoders the address of one matched block via Y-pass sequential decoding method as explained before.

Step 694: This is the decision step to further find the address of one matched block via 1^{st} level of YCk check. If YCk is found, then moves to Step 695.

Step 695: This step continue searching one matched block via 2^{nd}-level of YBj check. If YBj is found, then moves to Step 696.

Step 696: To return the matched block address to on-chip Address Aggregator.

Step 697: All stored voltages of WLs, WLBs, SSLs and GSLs in all blocks of Y-PB in NAND-CAM are discharged to Vss through concurrently opening all latched Blocks to reduce the gate stress.

Step 698: All found matched addresses of one matched LBL first and one matched block second are formed N-bit matched address in units of bytes.

Step 699: Lastly, the N-bit matched address of one matched NAND-CAM string that stores one matched data that matches Y-word is sequentially output via 8 I/Os to off-chip Flash controller.

Step 700: End Y-word search.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

1. A method for performing Y-word search with variable length from a NAND-CAM array having divided groups with hierarchical 2-level bit lines and an independent power line in X direction as a match line per group, the method comprising:
providing a NAND-CAM array comprising J numbers of HG groups, each HG group being associated with N₁ broken global bit lines (GBLs) laid at a first level along Y direction and being divided into L numbers of MG groups, each MG group being associated with N₂ local bit lines (LBLs) laid at a second level below the first level in parallel to and respectively coupled to the N1 GBLs via a N₂/N₁-Y-pass circuit and being further divided into J′ numbers of LG groups, each LG group being associated with N₂ broken-LBLs commonly pull down via a precharge circuit to one independent power line configured to be charged to a Vinh voltage, each broken-LBL forming a parasitic line capacitor serving as 1-bit dynamic cache register (DCR), each LG group including H numbers of blocks, each block including N₂ numbers of strings respectively associated with the N₂ broken-LBLs cascaded in a row along a word line (WL) or X direction orthogonal to the Y direction, each string comprising N₃ numbers of NAND memory cells divided into two N₃/2 numbers of complimentary sets of cells capped by a pair of string-select transistors respectively at two ends of the string having its source node connected to a common source line laid in the X direction shared by two neighboring blocks, wherein J, L, J′, H, N₁, N₂, and N₃ are integers of 2 and greater based on memory chip density and design;
providing multiple group-decoders including BHG-DEC, MG-DEC, BLG-DEC, and LG-based precharge power line decoder to generate respective gate control signals for dividing HG groups, coupling N₁ broken-GBLs to N₂ LBLs, dividing MG groups, and pulling down the broken-LBLs to the independent power line per LG group;
providing a block-decoder with a latch circuit coupled to a voltage generator via a set of N₃/2+1 pairs of complimentary bus lines in the Y direction and connected via corresponding block-gate transistors to a pseudo Y-page-buffer made by a corresponding set of N₃/2 pairs of complimentary word lines plus two string-select gate lines in the X direction;
setting the independent power line as a match line coupled to a LG-group based sense amplifier and a LG-group based ROM encoder circuit;
loading a Y-word data, upon receiving a Y-word search command, to the pseudo Y-page-buffer associated with each block;
determining the Y-word data having a length of a full block based on the Y-word search command, to set latch 2ⁿ number of complimentary voltages at each of N₃/2 pairs of complimentary word lines plus two string-select gate lines, otherwise, to add necessary number of don't-care mask bits with a same highest value of the 2ⁿ number of complimentary voltages on remaining pairs of complimentary word lines to make the length of a full block, where n=1 for SLC Y-word search and n=2 for MLC Y-word search.

2. The method of claim 1 further comprising:
turning off the group decoders including BHG-DEC, MG-DEC, BLG-DEC;
setting the set of N₃/2+1 pairs of complimentary bus lines in the Y direction to 0V by timely controlling the voltage generator;
simultaneously discharging all broken-LBLs associated with all LG groups of the NAND-CAM array to each independent power line per LG group, all LG groups being isolated from each other;
setting the independent power line of each selected LG group as the match line with a pre-charged voltage to connect to an input of the LG-group based sense amplifier;
enabling each LG-group based ROM encoder circuit coupled to an output of each LG-group based sense amplifier;
determining a matched LG group containing a string of memory cells with data matching the loaded Y-word data to cause discharging of the pre-charged voltage in the corresponding match line, otherwise stopping further operation on the selected LG group;
returning a first address of the matched LG group to a match-address aggregator, the first address being encoded by the LG-group based ROM encoder circuit.

3. The method of claim 2 further comprising:
turning off the pair of string-select transistors per each string of each block in the matched LG group;
precharging all broken-LBLs and the match line of the matched LG group;
sequentially turning on one pair of string-select transistors per each string of a selected block in the matched LG group in up to H cycles while checking logic state of the match line;
determining the selected block to be a matched one including a second address containing a string of memory cell with stored data matching the loaded Y-word data, otherwise performing similar search operation on a next selected block in the matched LG group;
returning the second address of the matched block to the match-address aggregator;
discharging all WLs, LBLs, and two gate signal lines for controlling two string-select transistors per block for all blocks concurrently.

4. The method of claim 3 further comprising:
reloading the second address of the matched block;
reloading the Y-word data including 2ⁿ number of complimentary voltages per each of corresponding N₃/2 pairs of complimentary word lines and two gate lines for the pair of string-select transistors only associated with the matched block based on the second address, while setting 0V to all gate lines for all unmatched blocks;
connecting each of N₁ GBLs via a HV isolation device to one-bit data-register sense amplifier in the Y direction in a N₁-bit Page Buffer, each data-register sense amplifier being coupled to a program-read buffer circuit and a static cache register and coupled via a first pass transistor to an additional power line;
applying one-shot 0V pulse to the additional power line with the first pass transistor being turned on to set 0V to all GBLs and LBLs to which the matched block belong with all associated transistors in multiple group-decoders including BHG-DEC, MG-DEC, and BLG-DEC being turned on and all precharge circuits being turned off, the MG-DEC including respective connections between Odd/Even LBLs and corresponding GBLs;
setting the common source line of the matched block to Vdd to charge up one of all GBLs corresponding to a matched GBL containing one matched LBL is at a voltage of logic high.

5. The method of claim 4 further comprising:
loading the voltages of all GBLs with a reference voltage into the corresponding data-register sense amplifier in e the Page Buffer of the NAND-CAM array;
transferring status of all data-register sense amplifiers to the corresponding program-read buffer circuits and a static cache registers, the status including information about corresponding Odd/Even LBL coupled to the matched GBL;
connecting all Odd LBLs only while closing all Even LBLs;
resetting GBLs with the status of all data-register sense amplifiers being transferred to the corresponding program-read buffer circuits;
checking an output node voltage of the program-read buffer circuit corresponding to the matched GBL at 0V to determine that a matched LBL is an Even LBL, otherwise to determine that a matched LBL is an Odd LBL.

6. The method of claim 5 further comprising:
coupling outputs of all static cache registers including one associated with the matched LBL to a Y-pass gate circuit via three sets of plurality of Y decoders;
selectively turning on a first set of plurality of Y decoders while other two sets of Y decoders being all set to an on state to determine a first part of a third address of the matched LBL;
decoding a second part of the third address by selectively turning on the second set of Y decoders;
decoding a third part of the third address by selectively turning on the third set of Y decoders;
returning the third address of the matched LBL by combining the first part, the second part, and the third part to the match-address aggregator;
discharging all WLs, LBLs, and gates to the string-select transistors of all blocks concurrently;
forming a full matched address based on the first address, the second address, and the third address;
outputting the full matched address to a Byte-based I/O Buffer circuit.

7. A method for performing Y-word search with variable length from a NAND-CAM array having divided groups with hierarchical 2-level bit lines and a common source line in X direction as a match line per two blocks in each group, the method comprising:
providing a NAND-CAM array comprising J numbers of HG groups, each HG group being associated with N₁ broken global bit lines (GBLs) laid at a first level along Y direction and being divided into L numbers of MG groups, each MG group being associated with N₂ local bit lines (LBLs) laid at a second level below the first level in parallel to and respectively coupled to the N1 GBLs via a N₂/N₁-Y-pass circuit and being further divided into J′ numbers of LG groups, each LG group being associated with N₂ broken-LBLs commonly pull down via a precharge circuit to one independent power line configured in the X direction to be charged to a Vinh voltage, each broken-LBL forming a parasitic line capacitor serving as 1-bit dynamic cache register (DCR), each LG group including H numbers of blocks, each block including N₂ numbers of strings respectively associated with the N₂ broken-LBLs cascaded in a row along a word line (WL) or X direction orthogonal to the Y direction, each string comprising N₃ numbers of NAND memory cells divided into two N₃/2 numbers of complimentary sets of cells capped by a pair of string-select transistors respectively at two ends of the string having its source node connected to a common source line laid in the X direction shared by a neighboring paired-block, wherein J, L, J′, H, N₁, N₂, and N₃ are integers of 2 and greater based on memory chip density and design;
providing multiple group-decoders including BHG-DEC, MG-DEC, BLG-DEC, and LG-based precharge power line decoder to generate respective gate control signals for dividing HG groups, coupling N₁ broken-GBLs to N₂ LBLs, dividing MG groups, and pulling down the broken-LBLs to the independent power line per LG group;
providing a block-decoder with a latch circuit coupled to a voltage generator via a set of N₃/2+1 pairs of complimentary bus lines in the Y direction and connected via corresponding block-gate transistors to a pseudo Y-page-buffer made by a corresponding set of N₃/2 pairs of complimentary word lines plus two string-select gate lines in the X direction;
setting the common source line as a match line coupled along the X direction to a Block-based sense amplifier and a Block-based ROM encoder circuit;
loading a Y-word data, upon receiving a Y-word search command, to the pseudo Y-page-buffer associated with each block.

8. The method of claim 7 further comprising:
determining the Y-word data having a length of a full block based on the Y-word search command, to latch 2ⁿ number of complimentary voltages at each of N₃/2 pairs of complimentary word lines plus two string-select gate lines, where n=1 for SLC Y-word search and n=2 for MLC Y-word search;
turning off the group decoders including BHG-DEC, MG-DEC, BLG-DEC;
setting the set of N₃/2+1 pairs of bus lines in the Y direction to 0V by timely controlling the voltage generator;
simultaneously discharging all common source lines associated with all paired-blocks of the NAND-CAM array, all paired-blocks in all array being isolated from each other;
charging all independent power lines to Vdd to allow a matched paired-block containing a string of memory cells with data matching the loaded Y-word data to have the corresponding match line being charged up to Vdd-Vt while leaving other match lines at 0V;
enabling all the Block-based sense amplifiers and Block-based ROM encoder circuits;
checking all match lines of all paired-blocks simultaneously to determine a first address of the matched paired-block with voltage at corresponding match line above Vt as logic high;
returning the first address of the matched paired-block to a match-address aggregator, the first address being encoded by the Block-based ROM encoder circuit.

9. The method of claim 8 further comprising:
disconnecting the match line from a first block of the paired-block to keep it at Logic-high voltage;
setting all independent power lines at Vss=0V to discharge all broken-LBL based DCRs;
determining the second block to be a matched block in the matched paired-block by recording the match line switched from logic high to logic low, otherwise the first block being a matched block;
returning a second address associated with the matched block to the match-address aggregator;
discharging all WLs, LBLs, and gate lines to string-select transistors for all blocks concurrently.

10. The method of claim 9 further comprising:
reloading the second address of the matched block;
reloading the Y-word data including 2ⁿ number of complimentary voltages per each of corresponding N₃/2 pairs of complimentary word lines and two gate lines for the pair of string-select transistors only associated with the matched block based on the second address, while setting 0V to all gate lines for all unmatched blocks;
connecting each of N₁ GBLs via a HV isolation device to one-bit data-register sense amplifier in the Y direction in a N₁-bit Page Buffer, each data-register sense amplifier being coupled to a program-read buffer circuit and a static cache register and coupled via a first pass transistor to an additional power line;
applying one-shot 0V pulse to the additional power line with the first pass transistor being turned on to set 0V to all GBLs and LBLs to which the matched block belong with all associated transistors in multiple group-decoders including BHG-DEC, MG-DEC, and BLG-DEC and all string-select transistors being turned on and all precharge circuits being turned off, the MG-DEC including respective connections between Odd/Even LBLs and corresponding GBLs;
setting the common source line of the matched block to Vdd to charge up one of all GBLs corresponding to a matched GBL containing one matched LBL is at a voltage of logic high.

11. The method of claim 10 further comprising:
loading the voltages of all GBLs with a reference voltage into the corresponding data-register sense amplifier in the Page Buffer of the NAND-CAM array;
transferring status of all data-register sense amplifiers to the corresponding program-read buffer circuits and static cache registers, the status including information about corresponding Odd/Even LBL coupled to the matched GBL;
connecting only the corresponding Odd LBL to the matched GBL while closing Even LBL;
resetting GBLs with the status of all data-register sense amplifiers being transferred to the corresponding program-read buffer circuits;
checking an output node voltage of the program-read buffer circuit corresponding to the matched GBL at 0V to determine that a matched LBL is an Even LBL, otherwise to determine that a matched LBL is an Odd LBL.

12. The method of claim 11 further comprising:
coupling outputs of all static cache registers including one associated with the matched LBL to a Y-pass gate circuit via three sets of Y decoders;
selectively turning on a first set of Y decoders while other two sets of Y decoders being all set to an on state to determine a first part of a third address of the matched LBL;
decoding a second part of the third address by selectively turning on the second set of Y decoders;
decoding a third part of the third address by selectively turning on the third set of Y-decoders;
returning the third address of the matched LBL by combining the first part, the second part, and the third part to the match-address aggregator;
discharging all WLs, LBLs, and gates to the string-select transistors of all blocks concurrently;
forming a full matched address based on the first address, the second address, and the third address;
outputting the full matched address to a Byte-based I/O Buffer circuit.

13. The method of claim 1 wherein the N₁ is number of bits selected from 8 KB, 16 KB or other suitable integers; N₂ is equal to 2^{m}×N₁, wherein m is 0 or a positive integer; J is selected from 8, 16, or other suitable integer smaller than 16; L is an integer selected from 4, 8, 16 or other suitable integer smaller than 16; J′ is 8; H is selected from 8, 16; and N₃ is selected from 64, 128, 256 or other suitable integer smaller than 256.

14. The method of claim 1 wherein the Vinh voltage is no greater than Vdd associated with all low-voltage transistors being used in multiple group-decoders including BHG-DEC, MG-DEC, BLG-DEC, and pairs of string-select transistors that connected to the independent power line per LG group.

15. The method of claim 5 wherein the resetting GBLs comprises:
discharging all common source lines to 0V to set each GBL voltage in accordance with corresponding string data originally stored;
loading all GBL voltages with a reference voltage into the corresponding data-register sense amplifier;
transferring status of all data-register sense amplifiers to corresponding program-read buffer circuits only, the status including information about corresponding Odd/Even LBL coupled to the matched GBL.

16. The method of claim 7 alternatively comprising:
connecting each of N₁ GBLs via a HV isolation device to one-bit data-register sense amplifier in the Y direction in a N₁-bit Page Buffer, each data-register sense amplifier being coupled to a program-read buffer circuit and a static cache register and coupled via a first pass transistor to an additional power line;
applying one-shot 0V pulse the additional power line with the first pass transistor being turned on to set 0V to all GBLs and LBLs with all associated transistors in multiple group-decoders including BHG-DEC, MG-DEC, and BLG-DEC and all string-select transistors being turned on and all precharge circuits being turned off, the MG-DEC including respective connections between Odd/Even LBLs and corresponding GBLs;
latching 2ⁿ number of complimentary voltages associated with the Y-word data at each of N₃/2 pairs of complimentary word lines plus two string-select gate lines, where n=1 for SLC Y-word search and n=2 for MLC Y-word search;
setting all common source lines to Vdd to set all GBL voltages in accordance with corresponding string data including at least a matched GBL containing one matched LBL at a voltage of logic high while rest GBLs being left at 0V.

17. The method of claim 16 further comprising:
loading all GBL voltages with a reference voltage into the corresponding data-register sense amplifier;
enabling all register sense amplifiers respectively coupled to all program-read buffer circuits and all static cache registers in the N₁-bit Page Buffer;
transferring status of all data-register sense amplifiers to the corresponding program-read buffer circuits and static cache registers in two cycles, the status including information about each GBL;
checking an output node voltage of each program-read buffer circuit corresponding to a corresponding GBL at 0V to determine that a matched GBL, otherwise, ending search operation.

18. The method of claim 17 further comprising:
connecting all Odd LBLs only while closing all Even LBLs for all LG group of the NAND-CAM array;
discharging all common source lines to 0V to set all GBL voltages in accordance with corresponding string data;
loading all GBL voltages with a reference voltage into the corresponding data-register sense amplifier;
enabling all data-register sense amplifiers respectively coupled to the corresponding program-read buffer circuits and static cache registers in the N₁-bit Page Buffer of the NAND-CAM array;
transferring status of all data-register sense amplifiers to corresponding program-read buffer circuits only in one cycle, the status including information about all GBLs respectively connecting corresponding Odd LBLs;
checking the output node voltage of the program-read buffer circuit corresponding to the matched GBL at 0V to determine that a matched LBL is an Even LBL, otherwise to determine that a matched LBL is an Odd LBL.

19. The method of claim 18 further comprising:
coupling outputs of all static cache registers including one associated with the matched LBL to a Y-pass gate circuit via three sets of Y-decoders;
selectively turning on a first set of Y-decoders while other two sets of Y-decoders being all set to on state to determine a first part of a first address of the matched LBL;
decoding a second part of the first address by selectively turning on the second set of Y-decoders;
decoding a third part of the first address by selectively turning on the third set of Y-decoders;
returning the first address of the matched LBL by combining the first part, the second part, and the second part to the match-address aggregator, the matched LBL belonging to at least H blocks of a LG group.

20. The method of claim 19 further comprising:
disconnecting each of N₁ static cache registers from a Byte-based I/O Buffer circuit;
connecting all N₁-bit static cache registers to corresponding GBLs which are connected to all corresponding LBLs;
loading the 2ⁿ number of complimentary voltages at corresponding N₃/2 pairs of complimentary word lines and two gate lines for the pair of string-select transistors;
enabling all Block-based sense amplifiers and Block-based ROM encoder circuits for all paired-blocks to find one common source line as the match line to be charged up at Logic high via the matched NAND-CAM string, the match line being associated with a matched paired-block with a second address;
returning the second address of the matched paired-block via a corresponding Block-based ROM encoder circuit to the match-address aggregator.

21. The method of claim 20 further comprising:
disconnecting the match line from a first block of the matched paired-block to keep it at Logic high;
discharging all GBLs to 0V by applying one-shot 0V to each additional power line associated with each data-register sense amplifier with the first pass transistor being turn on;
determining a second block of the matched paired-block to be a matched block by recording the match line discharged to 0V to switch from Logic high to Logic low, otherwise the first block being the matched block;
returning a third address associated with the matched block to the match-address aggregator;
discharging all WLs, LBLs, and gate lines to string-select transistors for all blocks concurrently;
forming a full matched address based on the first address, the second address, and the third address;
outputting the full matched address to the Byte-based I/O Buffer circuit.

22. A method for performing Y-word search with variable length from a NAND-CAM array having divided groups with hierarchical 2-level bit lines and a common source line in Y direction as a match line per two blocks in each group, the method comprising:
providing a NAND-CAM array comprising J numbers of HG groups, each HG group being associated with N₁ broken global bit lines (GBLs) laid at a first level along Y direction and being divided into L numbers of MG groups, each MG group being associated with N₂ local bit lines (LBLs) laid at a second level below the first level in parallel to and respectively coupled to the N1 GBLs via a N₂/N₁-Y-pass circuit and being further divided into J′ numbers of LG groups, each LG group being associated with N₂ broken-LBLs forming N₂-bit parasitic line capacitors serving as N₂-bit dynamic cache registers (DCRs), each LG group, each LG group including H numbers of blocks and being associated with N₂ broken-LBLs commonly pull down via a precharge circuit to one independent power line configured in X direction perpendicular to the Y direction to be charged to a Vinh voltage, each block including N₂ numbers of strings respectively associated with the N₂ broken-LBLs cascaded in a row along a word line (WL) in the X direction, each string comprising N₃ numbers of NAND memory cells divided into two N₃/2 numbers of complimentary sets of cells capped by a pair of string-select transistors respectively at two ends of the string having its source node connected to a common source line bended from the X direction to the Y direction shared by a neighboring paired-block, wherein J, L, J′, H, N₁, N₂, and N₃ are integers of 2 and greater based on memory chip design;
providing multiple group-decoders including BHG-DEC, MG-DEC, and BLG-DEC to generate respective gate control signals for dividing HG groups, coupling N₁ broken-GBLs to N₂ LBLs, and dividing MG groups;
providing a block-decoder with a latch circuit coupled to a voltage generator via a set of N₃/2+1 pairs of complimentary bus lines in the Y direction and connected via corresponding block-gate transistors to a Y-page-buffer made by a corresponding set of N₃/2 pairs of complimentary word lines plus two string-select gate lines in the X direction;
setting the common source line shared by each of total J×L×J′×H/2 numbers of paired-blocks in the NAND-CAM array as a match line coupled via a first pass transistor to one data-register sense amplifier in the Y direction selected from N₁ data registers in a N₁-bit Page Buffer, each data-register sense amplifier being coupled to a program-read buffer circuit and a static cache register and coupled via a second pass transistor to an additional power line, each of the N₁ data registers being coupled to a common input port connected via a HV isolation device to each of N₁ GBLs;
loading a Y-word data, upon receiving a Y-word search command, to the Y-page-buffer associated with each block.

23. The method of claim 22 further comprising:
applying one-shot 0V pulse the additional power line with the first pass transistor being turned on to set 0V to all GBLs and LBLs with all associated transistors in multiple group-decoders including BHG-DEC, MG-DEC, and BLG-DEC and all string-select transistors being turned on and all precharge circuits being turned off, the MG-DEC including respective connections between Odd/Even LBLs and corresponding GBLs;
loading 2ⁿ number of complimentary voltages per each of corresponding N₃/2 pairs of complimentary word lines and two gate lines for the pair of string-select transistors associated with the selected block, where n=1 for SLC Y-word search and n=2 for MLC Y-word search;
setting the common source line of the matched block to Vdd to charge up one of all GBLs corresponding to a matched GBL containing one matched LBL at a voltage of Logic high while rest GBLs being left at 0V.

24. The method of claim 23 further comprising:
loading all GBL voltages with a reference voltage into the corresponding data-register sense amplifier;
enabling all register sense amplifiers respectively coupled to all program-read buffer circuits and all static cache registers in the N₁-bit Page Buffer;
transferring status of all data-register sense amplifiers to the corresponding program-read buffer circuits and static cache registers in two cycles, the status including information about each GBL;
checking an output node voltage of each program-read buffer circuit corresponding to a corresponding GBL at 0V to determine that a matched GBL, otherwise, ending search operation.

25. The method of claim 24 further comprising:
connecting all Odd LBLs only while closing all Even LBLs for all LG group of the NAND-CAM array;
discharging all common source lines to 0V to set all GBL voltages in accordance with string data;
loading all GBL voltages with a reference voltage into the corresponding data-register sense amplifier;
enabling all data-register sense amplifiers respectively coupled to the corresponding program-read buffer circuits and static cache registers in the N₁-bit Page Buffer;
transferring status of all data-register sense amplifiers to corresponding program-read buffer circuits only in one cycle, the status including information about all GBLs respectively connecting corresponding Odd LBLs;
checking the output node voltage of the program-read buffer circuit corresponding to the matched GBL at 0V to determine that a matched LBL is an Even LBL, otherwise to determine that a matched LBL is an Odd LBL.

26. The method of claim 25 further comprising:
coupling outputs of all static cache registers including one associated with the matched LBL to a Y-pass gate circuit via three sets of Y-decoders;
selectively turning on a first set of Y-decoders while other two sets of Y-decoders being all set to on state to determine a first part of a first address of the matched LBL;
decoding a second part of the first address by selectively turning on the second set of Y-decoders;
decoding a third part of the first address by selectively turning on the third set of Y-decoders;
returning the first address of the matched LBL by combining the first part, the second part, and the third part to the match-address aggregator, the matched LBL belonging to at least H blocks of a LG group.

27. The method of claim 26 further comprising:
discharging all common source lines to 0V by applying one-shot 0V to the additional power line of each digital register sense amplifier of the N₁-bit Page Buffer of the NAND-CAM array while turning on at least the first and second pass transistors;
turning on all associated transistors in multiple group-decoders including BHG-DEC, MG-DEC, and BLG-DEC and all string-select transistors for all blocks in all LG groups;
loading the 2ⁿ number of complimentary voltages per each of corresponding N₃/2 pairs of complimentary word lines and two gate lines for the pair of string-select transistors;
charging up GBLs to Vdd from the corresponding static cache registers to detect a matched common source line at Logic high due to corresponding string data matching with the Y-word data and all rest common source lines being at 0V;
loading all common source line voltages with a reference voltage into the corresponding data-register sense amplifier;
enabling all data-register sense amplifiers respectively coupled to the corresponding program-read buffer circuits and static cache registers in the N₁-bit Page Buffer;
transferring status of all data-register sense amplifiers to corresponding program-read buffer circuits and static cache registers in one cycle, the status including information about all common source lines associated with corresponding pair-blocks;
checking the output node voltage of the program-read buffer circuit corresponding to a matched pair-block at 0V to determine that a matched common source line as the match line with a second address.

28. The method of claim 27 further comprising:
disconnecting the match line from a first block of the matched paired-block to keep it at Logic high;
discharging all common source lines to 0V to set all GBL voltages in accordance with string data;
loading all GBL voltages associated with the matched pair-block with a reference voltage into the corresponding data-register sense amplifier;
enabling all data-register sense amplifiers respectively coupled to the corresponding program-read buffer circuits and static cache registers in the N₁-bit Page Buffer;
transferring status of all data-register sense amplifiers to corresponding program-read buffer circuits only in one cycle, the status including information about the matched common source line associated with the matched pair-block;
determining a first block of the matched paired-block to be a matched block by recording the match line discharged to 0V by switching from Logic high to Logic low, otherwise the second block being the matched block.

29. The method of claim 28 further comprising:
coupling outputs of all static cache registers including one associated with the matched block to the Y-pass gate circuit via three sets of Y-decoders;
selectively turning on a second set of Y-decoders while keeping the two other sets of Y-decoders being all set to on states to determine a first part of a third address of the matched block;
decoding a second part of the first address by selectively turning on the third set of Y-decoders while keeping the two other sets of Y-decoders being all set to on states;
returning the third address of the matched block by combining the first part and the second part to the match-address aggregator;
discharging all WLs, LBLs, and gate lines to string-select transistors for all blocks concurrently;
forming a full matched address based on the first address, the second address, and the third address;
outputting the full matched address to a Byte-based I/O Buffer circuit.

30. The method of claim 22 alternatively comprising:
discharging all common source lines to 0V by applying one-shot 0V to the additional power line of each digital register sense amplifier of the N₁-bit Page Buffer of the NAND-CAM array while applying Vdd to gates of at least the first and second pass transistors;
turning on all associated transistors in multiple group-decoders including BHG-DEC, MG-DEC, and BLG-DEC and all string-select transistors for all blocks in all LG groups;
loading 2ⁿ number of complimentary voltages at corresponding N₃/2 pairs of complimentary word lines and two gate lines for the pair of string-select transistors associated with the selected block, where n=1 for SLC Y-word search and n=2 for MLC Y-word search.

31. The method of claim 30 further comprising:
charging all GBLs and LBLs to Vdd by setting Vdd to the additional power line with the second pass transistor being turned on to allow at least one common source line containing a matched pair-block to be charged up at Logic high while rest common source lines being at Logic low;
loading voltages of all common source lines with a reference voltage into a corresponding data-register sense amplifier;
enabling all N₁-bit digital register sense amplifiers, program-read buffer circuits, and static cache registers;
transferring status of all data-register sense amplifiers to corresponding program-read buffer circuits and static cache registers, the status including information about all common source lines;
determining a matched paired-block with a first address by recording an output node of the program-read buffer circuit at 0V corresponding to a matched common source line, otherwise, ending search operation.

32. The method of claim 31 further comprising:
disconnecting the match line from a first block of the matched paired-block to keep it at a Logic-high voltage;
discharging all common source lines to 0V to set corresponding GBL voltages in accordance with string data;
loading all GBL voltages of the matched pair-block with a reference voltage into the corresponding digital register sense amplifier;
enabling all N₁-bits digital-register sense amplifiers, program-read buffer circuits, and static cache registers;
transferring status of all data-register sense amplifiers to the corresponding program-read buffer circuits only, the status including information the match line with the Logic high voltage;
determining the first block to be a matched block with a second address by recording the match line switched from the Logic high voltage to 0V, otherwise determining a second block of the matched pair-block to be the matched block.

33. The method of claim 32 further comprising:
coupling outputs of all static cache registers including one associated with the matched block to a Y-pass gate circuit via three sets of Y-decoders with a first set of Y-decoders being set always on;
selectively turning on a second set of Y-decoders while keeping the other two sets of Y-decoders at on states to determine a first part of the second address of the matched block;
decoding a second part of the second address by selectively turning on the third set of Y-decoders;
returning the second address by combining the first part and the second part to a match-address aggregator.

34. The method of claim 33 further comprising:
reloading the second address of the matched block;
reloading the 2ⁿ number of complimentary voltages per each of corresponding N₃/2 pairs of complimentary word lines and two gate lines for the pair of string-select transistors associated with the matched block based on the second address, while setting 0V to all gate lines for all unmatched blocks;
applying one-shot 0V pulse to the additional power line with the second pass transistor being turned on to set 0V to all GBLs and LBLs to which the matched block belong with all associated transistors in multiple group-decoders including BHG-DEC, MG-DEC, and BLG-DEC and all string-select transistors being turned on and all precharge circuits being turned off, the MG-DEC including respective connections between Odd/Even LBLs and corresponding GBLs;
setting the common source line of the matched block to Vdd to charge up one of all GBLs corresponding to a matched GBL containing one matched LBL is at a voltage of Logic high.

35. The method of claim 34 further comprising:
loading the voltages of all GBLs with a reference voltage into the corresponding data-register sense amplifier in the Page Buffer of the NAND-CAM array;
transferring status of all data-register sense amplifiers to the corresponding program-read buffer circuits only, the status including information about corresponding Odd/Even LBL coupled to the matched GBL;
connecting only the corresponding Odd LBL to the matched GBL while closing Even LBL;
resetting GBLs with the status of all data-register sense amplifiers being transferred to the corresponding program-read buffer circuits;
checking an output node voltage of the program-read buffer circuit corresponding to the matched GBL at 0V to determine that a matched LBL is an Even LBL, otherwise to determine that a matched LBL is an Odd LBL.

36. The method of claim 35 further comprising:
coupling outputs of all static cache registers including one associated with the matched LBL to a Y-pass gate circuit via three sets of Y-decoders;
selectively turning on a first set of Y-decoders while other two sets of Y-decoders being all set to an on state to determine a first part of a third address of the matched LBL;
decoding a second part of the third address by selectively turning on the second set of Y-decoders;
decoding a third part of the third address by selectively turning on the third set of Y-decoders;
returning the third address of the matched LBL by combining the first part, the second part, and the third part to the match-address aggregator;
discharging all WLs, LBLs, and gates to the string-select transistors of all blocks concurrently;
forming a full matched address based on the first address, the second address, and the third address;
outputting the full matched address to a Byte-based I/O Buffer circuit.

37. The method of claim 1 wherein the LG-group based sense amplifier comprises a first NMOS transistor and a second NMOS transistor sharing a first common source line connected to the independent power line via a HV NMOS isolation transistor, a first PMOS transistor and a second PMOS transistor sharing a second common source line connected to a drain node of the second NMOS transistor, an inverter having an input node connected to the second common source line and an output node for coupling with the LG-group based ROM encoder circuit, the first NMOS transistor having a float drain node and being gated by a first bias voltage, the second NMOS transistor being gated by a second bias voltage, the first PMOS transistor having a float drain node and being gated by a third bias voltage, the second PMOS transistor having a float drain node and being gated by a fourth bias voltage.

38. The method of claim 37 wherein the LG-group based sense amplifier is configured to precharge all N₂ broken-LBL parasitic line capacitors associated with the LG group via the independent power line to a first level determined by the first bias voltage at a first maximum level minus a threshold level of the first NMOS transistor while setting the second bias voltage to 0V.

39. The method of claim 38 wherein the LG-group based sense amplifier is enabled by setting the third bias voltage for current-mirror control and setting the fourth bias voltage to Vdd so that the independent power line as a match line for the LG group is charged to a second level slightly higher than the first level determined by the first bias voltage at a second maximum level minus the threshold level of the first NMOS transistor while setting the second bias voltage high to allow the match line connected to the second common source line coupled to the input node of the inverter.

40. The method of claim 39 wherein the LG-group based sense amplifier is configured to sense a switch from a Logic-high level to a Logic-low level at the input node due to a conducting charge flow from the match line through a matched string among N₂ strings of each block in the LG group down to the common source line of the block and to output a Logic-high signal at the output node, the matched string containing stored data that match the Y-word data.

41. The method of claim 40 wherein the LG-group based ROM encoder circuit is configured by coupling varied numbers of transistors to respectively receive Logic-high/low signals from the output nodes of LG-group based sense amplifiers of all LG groups and by sequentially turning on/off the varied numbers of transistors associated with one or more up to 2^{k}-1 blocks in each LG group to encode k bits of digital addresses of the matched block based on one Logic-high input from one matched block of one LG group and Logic-low inputs from other un-matched blocks of all LG groups.

42. The method of claim 7 wherein the Block-based sense amplifier comprises a first NMOS transistor, a second NMOS transistor, a PMOS transistor, and a NOR device with an output node for coupling with a Block-based ROM encoder circuit, the first NMOS transistor having a gate node connected to the match line coupled to the common source line via a HV NMOS isolation transistor, a drain node connected to a first input node of the NOR device, and a source node connected to ground, the second NMOS transistor having a drain node connected to the match line, a gate node controlled by a first control signal, the PMOS transistor having a source node connected to the first input node and a gate node controlled by a second control signal, the NOR device having a second input node coupled to a third control signal.

43. The method of claim 42 wherein the Block-based sense amplifier is enabled by setting the first control signal to 0V, the second control signal to 0V, and the third control signal to 0V, and setting the independent power line to Vdd to precharge all N₂ broken-LBLs for each isolated LG group, and is configured to set the match line for allowing a current flow from the common source line per one paired-block in each LG group by setting the HV NMOS isolation transistor to a low-resistance state.

44. The method of claim 43 wherein the Block-based sense amplifier is configured to sense a switch from a Logic-high level to a Logic-low level at the first input node to cause the output node switching from 0V to Vdd as the current flows from the precharged broken-LBL through a matched string to the common source line and to the match line for determining a matched paired-block within one of all LG groups.

45. The method of claim 44 wherein the Block-based ROM encoder circuit is configured by coupling varied numbers of transistors to respectively receive Logic-high/low signals from the output nodes of all Block-based sense amplifiers of all LG groups and to encode all corresponding bits of digital addresses of the matched paired-block based on one Logic-high input from the matched paired block of the one of all LG groups and Logic-low inputs from other un-matched paired-blocks of all LG groups, and by sequentially turning on/off the varied numbers of transistors associated with one block of each paired-block in each LG group to determine a matched block of the matched paired-block, the matched block containing stored data that match the Y-word data.

46. The method of claim 7 wherein the Block-based sense amplifier comprises a first NMOS transistor and a second NMOS transistor sharing a first gate signal, a third NMOS transistor and a fourth NMOS transistor sharing a second gate signal, a fifth NMOS transistor coupled to a first drain node of the first NMOS transistor and gated by a first control signal, a first capacitor coupled between ground and a first common node of a first source node of the first NMOS transistor and a third drain node of the third NMOS transistor, a second capacitor coupled between ground and a second common node of a second source node of the second NMOS transistor and a fourth drain node of the fourth NMOS transistor, a latch circuit having a first data node coupled to a third source node of the third NMOS transistor and a second data node coupled to a fourth source node of the fourth NMOS transistor and a first latch node coupled to a PMOS transistor gated by a second control signal and a second latch node coupled to a NMOS transistor gated by a third control signal, a NOR device having a first input node connected to the second latch node, a second input node connected to an fourth control signal, and an output node for coupling to the Block-based ROM encoder circuit, wherein the first drain node is connected to the match line and the second drain node is connected to a reference line.

47. The method of claim 46 wherein the Block-based sense amplifier is configured to set the match line at a Logic-high level due to current flow from the common source line of a matched string in one block of a matched paired-block of one of all LG groups in the and set the reference line to a half of the Logic-high level to store a first voltage corresponding to a Logic-high level to the first capacitor and a second voltage equal to half of the first voltage to the second capacitor.

48. The method of claim 47 wherein the Block-based sense amplifier is further configured to transfer the first voltage in the first capacitor and the second voltage in the second capacitor respectively to the first latch node and the second latch node and is enabled to amplify the latched signal of a difference between the first voltage and the second voltage to generate a pattern of Vdd/Vss at the first input node of the NOR device, wherein the Vdd at the first input node corresponds to the matched paired block of the one of all LG groups leading a Vss=0V level at the corresponding output node.

49. The method of claim 48 wherein the Block-based ROM encoder circuit is configured by coupling varied numbers of transistors to respectively receive Logic-high/low signals from the output nodes of all Block-based sense amplifiers of all LG groups and to encode all corresponding bits of digital addresses of the matched paired-block based on one Vdd-level input from the matched paired block of the one of all LG groups and Vss-level inputs from other un-matched paired-blocks of all LG groups, and by sequentially turning on/off the varied numbers of transistors associated with one block of each paired-block in each LG group to determine a matched block of the matched paired-block, the matched block containing stored data that match the Y-word data.

50. The method of claim 22 wherein the data-register sense amplifier comprises a paired first and second input nodes of a latch circuit connected to a common input port respectively via a first NMOS transistor and a second NMOS transistor, the second input node being connected to a common source line via the first pass transistor gated by a first enable signal, the first input node being connected to a reference line via a third pass transistor gated by a third enable signal, the common input port being connected to the additional power line via the second pass transistor gated by a second enable signal and being connected to one of N₁ GBLs via the HV isolation device, the latch circuit being configured to receive a differential analog signal from the first and second input nodes and generating a pair of complimentary high/low digital signals at a pair of first and second output nodes by applying a pair of complimentary latch signals at a pair of latch nodes, the pair of first and second output nodes being coupled to the program-read buffer circuit and the static cache register.

51. The method of claim 50 wherein the program-read buffer circuit is made of two inverters having a first pair of input transistors with their gates being respectively connected from the pair of first and second output nodes of the data-register sense amplifier with the pair of complimentary high/low digital signals and a first pair of verify transistors gated by a pair of control signals to either allow a reception of the pair of complimentary high/low digital signals in reversed phase or block transfer of any signals, and having a second pair of input transistors with their gates being connected to corresponding output nodes of the static cache register and a second pair of verify transistors gated by a common control signal to either allow a reception of a pair of digital signals in reversed phase from the static cache register or block transfer of any signals, and including an output node connected either to the common input port via a first NMOS control transistor for one-bit programming or to a match line circuit with a second NMOS control transistor having a drain node as a pass port for indicating a pass of one-bit program-verify.

52. The method of claim 50 wherein the static cache register is made of two inverters having a first pair of input transistors with their gates being respectively connected from the pair of data nodes with the pair of complimentary high/low digital signals and a pair of gate-control transistors to either allow a reception of the pair of complimentary high/low digital signals in a same phase or block transfer of any signals, and having a second single input transistor connected to one of N₁ input nodes of a Y-pass gate circuit with one-byte output nodes coupled to a digital I/O Buffer circuit for loading input data in unit of Byte and decoding an output for identifying address of a matched LBL.

53. The method of claim 51 wherein the first output node of the latch circuit in the data-register sense amplifier is set to a first voltage level for one matched paired-block or is set to Vss for remaining all unmatched paired-blocks in the NAND-CAM array with each of all reference lines is set to a half of the first voltage level during a search operation, generating a 0V at the pass port to indicate that the one matched paired-block is found.

54. The method of claim 52 wherein the Y-pass gate circuit comprises a three-level encoder with one of one-byte output nodes commonly coupled to a first set of top-level inputs via the first set of top-level transistors controlled respectively by the first set of first gate signals, each top-level transistor being coupled to a second set of middle-level inputs via the second set of middle-level transistors controlled respectively by the second set of second gate signals, each middle-level transistor being coupled to a third set of low-level inputs via the third set of low-level transistors controlled respectively by the third set of third gate signals, each low-level input being delivered from an one-bit static cache register corresponding to one LBL among one byte of NAND strings during a LBL search operation.

55. The method of claim 54 wherein the digital I/O Buffer circuit in unit of byte comprises an input buffer circuit and an output buffer circuit having one I/O pin per each of one-byte pad, the input buffer circuit being coupled to a first drain node of a first NMOS transistor gated by a first control signal and the output buffer circuit being coupled to a second drain node of a second NMOS transistor gated by a second control signal, the first NMOS transistor and the second NMOS transistor having a common source node coupled to the one output node of the three-level encoder per byte, the second drain node being an encoder output node coupled in parallel to a first PMOS transistor gated by a third control signal and a second PMOS transistor gated by a fourth control signal, the first PMOS transistor having at least three-fold larger resistance than that of a corresponding NAND string to provide a P-load for one sensed NAND string matching with the loaded Y-word, the second PMOS transistor having a resistance much higher than that of the first PMOS transistor, the fourth control signal being used for precharging the Y-pass gate circuit.

56. The method of claim 55 wherein the LBL search operation comprises sequential on-off operations starting from turning on one of the top-level transistors while turning off rest of the top-level transistors followed by scanning through all the middle-level transistors and low-level transistors until a sinking current is detected at the second drain node to indicate a matched byte of LBLs with its address being encoded by the three-level encoder.

57. The method of claim 56 wherein the digital I/O Buffer circuit is further coupled to a 3-bit LBL-ROM encoder circuit comprising varied number of transistors respectively coupled to each of the encoder output nodes to identify a matched single LBL from the matched byte of LBLs.

58. The method of claim 7 wherein the N₁ is number of bits selected from 8 KB, 16 KB or other suitable integers; N₂ is equal to 2ⁿ×N₁, wherein m is 0 or a positive integer; J is selected from 8, 16, or other suitable integer smaller than 16; L is an integer selected from 4, 8, 16 or other suitable integer smaller than 16; J′ is 8; H is selected from 8, 16; and N₃ is selected from 64, 128, 256 or other suitable integer smaller than 256.

59. The method of claim 22 wherein the N₁ is number of bits selected from 8 KB, 16 KB or other suitable integers; N₂ is equal to 2^{m}×N₁, wherein m is 0 or a positive integer; J is selected from 8, 16, or other suitable integer smaller than 16; L is an integer selected from 4, 8, 16 or other suitable integer smaller than 16; J′ is 8; H is selected from 8, 16; and N₃ is selected from 64, 128, 256 or other suitable integer smaller than 256.

60. The method of claim 11 wherein the resetting GBLs comprises:
discharging all common source lines to 0V to set each GBL voltage in accordance with corresponding string data originally stored;
loading all GBL voltages with a reference voltage into the corresponding data-register sense amplifier;
transferring status of all data-register sense amplifiers to corresponding program-read buffer circuits only, the status including information about corresponding Odd/Even LBL coupled to the matched GBL.

61. The method of claim 1 wherein the Vinh voltage is greater than Vdd up to device break-down voltage about 7V associated with all high-voltage transistors being used in multiple group-decoders including BHG-DEC, MG-DEC, BLG-DEC, and pairs of string-select transistors that connected to the independent power line per LG group.

62. The method of claim 7 wherein the Vinh voltage is no greater than Vdd associated with all low-voltage transistors being used in multiple group-decoders including BHG-DEC, MG-DEC, BLG-DEC, and pairs of string-select transistors that connected to the independent power line per LG group.

63. The method of claim 7 wherein the Vinh voltage is greater than Vdd up to device break-down voltage about 7V associated with all high-voltage transistors being used in multiple group-decoders including BHG-DEC, MG-DEC, BLG-DEC, and pairs of string-select transistors that connected to the independent power line per LG group.

64. The method of claim 22 wherein the Vinh voltage is no greater than Vdd associated with all low-voltage transistors being used in multiple group-decoders including BHG-DEC, MG-DEC, BLG-DEC, and pairs of string-select transistors that connected to the independent power line per LG group.

65. The method of claim 22 wherein the Vinh voltage is greater than Vdd up to device break-down voltage about 7V associated with all high-voltage transistors being used in multiple group-decoders including BHG-DEC, MG-DEC, BLG-DEC, and pairs of string-select transistors that connected to the independent power line per LG group.

66. The method of claim 1 wherein loading a Y-word data to the pseudo Y-page-buffer comprises turning on the block-gate transistors to set N₃/2-bit complimentary voltages in the corresponding complimentary bus lines in the Y direction to be stored at respective parasitic poly capacitors of the N₃/2 pair of complimentary word lines in the X direction in one cycle per block and turning off the block-gate transistors to lock the N₃/2-bit complimentary voltages therein.

67. The method of claim 1 wherein the 2ⁿ number of complimentary voltages comprises 2 complimentary voltages for each pair of complimentary word lines in a block for SLC Y-word search for n=1 with a logic high voltage at Vdd and a logic low voltage at 0V as a low-power option or alternatively with a logic high voltage being pumped to above Vdd.

68. The method of claim 7 wherein loading a Y-word data to the pseudo Y-page-buffer comprises turning on the block-gate transistors to set N₃/2-bit complimentary voltages in the corresponding complimentary bus lines in the Y direction to be stored at respective parasitic poly capacitors of the N₃/2 pair of complimentary word lines in the X direction in one cycle per block and turning off the block-gate transistors to lock the N₃/2-bit complimentary voltages therein.

69. The method of claim 8 wherein the 2ⁿ number of complimentary voltages comprises 2 complimentary voltages for each pair of complimentary word lines in a block for SLC Y-word search for n=1 with a logic high voltage at Vdd and a logic low voltage at 0V as a low-power option or alternatively with a logic high voltage being pumped to above Vdd.

70. The method of claim 22 wherein loading a Y-word data to the pseudo Y-page-buffer comprises turning on the block-gate transistors to set N₃/2-bit complimentary voltages in the corresponding complimentary bus lines in the Y direction to be stored at respective parasitic poly capacitors of the N₃/2 pair of complimentary word lines in the X direction in one cycle per block and turning off the block-gate transistors to lock the N₃/2-bit complimentary voltages therein.

71. The method of claim 22 wherein the 2ⁿ number of complimentary voltages comprises 2 complimentary voltages for each pair of complimentary word lines in a block for SLC Y-word search for n=1 with a logic high voltage at Vdd and a logic low voltage at 0V as a low-power option or alternatively with a logic high voltage being pumped to above Vdd.

72. The method of claim 2 wherein returning a first address of the matched LG group is encoded by the LG-group based ROM encoder circuit within 25 μs due to that total capacitances to be precharged and discharged during the searching operation include only one parasitic line capacitor associated with a metal broken-LBL in a block of the matched LG group plus one parasitic line capacitor associated with a poly word line.
